(19) United States
(12) Patent Application Publication
(10) Pub. No.: US 2025/0194253 A1
(43) Pub. Date: Jun. 12, 2025

(54) SEMICONDUCTOR DEVICE AND DISPLAY DEVICE

(71) Applicant: SEMICONDUCTOR ENERGY LABORATORY CO., LTD., Atsugi-shi (JP)

(72) Inventors: Hajime KIMURA, Atsugi (JP); Shunpei YAMAZAKI, Tokyo (JP)

(21) Appl. No.: 18/957,122

(22) Filed: Nov. 22, 2024

(30) Foreign Application Priority Data
Dec. 8, 2023 (JP) 2023-207567

(51) Int. Cl. H01L 27/12; H01L 29/786

(52) U.S. Cl. CPC H10D 86/60; H10D 30/6728; H10D 86/421; H10D 86/481

(57) ABSTRACT

A semiconductor device including a miniaturized transistor. The semiconductor device includes a transistor and a capacitor. The transistor is a vertical transistor. A conductive layer positioned on the upper side of two conductive layers, which serve as a source electrode and a drain electrode, serves as one electrode of the capacitor. An insulating layer functioning as a gate insulating layer also serves as a dielectric of the capacitor. A conductive layer which is provided over a dielectric to overlap with the one electrode of the capacitor and the dielectric serves as the other electrode of the capacitor. A gate electrode of the transistor and the other electrode of the capacitor contain the same material.

### BACKGROUND OF THE INVENTION

### 1. Field of the Invention

One embodiment of the present invention relates to a transistor. One embodiment of the present invention relates to a capacitor. One embodiment of the present invention relates to a semiconductor device including a transistor and a capacitor. One embodiment of the present invention relates to a display device including a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, a lighting device, an input device, an input/output device, an electronic device including any of them, a driving method thereof, and a manufacturing method thereof. A semiconductor device generally means a device that can function by utilizing semiconductor characteristics.

### 2. Description of the Related Art

An example of display devices is a liquid crystal display device including a liquid crystal element as a display element. For example, an active matrix liquid crystal display device in which pixel electrodes are arranged in a matrix and a switching element is connected to each of the pixel electrodes is used for various devices such as a smartphone, a tablet terminal, a monitor device, a television device, and digital signage.

It is known that liquid crystal display devices are classified into two major types: transmissive type and reflective type. A liquid crystal display device can display brighter images as the effective light-emitting area ratio (also referred to as an aperture ratio) of a pixel is higher, which also brings about a reduction in power consumption; thus, an improvement in aperture ratio is required.

For example, an active matrix liquid crystal display device in which a transistor including metal oxide in its channel formation region is used as a switching element connected to each pixel electrode has been known. Patent Document 1 discloses a liquid crystal display device in which a transistor including metal oxide in its channel formation region is used to improve the aperture ratio.

### REFERENCE

[Patent Document 1] Japanese Published Patent Application No. 2018-189938

### SUMMARY OF THE INVENTION

An object of one embodiment of the present invention is to provide a semiconductor device including a miniaturized transistor and a display device including the semiconductor device. Another object of one embodiment of the present invention is to provide a small-sized semiconductor device and a display device including the semiconductor device. Another object of one embodiment of the present invention is to provide a display device with high resolution. Another object of one embodiment of the present invention is to provide a highly reliable display device. Another object of one embodiment of the present invention is to provide a display device with high display quality. Another object of one embodiment of the present invention is to provide a display device with a high aperture ratio. Another object of one embodiment of the present invention is to provide a display device capable of high-speed driving.

Another object of one embodiment of the present invention is to provide a semiconductor device, a display device, a transistor, an electronic device, or the like that has a novel structure. Another object of one embodiment of the present invention is to at least alleviate at least one of problems in the conventional art.

Note that the description of these objects does not preclude the existence of other objects. One embodiment of the present invention does not necessarily achieve all of these objects. Objects other than these can be derived from the description of the specification, the drawings, the claims, and the like.

One embodiment of the present invention is a semiconductor device including a transistor, a capacitor, and a first insulating layer. The transistor includes a first conductive layer, a second conductive layer, a third conductive layer, a semiconductor layer, and a second insulating layer. The first insulating layer is positioned over the first conductive layer. The second conductive layer is positioned over the first insulating layer. The second conductive layer and the first insulating layer include an opening reaching the first conductive layer. In the opening, the semiconductor layer is in contact with a side surface of the second conductive layer, a side surface of the first insulating layer, and a top surface of the first conductive layer. The second insulating layer is in contact with a top surface of the semiconductor layer and a top surface of the second conductive layer. The third conductive layer is positioned over the second insulating layer so as to include a region overlapping with the semiconductor layer. The capacitor includes the second conductive layer, the second insulating layer, and a fourth conductive layer. The fourth conductive layer is positioned over the second insulating layer so as to include a region overlapping with the second conductive layer.

In the above semiconductor device, the third conductive layer and the fourth conductive layer preferably contain the same material.

It is preferable that the above semiconductor device further include a fifth conductive layer over the same layer as the first conductive layer. The fifth conductive layer preferably includes a region overlapping with the second conductive layer with the first insulating layer therebetween. The capacitor preferably includes the second conductive layer, the second insulating layer, the fourth conductive layer, the fifth conductive layer, and the first insulating layer.

In the above semiconductor device, the semiconductor layer preferably includes a region positioned between the second conductive layer and the fourth conductive layer, and the region preferably serves as a dielectric of the capacitor.

Another embodiment of the present invention is a semiconductor device including a transistor, a capacitor, and a first insulating layer. The transistor includes a first conductive layer, a second conductive layer, a third conductive layer, a semiconductor layer, and a second insulating layer. The first insulating layer is positioned over the first conductive layer. The second conductive layer is positioned over the first insulating layer. The second conductive layer and the first insulating layer include a first opening reaching the first conductive layer. In the first opening, the semiconductor layer is in contact with a side surface of the second conductive layer, a side surface of the first insulating layer, and a top surface of the first conductive layer. The second insulating layer is in contact with a top surface of the semiconductor layer and a top surface of the second conductive layer. The third conductive layer is positioned over the second insulating layer so as to include a region overlapping with the semiconductor layer. The capacitor includes the first conductive layer, the second insulating layer, and a fourth conductive layer. The first insulating layer includes a second opening reaching the first conductive layer. In the second opening, the second insulating layer is in contact with a side surface of the first insulating layer and a top surface of the first conductive layer. The fourth conductive layer is positioned over the second insulating layer so as to include a region overlapping with the second opening.

In the above semiconductor device, the third conductive layer and the fourth conductive layer preferably contain the same material.

Another embodiment of the present invention is a display device including the above-described semiconductor device and a display element.

In the above display device, the display element is preferably a liquid crystal element.

In the above display device, the display element is preferably a light-emitting element.

One embodiment of the present invention can provide a semiconductor device including a miniaturized transistor and a display device including the semiconductor device. One embodiment of the present invention can provide a small-sized semiconductor device and a display device including the semiconductor device. One embodiment of the present invention can provide a display device with high resolution. One embodiment of the present invention can provide a highly reliable display device. One embodiment of the present invention can provide a display device with high display quality. One embodiment of the present invention can provide a display device with a high aperture ratio. One embodiment of the present invention can provide a display device capable of high-speed driving.

One embodiment of the present invention can provide a semiconductor device, a display device, a transistor, an electronic device, or the like having a novel structure. According to one embodiment of the present invention, at least one of problems in the conventional art can be at least alleviated.

Note that the description of these effects does not preclude the existence of other effects. One embodiment of the present invention does not necessarily have all of these effects. Effects other than these can be derived from the description of the specification, the drawings, the claims, and the like.

### BRIEF DESCRIPTION OF THE DRAWINGS

FIGS. 1A and 1B illustrate a structure example of a display device.

FIG. 2A is a plan view illustrating an example of a semiconductor device. FIG. 2B is a cross-sectional view illustrating the example of the semiconductor device. FIG. 2C is a cross-sectional view illustrating an example of a transistor.

FIG. 3A is a plan view illustrating an example of a semiconductor device. FIG. 3B is a cross-sectional view illustrating the example of the semiconductor device.

FIG. 4A is a plan view illustrating an example of a semiconductor device. FIG. 4B is a cross-sectional view illustrating the example of the semiconductor device.

FIG. 5A is a plan view illustrating an example of a semiconductor device. FIG. 5B is a cross-sectional view illustrating the example of the semiconductor device.

FIG. 6A is a plan view illustrating an example of a semiconductor device. FIG. 6B is a cross-sectional view illustrating the example of the semiconductor device.

FIG. 7A is a plan view illustrating an example of a semiconductor device. FIG. 7B is a cross-sectional view illustrating the example of the semiconductor device.

FIG. 8A is a plan view illustrating an example of a semiconductor device. FIG. 8B is a cross-sectional view illustrating the example of the semiconductor device.

FIG. 9A is a plan view illustrating an example of a semiconductor device. FIG. 9B is a cross-sectional view illustrating the example of the semiconductor device.

FIG. 10A is a plan view illustrating an example of a semiconductor device. FIG. 10B is a cross-sectional view illustrating the example of the semiconductor device.

FIG. 11A is a plan view illustrating an example of a semiconductor device. FIG. 11B is a cross-sectional view illustrating the example of the semiconductor device.

FIG. 12A is a plan view illustrating an example of a semiconductor device. FIG. 12B is a cross-sectional view illustrating the example of the semiconductor device.

FIG. 13A is a plan view illustrating an example of a semiconductor device. FIG. 13B is a cross-sectional view illustrating the example of the semiconductor device.

FIG. 14A is a plan view illustrating an example of a semiconductor device. FIG. 14B is a cross-sectional view illustrating the example of the semiconductor device.

FIG. 15A is a plan view illustrating an example of a semiconductor device. FIG. 15B is a cross-sectional view illustrating the example of the semiconductor device.

FIG. 16A is a plan view illustrating an example of a semiconductor device. FIG. 16B is a cross-sectional view illustrating the example of the semiconductor device.

FIG. 17A is a plan view illustrating an example of a semiconductor device. FIG. 17B is a cross-sectional view illustrating the example of the semiconductor device.

FIG. 18A is a plan view illustrating an example of a semiconductor device. FIG. 18B is a cross-sectional view illustrating the example of the semiconductor device.

FIG. 19A is a plan view illustrating an example of a semiconductor device. FIG. 19B is a cross-sectional view illustrating the example of the semiconductor device.

FIG. 20A is a plan view illustrating an example of a semiconductor device. FIG. 20B is a cross-sectional view illustrating the example of the semiconductor device.

FIG. 21A is a plan view illustrating an example of a semiconductor device. FIG. 21B is a cross-sectional view illustrating the example of the semiconductor device.

FIG. 22A is a plan view illustrating an example of a semiconductor device. FIG. 22B is a cross-sectional view illustrating the example of the semiconductor device.

FIG. 23A is a plan view illustrating an example of a semiconductor device. FIG. 23B is a cross-sectional view illustrating the example of the semiconductor device.

FIG. 24A is a plan view illustrating an example of a semiconductor device. FIG. 24B is a cross-sectional view illustrating the example of the semiconductor device.

FIG. 25A is a plan view illustrating an example of a semiconductor device. FIG. 25B is a cross-sectional view illustrating the example of the semiconductor device.

FIG. 26A is a plan view illustrating an example of a semiconductor device. FIG. 26B is a cross-sectional view illustrating the example of the semiconductor device.

FIG. 27A is a plan view illustrating an example of a semiconductor device. FIG. 27B is a cross-sectional view illustrating the example of the semiconductor device.

FIG. 28A is a plan view illustrating an example of a semiconductor device. FIG. 28B is a cross-sectional view illustrating the example of the semiconductor device.

FIG. 29A is a plan view illustrating an example of a semiconductor device. FIG. 29B is a cross-sectional view illustrating the example of the semiconductor device.

FIG. 30A is a plan view illustrating an example of a semiconductor device. FIG. 30B is a cross-sectional view illustrating the example of the semiconductor device.

FIG. 31A is a plan view illustrating an example of a semiconductor device. FIG. 31B is a cross-sectional view illustrating the example of the semiconductor device.

FIG. 32A is a plan view illustrating an example of a semiconductor device. FIG. 32B is a cross-sectional view illustrating the example of the semiconductor device.

FIG. 33A and FIG. 33B are each a cross-sectional view illustrating an example of a semiconductor device.

FIG. 34A is a plan view illustrating an example of a semiconductor device. FIG. 34B is a cross-sectional view illustrating the example of the semiconductor device.

FIG. 35A is a plan view illustrating an example of a semiconductor device. FIG. 35B is a cross-sectional view illustrating the example of the semiconductor device.

FIG. 36A is a plan view illustrating an example of a semiconductor device. FIG. 36B is a cross-sectional view illustrating the example of the semiconductor device.

FIG. 37A is a plan view illustrating an example of a semiconductor device. FIG. 37B is a cross-sectional view illustrating the example of the semiconductor device.

FIG. 38A is a plan view illustrating an example of a semiconductor device. FIG. 38B is a cross-sectional view illustrating the example of the semiconductor device.

FIG. 39A is a plan view illustrating an example of a semiconductor device. FIG. 39B is a cross-sectional view illustrating the example of the semiconductor device.

FIGS. 40A to 40D each illustrate a structure example of a pixel.

FIGS. 41A to 41D each illustrate a structure example of a pixel.

FIG. 42 illustrates a structure example of a pixel.

FIGS. 43A to 43D each illustrate a structure example of an electronic device.

FIGS. 44A to 44F each illustrate a structure example of an electronic device.

FIGS. 45A to 45G each illustrate a structure example of an electronic device.

### DETAILED DESCRIPTION OF THE INVENTION

Embodiments will be described below with reference to the drawings. Note that the embodiments can be implemented in many different modes, and it will be readily appreciated by those skilled in the art that modes and details can be changed in various ways without departing from the spirit and scope of the present invention. Thus, the present invention should not be interpreted as being limited to the following description of the embodiments.

Note that in structures of the present invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of current or voltage, switching operation for controlling conduction or non-conduction, and the like. A transistor in this specification includes, in its category, an insulated-gate field effect transistor (IGFET) and a thin film transistor (TFT).

The functions of a “source” and a “drain” are sometimes replaced with each other when a transistor of opposite polarity is used or when the direction of current flow is changed in circuit operation, for example. Thus, the terms “source” and “drain” can be used interchangeably in this specification.

The expression “connection” in this specification includes “electrical connection”, for example.

When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit.

An example of the case where the expression “A and B are indirectly connected” can be used is the case where A and B are connected to each other through a source and a drain of at least one transistor.

However, there are exceptional cases where the expression “A and B are indirectly connected” cannot be used. Specific examples of such exceptions include the case where a capacitor is connected between A and B and the case where a gate insulating film of a transistor or the like is present between A and B. In that case, the expression “A (a gate of the transistor) and B (a source or a drain of the transistor) are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also includes the case where the outlines do not completely overlap with each other in some cases; for instance, the edge of the upper layer may be positioned on the inner side or the outer side of the edge of the lower layer.

Note that in this specification and the like, a top surface shape of a component means an outline shape of the component in a plan view. A plan view means that the component is observed from a direction normal to a surface where the component is formed or from a direction normal to a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (or the formation order) of a stacked body or the like, even in the case where a surface on which the stacked body is provided (e.g., a formation surface, a support surface, a bonding surface, or a planarization surface) is located over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

### Embodiment 1

In this embodiment, a display device of one embodiment of the present invention will be described.

### [Structure Example of Display Device]

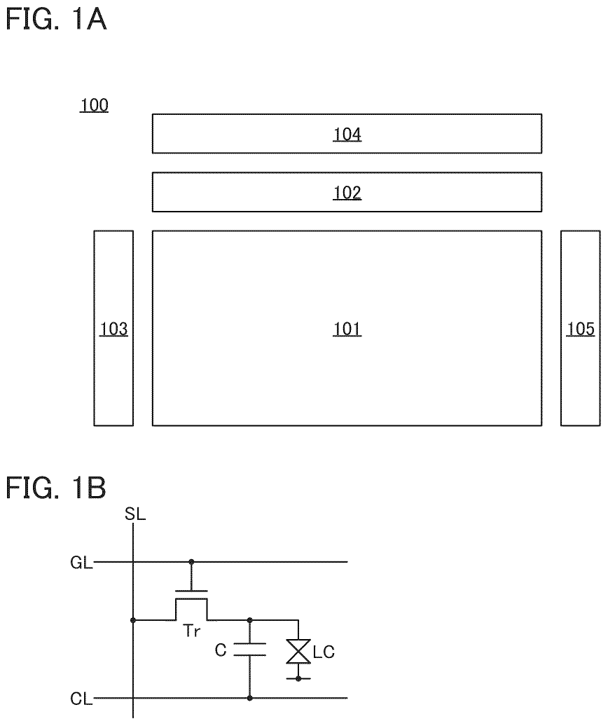

FIG. 1A is a block diagram of a display device 100 of one embodiment of the present invention. The display device 100 includes a pixel portion 101, a source line driver circuit portion 102, a gate line driver circuit portion 103, a protection circuit portion 104, and a touch sensor driver circuit portion 105.

The pixel portion 101 is a region where a plurality of pixels are arranged in a matrix, and at least one display element and a pixel circuit are provided in one pixel. At least one gate line and at least one source line are connected to the pixel circuit. Each pixel circuit includes at least one transistor and one capacitor. Any of a variety of elements can be used as the display element. Typically, a light-emitting element (also referred to as a light-emitting device) having a function of emitting light, such as an organic electroluminescent (EL) element or a light-emitting diode (LED) element, a liquid crystal element, a microelectromechanical systems (MEMS) element, or the like can be used.

The source line driver circuit portion 102 is a circuit which is connected to a source line and which outputs a signal to the source line. The source line driver circuit portion 102 can include one or more of a shift register circuit, a sampling switch, a latch circuit, an analog amplifier circuit, and a demultiplexer (DeMUX) circuit.

The gate line driver circuit portion 103 is a circuit which is connected to a gate line and which outputs a signal to the gate line. The gate line driver circuit can include a shift register circuit, an analog amplifier circuit, or the like.

The protection circuit portion 104 has a function of preventing a transistor or the like provided in the pixel circuit from being broken by application of a surge voltage to a gate line, a source line, a capacitor line, a power supply line, or the like due to static electricity or the like. For example, a structure can be employed in which electric charge is released to a common wiring or the like when the surge voltage is applied. The protection circuit can be formed using non-linear elements arranged in parallel with a target wiring therebetween. The non-linear element includes a two-terminal element such as a diode or a three-terminal element such as a transistor. For example, when a gate terminal and a drain terminal of a transistor are connected to each other, the transistor can have characteristics similar to those of a diode.

The touch sensor driver circuit portion 105 has a function of outputting a signal for driving a touch sensor provided in the pixel portion 101 or a touch sensor provided to overlap with the pixel portion 101 and a function of outputting a signal input from the touch sensor. As the touch sensor, any of various types given as follows can be employed: a capacitive type, a resistive type, an infrared type, an electromagnetic induction type, a surface acoustic wave type, and an optical type. In particular, a capacitive sensor or an optical sensor is preferably used. Note that in the case where a touch sensor is not needed, the touch sensor driver circuit portion 105 is not necessarily provided.

Transistors that can be used in the display device of one embodiment of the present invention will be described.

The first is a transistor in which a source electrode and a drain electrode are positioned at different levels with respect to a substrate surface, and a current flowing in the semiconductor layer flows in the height direction. In other words, the channel length direction includes a height (vertical) component, so that the transistor of one embodiment of the present invention can also be referred to as a vertical transistor, a vertical channel transistor, or the like. Hereinafter, the transistor is referred to as a vertical transistor in some cases.

The channel length of a vertical transistor can be accurately controlled by the thickness of an insulating layer functioning as a spacer between a source electrode and a drain electrode. When the insulating layer has a small thickness, the transistor can have an extremely short channel length, whereby a transistor through which a large amount of current can flow in an on state (hereinafter also referred to as an on-state current) can be achieved. Moreover, an oxide semiconductor is used for the semiconductor layer, whereby a leakage current in an off state (hereinafter also referred to as an off-state current) can be extremely small. Thus, a vertical transistor is suitably used as a switching element.

The second is a transistor having a top-gate structure (hereinafter referred to as a TG transistor in some cases) in which a semiconductor layer is provided on a plane and a gate is provided above the semiconductor layer. In one embodiment of the present invention, an oxide semiconductor layer is preferably used as a semiconductor layer of the TG transistor. The channel length of the TG transistor can be long. For this reason, when the transistor operates in a saturation region, a change in source-drain current relative to a change in gate-source voltage can be smaller. For example, when a TG transistor is used as a driving transistor included in the pixel circuit, the amount of current flowing through a light-emitting device can be minutely controlled. Consequently, the number of gray levels expressed by the pixel circuit can be increased. Moreover, a stable current can flow through the light-emitting device even when the electrical characteristics (e.g., resistance) of the light-emitting device change or the electrical characteristics of the light-emitting devices vary.

The third is a transistor in which a crystalline silicon thin film is used for a semiconductor layer. Typically, low temperature polysilicon (LTPS) can be used. Hereinafter, a transistor using LTPS is referred to as an LTPS transistor in some cases. The LTPS transistor has high field-effect mobility and thus can have a high on-state current. Furthermore, with use of LTPS for a semiconductor material of transistors, n-channel transistors and p-channel transistors can be formed in one plane at the same time. Thus, the LTPS transistors can form a CMOS circuit and thus can reduce power consumption when used in a driver circuit or the like. Furthermore, when a p-channel LTPS transistor is used as the driving transistor of a pixel, stable circuit operation can be achieved as compared with the case where the pixel is formed using only an n-channel transistor.

A transistor using single crystal silicon for a semiconductor layer can also be used. A transistor using part of a single crystal silicon substrate for a semiconductor layer has much higher field-effect mobility than an LTPS transistor and is suitable for a driver circuit required to operate at high speed (e.g., the source line driver circuit portion 102 or the touch sensor driver circuit portion 105).

The vertical transistor has a feature of being able to achieve finer miniaturization compared with the TG transistor. The TG transistor has a feature of having a smaller parasitic capacitance than the vertical transistor. The vertical transistor including the oxide semiconductor layer and the LTPS transistor each have a feature of having a higher on-state current than the TG transistor including the oxide semiconductor layer. With use of LTPS as a semiconductor material of transistors, p-channel transistors can be formed easily.

The pixel portion 101 is required to achieve high-luminance display. For this reason, a vertical transistor with a high on-state current is preferably used in the pixel portion 101. Alternatively, a vertical transistor and an LTPS transistor are preferably used.

On the other hand, in the case where the parasitic capacitance between wirings included in the pixel portion 101 is large, the influence of noise between the wirings is large, leading to a reduction in display quality. Thus, in this case, a TG transistor with low parasitic capacitance is preferably used in the pixel portion 101. Alternatively, a TG transistor and an LTPS transistor are preferably used.

The gate line driver circuit portion 103 is required to operate at high speed. Thus, one or both of a vertical transistor and an LTPS transistor, which have high on-state currents, are preferably used in the gate line driver circuit portion 103.

The source line driver circuit portion 102 is required to operate at higher speed than the gate line driver circuit portion 103. Thus, one or more of a vertical transistor, an LTPS transistor, and a transistor using single crystal silicon, which have high on-state currents, are preferably used in the source line driver circuit portion 102.

Any of a vertical transistor, a TG transistor, and an LTPS transistor may be used in the protection circuit portion 104.

Like the gate line driver circuit portion 103, the touch sensor driver circuit portion 105 is required to operate at high speed; thus, one or both of a vertical transistor and an LTPS transistor are preferably used.

Two or more of a vertical transistor, a TG transistor, and an LTPS transistor can be used in the display device 100. In that case, the two or more transistors are preferably fabricated over the same substrate through the same process.

FIG. 1B illustrates an example of a pixel circuit that can be used in the pixel portion 101. FIG. 1B illustrates an example in which a liquid crystal element is used as the display element. The pixel includes a transistor Tr, a capacitor C, and a liquid crystal element LC. A wiring GL, a wiring SL, and a wiring CL are electrically connected to the pixel. The wiring GL functions as a gate line, the wiring SL functions as a source line, and a fixed potential is supplied to the wiring CL.

A gate of the transistor Tr is connected to the wiring GL; one of a source and a drain of the transistor Tr is connected to the wiring SL; and the other of the source and the drain of the transistor Tr is connected to one electrode of the capacitor C and one electrode of the liquid crystal element LC. The other electrode of the capacitor C is connected to the wiring CL. The other electrode of the liquid crystal element LC functions as a common electrode. For example, a vertical transistor can be used as the transistor Tr. The transistor Tr can achieve finer miniaturization when a vertical transistor is used as the transistor Tr than when a TG transistor is used as the transistor Tr; thus, the pixel portion 101 can have high resolution.

When an oxide semiconductor is used for a semiconductor layer of the vertical transistor, the leakage current in an off state can be extremely low. Thus, with use of a vertical transistor including an oxide semiconductor in its semiconductor layer as the transistor Tr, the display device 100 can operate with lower power consumption than in the case where an LTPS transistor is used as the transistor Tr.

Here, for example, in the case where the display device 100 has a structure including both a vertical transistor including an oxide semiconductor in its semiconductor layer and an LTPS transistor, a first layer where the vertical transistor is formed and a second layer where the LTPS transistor is formed need to be stacked. In the first layer, a vertical transistor is preferably provided as the transistor Tr mainly included in the pixel portion 101. Since the vertical transistor has both a high on-state current and a low leakage current, a high voltage can be applied to the liquid crystal element LC and leakage from the capacitor C can be inhibited in the pixel portion 101. In contrast, an LTPS transistor is preferably provided in the second layer as a transistor included in a portion that is required to operate at high speed, such as the gate line driver circuit portion 103 or the source line driver circuit portion 102. That is, in the case where both a vertical transistor and an LTPS transistor are used in the display device 100, the number of LTPS transistors in the second layer is likely to be larger than the number of vertical transistors in the first layer. In other words, the area occupied by the transistors in the first layer is likely to be smaller than the area occupied by the transistors in the second layer.

Thus, components other than the transistor Tr included in the pixel portion 101, such as the capacitor C, are preferably provided in the same first layer not as the LTPS transistor but as the vertical transistor. In that case, an unoccupied space in the first layer in a plan view can be effectively utilized. When the capacitor C is provided in the unoccupied space, a sufficient area occupied by the capacitor can be ensured. Thus, the capacity value can be increased. Since the capacitor C does not need to be formed in the second layer, elements (e.g., transistors) other than the capacitor can be arranged at high density in the second layer. Note that the vertical transistor and the capacitor are preferably provided through some same steps. Thus, the number of steps for the whole display device 100 can be reduced.

Any of elements with various structures can be used as the liquid crystal elements LC included in the display device 100. Typically, a transmissive liquid crystal element employing a vertical alignment (VA) mode, a fringe field switching (FFS) mode, an in-plane switching (IPS) mode, or the like can be used. Instead of a transmissive liquid crystal element, a reflective liquid crystal element or a transflective liquid crystal element may be used as the liquid crystal element. The display device is preferably a normally black liquid crystal display device.

Examples of the VA mode include a multi-domain vertical alignment (MVA) mode, a patterned vertical alignment (PVA) mode, and an advanced super view (ASV) mode.

The liquid crystal element LC can employ a variety of modes. The liquid crystal element can employ, for example, a twisted nematic (TN) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an electrically controlled birefringence (ECB) mode, or a guest-host mode, in addition to the VA mode, an FFS mode, and an IPS mode.

Here, the liquid crystal display device is a display device that controls transmission and non-transmission of light by utilizing polarized light and an optical modulation action of a liquid crystal. The optical modulation action of a liquid crystal is controlled by an electric field applied to the liquid crystal (including a horizontal electric field, a vertical electric field, or an oblique electric field). As the liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions. As the liquid crystal material, a positive liquid crystal or a negative liquid crystal may be used, and an appropriate liquid crystal material may be used depending on the mode and design to be used.

### [Pixel Structure Example]

Structure examples of a pixel that can be used for the pixel portion 101 are described below.

### Structure Example 1

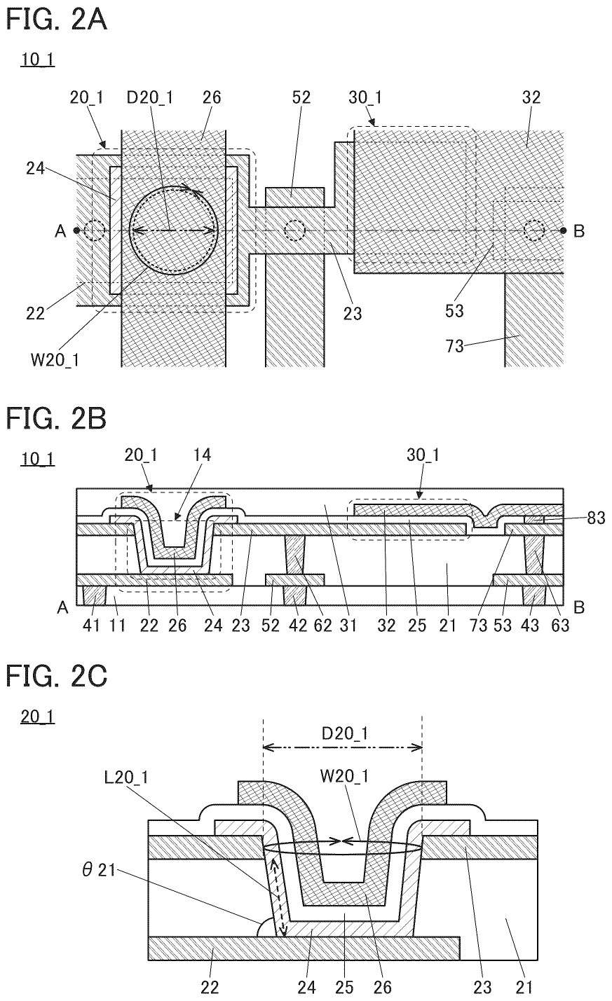

FIG. 2A is a plan view (also referred to as a top view) of a semiconductor device 10_1 included in the pixel. FIG. 2B is a cross-sectional view along the dashed-dotted line A-B in FIG. 2A. FIG. 2C is an enlarged cross-sectional view of a transistor 20_1 included in the semiconductor device 10_1 illustrated in FIG. 2B. Note that in FIG. 2A, some components (e.g., an insulating layer) of the semiconductor device 10_1 are not illustrated. As in FIG. 2A, some components are not illustrated in the following plan views of semiconductor devices and the like.

The semiconductor device 10_1 includes the transistor 20_1 and a capacitor 30_1 over an insulating layer 11 over a substrate (not illustrated).

The transistor 20_1 includes a conductive layer 22 functioning as one of a source electrode and a drain electrode, a conductive layer 23 functioning as the other of the source electrode and the drain electrode, a semiconductor layer 24, an insulating layer 25 functioning as a gate insulating layer, and a conductive layer 26 functioning as a gate electrode. The transistor 20_1 is a vertical transistor in which a source electrode and a drain electrode are positioned at different levels, and a current flowing in a semiconductor layer flows in the height direction.

The capacitor 30_1 includes the conductive layer 23 functioning as one electrode, a conductive layer 32 functioning as the other electrode, and the insulating layer 25 functioning as a dielectric.

As described above, the conductive layer 23 can function as the other of the source electrode and the drain electrode of the transistor 20_1 and also function as one electrode of the capacitor 30_1. The insulating layer 25 can function as a gate insulating layer of the transistor 20_1 and also function as a dielectric of the capacitor 30_1. It can be said that part of the conductive layer 23 functions as the other of the source electrode and the drain electrode of the transistor 20_1 and another part thereof functions as the one electrode of the capacitor 30_1. It can be said that part of the insulating layer 25 functions as a gate insulating layer of the transistor 20_1 and another part thereof functions as the dielectric of the capacitor 30_1. When some components are shared by the transistor 20_1 and the capacitor 30_1 in the semiconductor device 10_1, the number of steps for manufacturing the semiconductor device 10_1 can be reduced.

The structure of the semiconductor device 10_1 is described in detail.

The conductive layer 22, a conductive layer 52, and a conductive layer 53 are provided over the insulating layer 11. An insulating layer 21 is provided over the insulating layer 11, the conductive layer 22, the conductive layer 52, and the conductive layer 53. In the insulating layer 21, a conductive layer 62 is provided to include a region overlapping with the conductive layer 52 and a conductive layer 63 is provided to include a region overlapping with the conductive layer 53. The conductive layer 62 and the conductive layer 63 are provided to be embedded in the insulating layer 21. The top surfaces of the conductive layer 62, the conductive layer 63, and the insulating layer 21 are substantially level with each other. The conductive layer 23 and a conductive layer 73 are provided over the insulating layer 21. The conductive layer 23 is provided to include a region overlapping with the conductive layer 22 and the conductive layer 52. The conductive layer 73 is provided so as to include a region overlapping with the conductive layer 53. The conductive layer 23 includes a region in contact with a top surface of the conductive layer 62 and a region in contact with part of a top surface of the insulating layer 21. The conductive layer 73 includes a region in contact with a top surface of the conductive layer 63 and a region in contact with another part of the top surface of the insulating layer 21. The conductive layer 23 and the conductive layer 73 can be formed at the same time by processing the same material. The conductive layer 22, the conductive layer 52, and the conductive layer 53 can be formed at the same time by processing the same material.

An opening 14 reaching the conductive layer 22 is provided in the conductive layer 23 and the insulating layer 21. The semiconductor layer 24 is provided in contact with the sidewall of the opening 14 (i.e., a side surface of the conductive layer 23 and a side surface of the insulating layer 21 in the opening 14), the bottom surface of the opening 14 (i.e., a top surface of the conductive layer 22 in the opening 14), and a top surface of the conductive layer 23. The insulating layer 25 is provided over the semiconductor layer 24, the conductive layer 23, the conductive layer 73, and the insulating layer 21. The insulating layer 25 includes a region in contact with a top surface and a side surface of the semiconductor layer 24, a region in contact with the top surface and the side surface of the conductive layer 23, a region in contact with the top surface and a side surface of the conductive layer 73, and a region in contact with the top surface of the insulating layer 21.

A conductive layer 83 is provided in the insulating layer 25 so as to include a region overlapping with the conductive layer 73. The conductive layer 83 is provided to be embedded in the insulating layer 25.

The conductive layer 26 and the conductive layer 32 are provided over the insulating layer 25. The conductive layer 26 is provided to include a region overlapping with the conductive layer 22 and the semiconductor layer 24. That is, the conductive layer 26 is provided so that at least part of the conductive layer 26 is positioned in the opening 14 provided in the conductive layer 23 and the insulating layer 21. The conductive layer 32 is provided to include a region overlapping with the conductive layer 23 and the conductive layer 73. The conductive layer 32 includes a region in contact with the top surface of the conductive layer 83.

An insulating layer 31 is provided over the conductive layer 26, the conductive layer 32, and the insulating layer 25. The insulating layer 31 is provided to fill unevenness of the transistor 20_1 and the capacitor 30_1.

A region of the semiconductor layer 24 that is in contact with the conductive layer 22 functions as one of a source region and a drain region of the transistor 20_1. A region of the semiconductor layer 24 that is in contact with the conductive layer 23 functions as the other of the source region and the drain region of the transistor 20_1. A region of the semiconductor layer 24 that is sandwiched between the source region and the drain region functions as a channel formation region. That is, a region of the semiconductor layer 24 in contact with the side surface of the insulating layer 21, which is a side wall of the opening 14 provided in the conductive layer 23 and the insulating layer 21, functions as a channel formation region. In the opening 14, the semiconductor layer 24 includes a region facing the conductive layer 26 with the insulating layer 25 therebetween.

Note that although there is no limitation on a semiconductor used for the semiconductor layer 24, it is particularly preferable to use an oxide semiconductor. Description is given below of the case where an oxide semiconductor is used for the semiconductor layer 24 unless otherwise specified.

A conductive layer 41, a conductive layer 42, and a conductive layer 43 are provided in the insulating layer 11. The conductive layer 41, the conductive layer 42, and the conductive layer 43 are provided to be embedded in the insulating layer 11. The conductive layer 41 is provided to include a region overlapping with the conductive layer 22. The conductive layer 42 is provided to include a region overlapping with the conductive layer 52. The conductive layer 43 is provided to include a region overlapping with the conductive layer 53. Top surfaces of the conductive layer 41, the conductive layer 42, the conductive layer 43, and the insulating layer 11 are substantially level with each other.

For example, in the pixel circuit illustrated in FIG. 1B, the conductive layer 41 functions as a plug that connects the wiring SL to one of a source electrode and a drain electrode of the transistor Tr. The conductive layer 42 and the conductive layer 62 function as a plug that connects the other of the source electrode and the drain electrode of the transistor Tr and the one electrode of the capacitor C to the one electrode of the liquid crystal element LC through the conductive layer 52. The conductive layer 43, the conductive layer 63, and the conductive layer 83 function as a plug that connects the wiring CL to the other electrode of the capacitor C through the conductive layer 53 and the conductive layer 73.

The channel length and the channel width of the transistor 20_1, which is a vertical transistor, are described with reference to FIG. 2C.

The channel length of the transistor 20_1 is a distance between the source region and the drain region. In FIG. 2C, the channel length L20_1 of the transistor 20_1 is indicated by a dashed double-headed arrow. In FIG. 2C, the distance between the conductive layer 22 and the conductive layer 23 along the semiconductor layer 24 is denoted by the channel length L20_1 of the transistor 20_1.

Note that the thickness of the insulating layer 21 in a region between the conductive layer 22 and the conductive layer 23 is used as the channel length L20_1 of the transistor 20_1 in some cases. Alternatively, the thickness of the thickest region of the insulating layer 21 is sometimes used as the channel length L20_1 of the transistor 20_1. Alternatively, the sum of the thickness of the insulating layer 21 in the region between the conductive layer 22 and the conductive layer 23 and the thickness of the conductive layer 23 is sometimes used as the channel length L20_1 of the transistor 20_1.

Here, the channel length L20_1 of the transistor 20_1 is determined by the thickness of the insulating layer 21, the thickness of the conductive layer 23, the angle θ21 formed by the sidewall of the opening 14 formed in the conductive layer 23 and the insulating layer 21 (here, the side surface of the insulating layer 21 in the opening 14), a bottom surface of the opening 14 (here, the top surface of the conductive layer 22 in the opening 14), and the like, and is not affected by the performance of the light-exposure apparatus used for fabricating the transistor. Hence, the channel length L20_1 can be a smaller value than the resolution limit of the light-exposure apparatus and thus the transistor can be miniaturized.

The channel length L20_1 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. For example, the channel length L20_1 can be greater than or equal to 100 nm and less than or equal to 1 μm. When the channel length L20_1 is small, the transistor 20_1 can have a high on-state current.

The angle θ21 can be, for example, greater than or equal to 30° and less than or equal to 90°, greater than or equal to 35° and less than or equal to 85°, greater than or equal to 40° and less than or equal to 80°, greater than or equal to 45° and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. The angle θ21 is preferably smaller, in which case coverage with a layer (e.g., the semiconductor layer 24) formed along the sidewall of the opening 14 formed in the conductive layer 23 and the insulating layer 21 can be improved. Meanwhile, the angle θ21 closer to 90° is preferable, in which case the area in the substrate plane occupied by the transistor can be reduced.

The channel width of the transistor 20_1 is the length of the source region or the length of the drain region in the plan view (FIG. 2A). In other words, the channel width of the transistor 20_1 is the length of a region where the semiconductor layer 24 and the conductive layer 22 are in contact with each other or the length of a region where the semiconductor layer 24 and the conductive layer 23 are in contact with each other in the plan view. Alternatively, as the channel width of the transistor 20_1, an intermediate value between the length of the region where the semiconductor layer 24 and the conductive layer 22 are in contact with each other in the plan view and the length of the region where the semiconductor layer 24 and the conductive layer 23 are in contact with each other in the plan view is used in some cases.

Here, the channel width of the transistor 20_1 is described as the length of the perimeter of a region where the semiconductor layer 24 and the side surface of the conductive layer 23 are in contact with each other in the opening 14 formed in the conductive layer 23 and the insulating layer 21. In FIGS. 2A and 2C, a channel width W20_1 of the transistor 20_1 is indicated by the solid line double-headed arrow. The channel width W20_1 can also be referred to as the perimeter of the opening 14 in the plan view.

The channel width W20_1 is determined by the top surface shape of the opening 14, for example. In FIGS. 2A to 2C, a width D20_1 of the opening 14 is indicated by a dashed-two-dotted double-headed arrow. The width D20_1 is the shorter side of the smallest rectangle circumscribing the opening 14 in the plan view. In the case where the opening 14 is formed by a photolithography method, the width D20_1 of the opening 14 is larger than or equal to the resolution limit of a light-exposure apparatus. The width D20_1 is, for example, greater than or equal to 0.20 μm and less than 5.0 μm. Note that when the top surface shape of the opening 14 is circular, the width D20_1 corresponds to the diameter of the opening 14, and the channel width W20_1 can be calculated to be “D20_1×π”.

Note that the top surface shape of the opening 14 can be circular or elliptic, for example. Examples of the top surface shape of the opening 14 include polygons such as a triangle, a tetragon (including a rectangle, a rhombus, and a square), and a pentagon; and polygons with rounded corners. The top surface shape of the opening 14 is preferably circular as illustrated in FIG. 2A. When the top surface of the opening 14 has a circular shape, high processing accuracy to form the opening 14 in a minute size is possible. Note that in this specification and the like, a circular shape is not necessarily a perfect circular shape.

### Structure Example 2

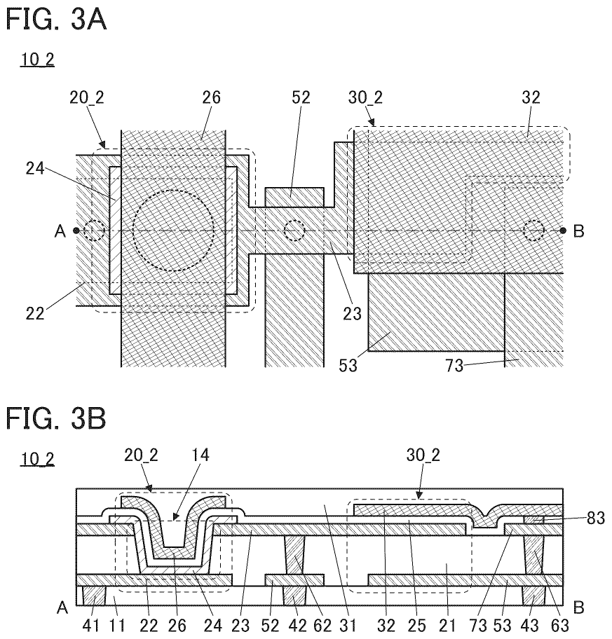

FIGS. 3A and 3B illustrate a semiconductor device 10_2 having a structure different from that of the semiconductor device 10_1 illustrated in FIGS. 2A and 2B. FIG. 3A is a plan view of the semiconductor device 10_2. FIG. 3B is a cross-sectional view taken along the dashed dotted line A-B illustrated in FIG. 3A.

The semiconductor device 10_2 includes a transistor 20_2 and a capacitor 30_2. For the transistor 20_2, the description of the transistor 20_1 included in the semiconductor device 10_1 can be referred to. The structure of the capacitor 30_2 in the semiconductor device 10_2 is different from that of the capacitor 30_1 in the semiconductor device 10_1.

Specifically, in the semiconductor device 10_2, the conductive layer 53 is provided to extend toward the A side of the dashed-dotted line A-B as compared with the conductive layer 53 in the semiconductor device 10_1, and the capacitor 30_2 includes the insulating layer 21 and the conductive layer 53 in addition to the components included in the capacitor 30_1.

In the capacitor 30_2, a region where the conductive layer 23, the insulating layer 25, and the conductive layer 32 overlap with each other can function as a capacitor (a first capacitor), as in the capacitor 30_1. In the capacitor 30_2, a region where the conductive layer 53, the insulating layer 21, and the conductive layer 23 overlap with each other can also function as a capacitor (a second capacitor).

That is, the capacitance value of the capacitor 30_2 can be larger than that of the capacitor 30_1 by the capacitance of the second capacitor because the capacitor 30_2 includes the second capacitor. As in the description of the semiconductor device 10_1, the conductive layer 53 functions as part of a conductive layer that connects the one electrode of the capacitor C and the one electrode of the liquid crystal element LC in the pixel circuit illustrated in FIG. 1B. Thus, in the semiconductor device 10_2, the conductive layer 53 functions both as part of the conductive layer and as one electrode of the second capacitor. The insulating layer 21 functions both as a spacer between the source electrode and the drain electrode of the transistor 20_2 and as a dielectric forming the second capacitor. Therefore, the number of steps can be reduced as compared with the case where the part of the conductive layer and the capacitor 30_2 are formed separately.

For the contents of the semiconductor device 10_2 other than what is described in <Structure example 2>, the description of the semiconductor device 10_1 illustrated in FIGS. 2A and 2B can be referred to.

### Structure Example 3

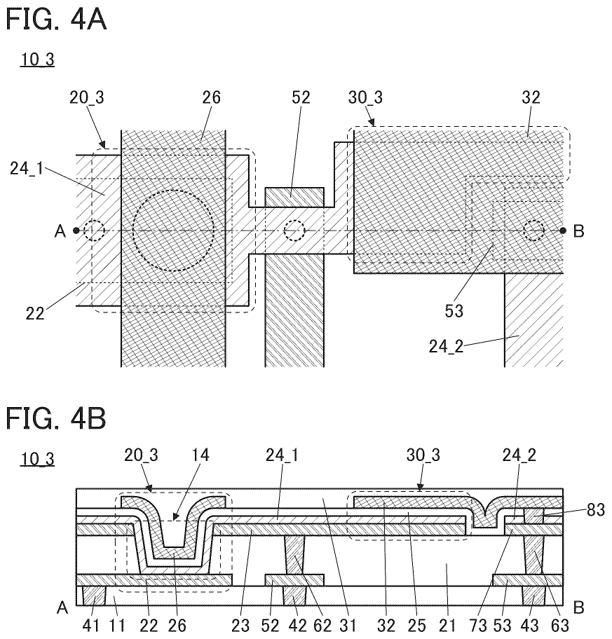

FIGS. 4A and 4B illustrate a semiconductor device 10_3 having a structure different from that of the semiconductor device 10_1 illustrated in FIGS. 2A and 2B. FIG. 4A is a plan view of the semiconductor device 10_3. FIG. 4B is a cross-sectional view taken along the dashed dotted line A-B illustrated in FIG. 4A.

The semiconductor device 10_3 includes a transistor 20_3 and a capacitor 30_3. The semiconductor device 10_3 is different from the semiconductor device 10_1 in the structure of the semiconductor layer.

Specifically, the semiconductor device 10_3 includes a semiconductor layer 24_1 provided over the conductive layer 23 and a semiconductor layer 24_2 provided over the conductive layer 73. In a plan view (FIG. 4A), an end portion of the semiconductor layer 24_1 is aligned with an end portion of the conductive layer 23. An end portion of the semiconductor layer 24_2 is aligned with an end portion of the conductive layer 73. Thus, the semiconductor layer 24_1 and the conductive layer 23 can be collectively formed using the same mask, and the semiconductor layer 24_2 and the conductive layer 73 can be collectively formed using the same mask. Accordingly, the conductive layer 23, the conductive layer 73, and the semiconductor layer 24 do not need to be formed separately as in the semiconductor device 10_1; hence, the number of steps can be reduced.

The capacitor 30_3 includes the semiconductor layer 24_1 and the insulating layer 25 between the conductive layer 23 and the conductive layer 32. Thus, in the capacitor 30_3, the semiconductor layer 24_1 and the insulating layer 25 in a region between the conductive layer 23 and the conductive layer 32 function as dielectrics. That is, the semiconductor layer 24_1 in a region overlapping with the transistor 20_3 functions as a semiconductor layer of the transistor and the semiconductor layer 24_1 in a region overlapping with the capacitor 30_3 functions as a dielectric of the capacitor.

For the contents of the semiconductor device 10_3 other than what is described in <Structure example 3>, the description of the semiconductor device 10_1 illustrated in FIGS. 2A and 2B can be referred to.

### Structure Example 4

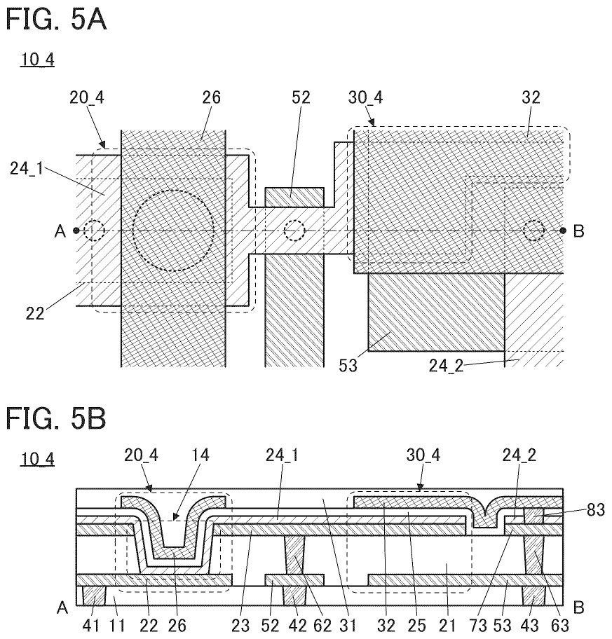

FIGS. 5A and 5B illustrate a semiconductor device 10_4 having a structure different from that of the semiconductor device 10_1 illustrated in FIGS. 2A and 2B. FIG. 5A is a plan view of the semiconductor device 10_4. FIG. 5B is a cross-sectional view taken along the dashed dotted line A-B illustrated in FIG. 5A.

The semiconductor device 10_4 includes a transistor 20_4 and a capacitor 30_4. The semiconductor device 10_4 has a structure in which the semiconductor device 10_2 illustrated in FIGS. 3A and 3B and the semiconductor device 10_3 illustrated in FIGS. 4A and 4B are combined.

Specifically, as in the semiconductor device 10_2, the conductive layer 53 in the semiconductor device 10_4 is provided to extend toward the A side of the dashed-dotted line A-B as compared with the conductive layer 53 in the semiconductor device 10_1. Furthermore, as in the semiconductor device 10_3, the semiconductor device 10_4 includes the semiconductor layer 24_1 provided over the conductive layer 23 and the semiconductor layer 24_2 provided over the conductive layer 73.

The semiconductor device 10_4 with the above structure can provide the effect similar to the effects of the semiconductor device 10_2 and the semiconductor device 10_3.

For the contents of the semiconductor device 10_4 other than what is described in <Structure example 4>, the description of the semiconductor device 10_1 illustrated in FIGS. 2A and 2B, the semiconductor device 10_2 illustrated in FIGS. 3A and 3B, and the semiconductor device 10_3 illustrated in FIGS. 4A and 4B can be referred to.

### Structure Example 5

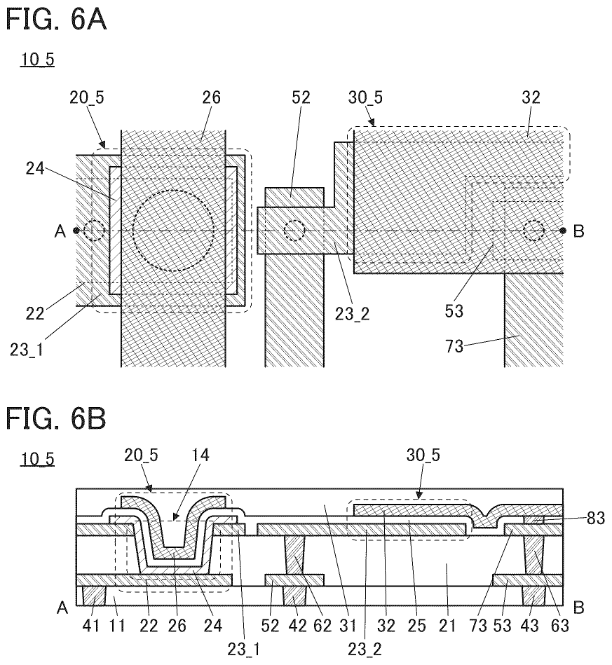

FIGS. 6A and 6B illustrate a semiconductor device 10_5 having a structure different from that of the semiconductor device 10_1 illustrated in FIGS. 2A and 2B. FIG. 6A is a plan view of the semiconductor device 10_5. FIG. 6B is a cross-sectional view taken along the dashed dotted line A-B illustrated in FIG. 6A.

The semiconductor device 10_5 includes a transistor 20_5 and a capacitor 30_5. The semiconductor device 10_5 is different from the semiconductor device 10_1 in which the same conductive layer (the conductive layer 23) is shared between the transistor 20_1 and the capacitor 30_1 in that a conductive layer functioning as the other of a source electrode and a drain electrode of the transistor 20_5 and a conductive layer functioning as one electrode of the capacitor 30_5 are separately formed.

The transistor 20_5 includes a conductive layer 23_1 as a conductive layer functioning as the other of the source electrode and the drain electrode. The capacitor 30_5 includes a conductive layer 23_2 as a conductive layer functioning as one electrode.

In the case of this structure, for example, the conductive layer 41 and the conductive layer 42 are connected to each other in a layer below the insulating layer 11 (not illustrated), whereby the transistor 20_5 can function as the transistor Tr in the pixel circuit illustrated in FIG. 1B and the capacitor 30_5 can function as the capacitor C in the pixel circuit illustrated in FIG. 1B. In that case, the source electrode and the drain electrode are interchanged between the transistor 20_1 included in the semiconductor device 10_1 and the transistor 20_5 included in the semiconductor device 10_5. Furthermore, one electrode and the other electrode are interchanged between the capacitor 30_1 included in the semiconductor device 10_1 and the capacitor 30_5 included in the semiconductor device 10_5.

For the contents of the semiconductor device 10_5 other than what is described in <Structure example 5>, the description of the semiconductor device 10_1 illustrated in FIGS. 2A and 2B can be referred to.

### Structure Example 6

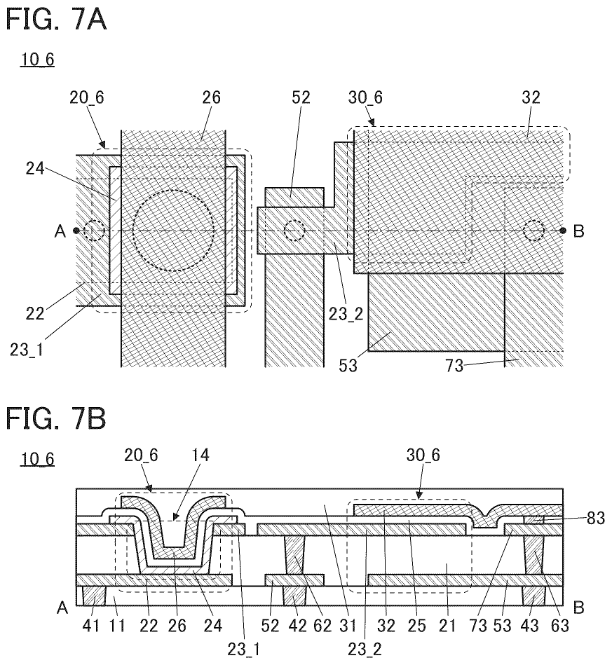

FIGS. 7A and 7B illustrate a semiconductor device 10_6 having a structure different from that of the semiconductor device 10_1 illustrated in FIGS. 2A and 2B. FIG. 7A is a plan view of the semiconductor device 10_6. FIG. 7B is a cross-sectional view taken along the dashed dotted line A-B illustrated in FIG. 7A.

The semiconductor device 10_6 includes a transistor 20_6 and a capacitor 30_6. The semiconductor device 10_6 has a structure in which the semiconductor device 10_2 illustrated in FIGS. 3A and 3B and the semiconductor device 10_5 illustrated in FIGS. 6A and 6B are combined.

Specifically, as in the semiconductor device 10_2, the conductive layer 53 in the semiconductor device 10_6 is provided to extend toward the A side of the dashed-dotted line A-B as compared with the conductive layer 53 in the semiconductor device 10_1. As in the semiconductor device 10_5, the conductive layer 23_1 functioning as the other of the source electrode and the drain electrode of the transistor and the conductive layer 23_2 functioning as one electrode of the capacitor are separately formed.

The semiconductor device 10_6 with the above structure can provide the effect similar to the effects of the semiconductor device 10_2 and the semiconductor device 10_5.

For the contents of the semiconductor device 10_6 other than what is described in <Structure example 6>, the description of the semiconductor device 10_1 illustrated in FIGS. 2A and 2B, the semiconductor device 10_2 illustrated in FIGS. 3A and 3B, and the semiconductor device 10_5 illustrated in FIGS. 6A and 6B can be referred to.

### Structure Example 7

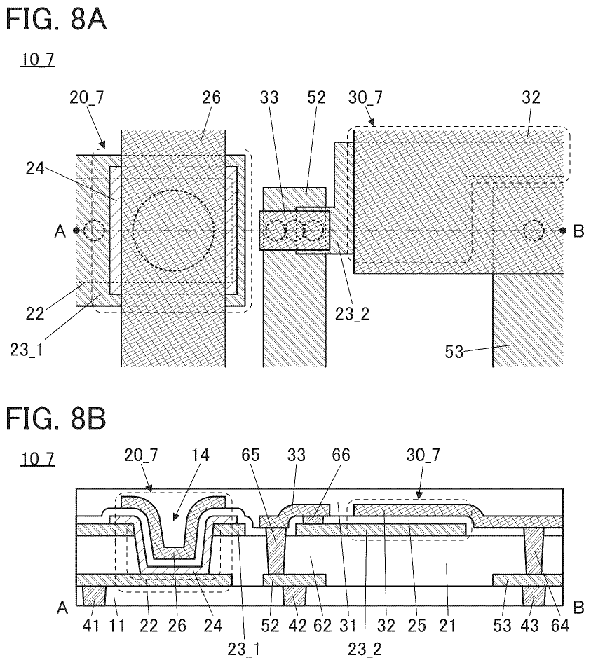

FIGS. 8A and 8B illustrate a semiconductor device 10_7 having a structure different from that of the semiconductor device 10_5 illustrated in FIGS. 6A and 6B. FIG. 8A is a plan view of the semiconductor device 10_7. FIG. 8B is a cross-sectional view taken along the dashed dotted line A-B illustrated in FIG. 8A.

The semiconductor device 10_7 includes a transistor 20_7 and a capacitor 30_7. The semiconductor device 10_7 is different from the semiconductor device 10_5 in a method for connecting the conductive layer 52 and the conductive layer 23_2 and a method for connecting the conductive layer 53 and the conductive layer 32.

Specifically, in the semiconductor device 10_7, the conductive layer 52 and the conductive layer 23_2 are connected to each other through a conductive layer 65, a conductive layer 33, and a conductive layer 66. Furthermore, the conductive layer 53 and the conductive layer 32 are connected to each other through a conductive layer 64.

The conductive layer 65 is formed to fill an opening provided in the insulating layer 25 and the insulating layer 21 and includes a region in contact with a top surface of the conductive layer 52. The conductive layer 66 is formed to fill another opening provided in the insulating layer 25 and includes a region in contact with a top surface of the conductive layer 23_2. The conductive layer 33 is provided over the insulating layer 25 to include a region overlapping with the conductive layer 65 and the conductive layer 66. The conductive layer 33 includes a region in contact with a top surface of the conductive layer 65, a top surface of the conductive layer 66, and a top surface of the insulating layer 25. The conductive layer 65 and the conductive layer 66 function as plugs that connect the conductive layer 52 to the conductive layer 23_2 through the conductive layer 33. The conductive layer 26, the conductive layer 33, and the conductive layer 32 can be formed at the same time by processing the same material.

The conductive layer 64 is formed to fill an opening (different from the opening provided with the conductive layer 65) provided in the insulating layer 25 and the insulating layer 21 and includes a region in contact with a top surface of the conductive layer 53. The conductive layer 32 is provided over the insulating layer 25 to include a region overlapping with the conductive layer 64. The conductive layer 32 includes a region in contact with a top surface of the conductive layer 64 and the top surface of the insulating layer 25. The conductive layer 64 functions as a plug that connects the conductive layer 53 to the conductive layer 32. The conductive layer 64 and the conductive layer 65 can be formed at the same time by processing the same material.

For the contents of the semiconductor device 10_7 other than what is described in <Structure example 2>, the description of the semiconductor device 10_5 illustrated in FIGS. 6A and 6B can be referred to.

### Structure Example 8

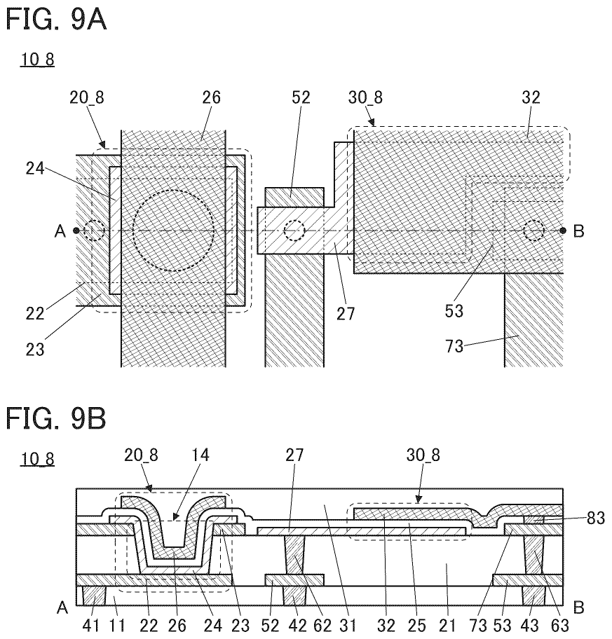

FIGS. 9A and 9B illustrate a semiconductor device 10_8 having a structure different from that of the semiconductor device 10_5 illustrated in FIGS. 6A and 6B. FIG. 9A is a plan view of the semiconductor device 10_8. FIG. 9B is a cross-sectional view taken along the dashed dotted line A-B illustrated in FIG. 9A.

The semiconductor device 10_8 includes a transistor 20_8 and a capacitor 30_8. The semiconductor device 10_8 is different from the semiconductor device 10_5 in that the semiconductor layer 27 is used as a component functioning as one electrode of the capacitor 30_8.

The semiconductor layer 27 is provided over the insulating layer 21 to include a region overlapping with the conductive layer 32. The semiconductor layer 27 is in contact with the top surface of the conductive layer 62 and the top surface of the insulating layer 21. The semiconductor layer 27 has the same shape as the conductive layer 23_2 included in the semiconductor device 10_5 in the plan view (FIG. 9A), and is placed in a position corresponding to the conductive layer 23_2. That is, the semiconductor device 10_8 has a structure in which the conductive layer 23_2 in the semiconductor device 10_5 is replaced with the semiconductor layer 27. In the semiconductor device 10_8, the semiconductor layer 24 and the semiconductor layer 27 can be formed at the same time by processing the same material.

In the capacitor 30_8 included in the semiconductor device 10_8, the semiconductor layer 27 functions as one electrode and thus preferably has high conductivity. For example, it is preferable that the semiconductor layer 24 and the semiconductor layer 27 be formed into island shapes by processing the same semiconductor material and then an impurity such as hydrogen be added only to the semiconductor layer 27 to reduce the resistance. Thus, the semiconductor layer 27 can function as the one electrode of the capacitor 30_8.

For the contents of the semiconductor device 10_8 other than what is described in <Structure example 8>, the description of the semiconductor device 10_5 illustrated in FIGS. 6A and 6B can be referred to.

### Structure Example 9

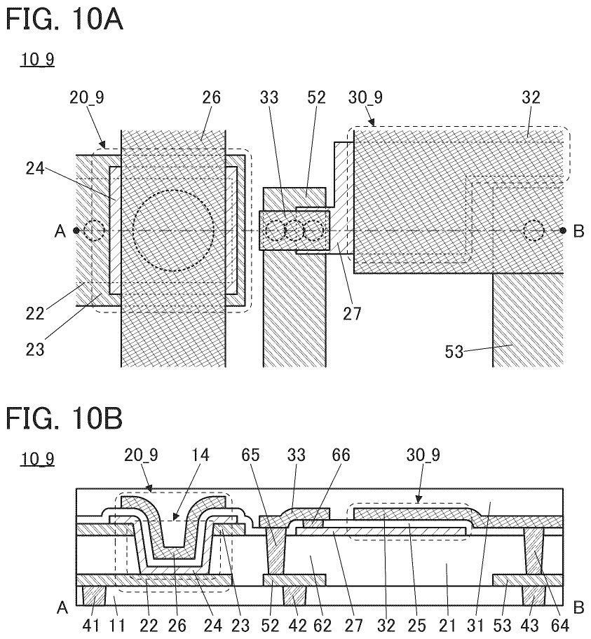

FIGS. 10A and 10B illustrate a semiconductor device 10_9 having a structure different from that of the semiconductor device 10_1 illustrated in FIGS. 2A and 2B. FIG. 10A is a plan view of the semiconductor device 10_9. FIG. 10B is a cross-sectional view taken along the dashed dotted line A-B illustrated in FIG. 10A.

The semiconductor device 10_9 includes a transistor 20_9 and a capacitor 30_9. The semiconductor device 10_9 has a structure in which the semiconductor device 10_7 illustrated in FIGS. 8A and 8B and the semiconductor device 10_8 illustrated in FIGS. 9A and 9B are combined.

Specifically, like the semiconductor device 10_7, the semiconductor device 10_9 includes the conductive layer 65, the conductive layer 33, and the conductive layer 66 that connect the conductive layer 52 and one electrode of the capacitor. Furthermore, like the semiconductor device 10_8, the semiconductor device 10_9 includes the semiconductor layer 27 functioning as the one electrode of the capacitor.

The semiconductor device 10_9 with the above structure can provide the effect similar to the effects of the semiconductor device 10_7 and the semiconductor device 10_8.

For the contents of the semiconductor device 10_9 other than what is described in <Structure example 9>, the description of the semiconductor device 10_1 illustrated in FIGS. 2A and 2B, the semiconductor device 10_7 illustrated in FIGS. 8A and 8B, and the semiconductor device 10_8 illustrated in FIGS. 9A and 9B can be referred to.

### Structure Example 10

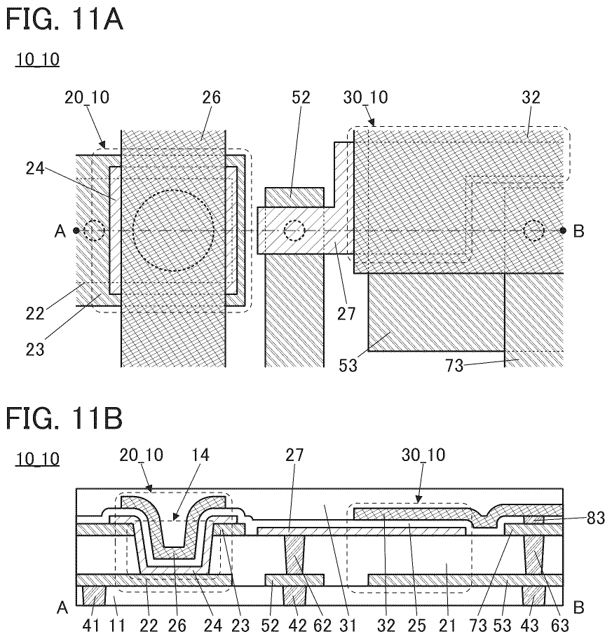

FIGS. 11A and 11B illustrate a semiconductor device 10_10 having a structure different from that of the semiconductor device 10_1 illustrated in FIGS. 2A and 2B. FIG. 11A is a plan view of the semiconductor device 10_10. FIG. 11B is a cross-sectional view taken along the dashed dotted line A-B illustrated in FIG. 11A.

The semiconductor device 10_10 includes a transistor 20_10 and a capacitor 30_10. The semiconductor device 10_10 has a structure in which the semiconductor device 10_2 illustrated in FIGS. 3A and 3B and the semiconductor device 10_8 illustrated in FIGS. 9A and 9B are combined.

Specifically, as in the semiconductor device 10_2, the conductive layer 53 in the semiconductor device 10_9 is provided to extend toward the A side of the dashed-dotted line A-B as compared with the conductive layer 53 in the semiconductor device 10_1. Furthermore, like the semiconductor device 10_8, the semiconductor device 10_9 includes the semiconductor layer 27 functioning as the one electrode of the capacitor.

The semiconductor device 10_10 with the above structure can provide the effect similar to the effects of the semiconductor device 10_2 and the semiconductor device 10_8.

For the contents of the semiconductor device 10_10 other than what is described in <Structure example 10>, the description of the semiconductor device 10_1 illustrated in FIGS. 2A and 2B, the semiconductor device 10_2 illustrated in FIGS. 3A and 3B, and the semiconductor device 10_8 illustrated in FIGS. 9A and 9B can be referred to.

### Structure Example 11

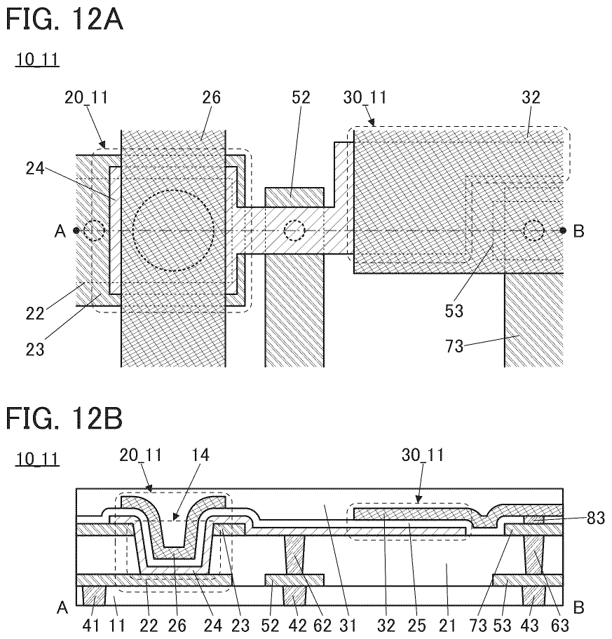

FIGS. 12A and 12B illustrate a semiconductor device 10_11 having a structure different from that of the semiconductor device 10_1 illustrated in FIGS. 2A and 2B. FIG. 12A is a plan view of the semiconductor device 10_11. FIG. 12B is a cross-sectional view taken along the dashed dotted line A-B illustrated in FIG. 12A.

The semiconductor device 10_11 includes a transistor 20_11 and a capacitor 30_11. The semiconductor device 10_11 is different from the semiconductor device 10_1 in that the semiconductor layer 24 is provided to extend toward the B side of the dashed-dotted line A-B compared with the semiconductor device 10_1 and that the capacitor 30_11 does not include the conductive layer 23.

In the semiconductor device 10_11, the semiconductor layer 24 includes not only a region overlapping with the transistor 20_11 but also a region overlapping with the capacitor 30_11. The semiconductor layer 24 includes a region in contact with a side wall of the opening 14 provided in the conductive layer 23 and the insulating layer 21 (i.e., the side surface of the conductive layer 23 in the opening 14 and the side surface of the insulating layer 21 in the opening 14) and a region in contact with the bottom surface of the opening 14 (i.e., the top surface of the conductive layer 22 in the opening 14). The semiconductor layer 24 further includes a region in contact with the top surface of the conductive layer 23, a region in contact with a side surface of the conductive layer 23 which does not face the opening 14, and a region in contact with the top surface of the insulating layer 21. Furthermore, the semiconductor layer 24 includes a region overlapping with the conductive layer 32 with the insulating layer 25 therebetween.

In the semiconductor device 10_11, the semiconductor layer 24 in the region overlapping with the transistor 20_11 functions as a semiconductor layer of the transistor and the semiconductor layer 24 in the region overlapping with the capacitor 30_11 functions as one electrode of the capacitor.

When the semiconductor device 10_11 has the above structure, the semiconductor layer of the transistor 20_11 and the one electrode of the capacitor 30_11 do not need to be processed separately; hence, the number of steps can be reduced.

Note that in the semiconductor layer 24, the region overlapping with the conductive layer 32 functions as the one electrode of the capacitor 30_11 and thus preferably has high conductivity. For example, it is preferable that the semiconductor layer 24 be formed and then an impurity such as hydrogen be added only to the region in the semiconductor layer 24 overlapping with the capacitor 30_11 to reduce the resistance. Thus, the region in the semiconductor layer 24 can function as the one electrode of the capacitor 30_11.

For the contents of the semiconductor device 10_11 other than what is described in <Structure example 11>, the description of the semiconductor device 10_1 illustrated in FIGS. 2A and 2B can be referred to.

### Structure Example 12

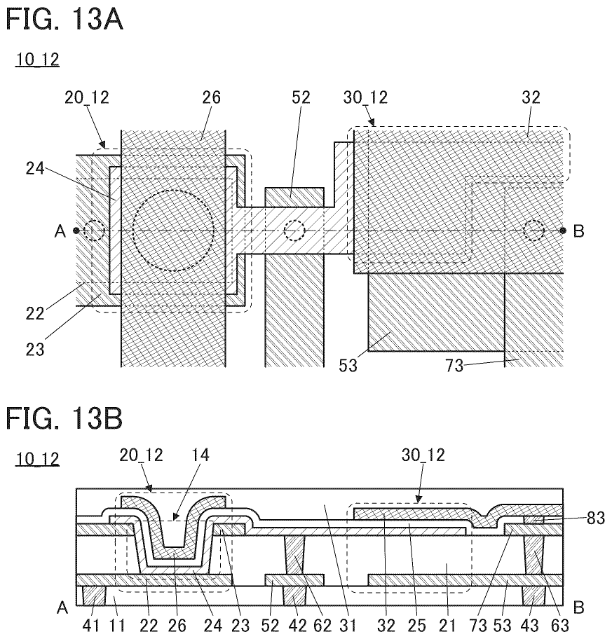

FIGS. 13A and 13B illustrate a semiconductor device 10_12 having a structure different from that of the semiconductor device 10_1 illustrated in FIGS. 2A and 2B. FIG. 13A is a plan view of the semiconductor device 10_12. FIG. 13B is a cross-sectional view taken along the dashed dotted line A-B illustrated in FIG. 13A.

The semiconductor device 10_12 includes a transistor 20_12 and a capacitor 30_12. The semiconductor device 10_12 has a structure in which the semiconductor device 10_2 illustrated in FIGS. 3A and 3B and the semiconductor device 10_11 illustrated in FIGS. 12A and 12B are combined.

Specifically, as in the semiconductor device 10_2, the conductive layer 53 in the semiconductor device 10_12 is provided to extend toward the A side of the dashed-dotted line A-B as compared with the conductive layer 53 in the semiconductor device 10_1. In the semiconductor device 10_12, the semiconductor layer 24 is provided to extend toward the B side of the dashed-dotted line A-B as compared with the semiconductor layer 24 in the semiconductor device 10_1 as in the semiconductor device 10_11, and the capacitor 30_12 does not include the conductive layer 23.

The semiconductor device 10_12 with the above structure can provide the effect similar to the effects of the semiconductor device 10_2 and the semiconductor device 10_11.

For the contents of the semiconductor device 10_12 other than what is described in <Structure example 12>, the description of the semiconductor device 10_1 illustrated in FIGS. 2A and 2B, the semiconductor device 10_2 illustrated in FIGS. 3A and 3B, and the semiconductor device 10_11 illustrated in FIGS. 12A and 12B can be referred to.

### Structure Example 13

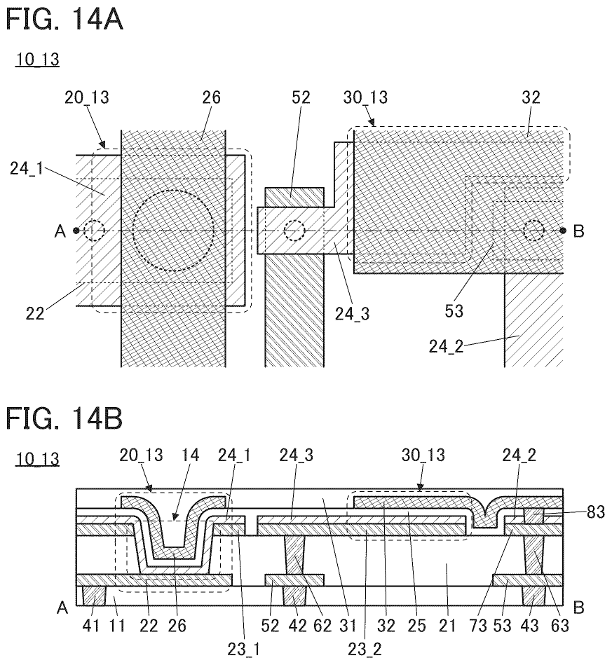

FIGS. 14A and 14B illustrate a semiconductor device 10_13 having a structure different from that of the semiconductor device 10_3 illustrated in FIGS. 4A and 4B. FIG. 14A is a plan view of the semiconductor device 10_13. FIG. 14B is a cross-sectional view taken along the dashed dotted line A-B illustrated in FIG. 14A.

The semiconductor device 10_13 includes a transistor 20_13 and a capacitor 30_13. The semiconductor device 10_13 is different from the semiconductor device 10_3 where the same conductive layer (the conductive layer 23) and the same semiconductor layer (the semiconductor layer 24_1) are shared between the transistor 20_3 and the capacitor 30_3 in that a conductive layer functioning as the other of a source electrode and a drain electrode of the transistor 20_13 and a conductive layer functioning as one electrode of the capacitor 30_13 are formed separately and that a semiconductor layer of the transistor 20_13 and a semiconductor layer functioning as a dielectric of the capacitor 30_13 are formed separately.

The transistor 20_13 includes a conductive layer 23_1 as a conductive layer functioning as the other of the source electrode and the drain electrode. The capacitor 30_13 includes a conductive layer 23_2 as a conductive layer functioning as one electrode. The transistor 20_13 includes the semiconductor layer 24_1 as its semiconductor layer. The capacitor 30_13 includes a semiconductor layer 24_3 as its dielectric.

In the case of this structure, for example, the conductive layer 41 and the conductive layer 42 are connected to each other in a layer below the insulating layer 11 (not illustrated), whereby the transistor 20_13 can function as the transistor Tr in the pixel circuit illustrated in FIG. 1B and the capacitor 30_13 can function as the capacitor C in the pixel circuit illustrated in FIG. 1B. In that case, the source electrode and the drain electrode are interchanged between the transistor 20_1 included in the semiconductor device 10_1 and the transistor 20_13 included in the semiconductor device 10_13. Furthermore, one electrode and the other electrode are interchanged between the capacitor 30_1 included in the semiconductor device 10_1 and the capacitor 30_13 included in the semiconductor device 10_13.

In a plan view (FIG. 14A), an end portion of the semiconductor layer 24_1 is aligned with an end portion of the conductive layer 23_1. End portions of the semiconductor layer 24_3 and end portions of the conductive layer 23_2 are aligned with each other. The end portion of the semiconductor layer 24_2 is aligned with the end portion of the conductive layer 73. Thus, the semiconductor layer 24_1 and the conductive layer 23_1 can be collectively formed using the same mask, the semiconductor layer 24_3 and the conductive layer 23_2 can be collectively formed using the same mask, and the semiconductor layer 24_2 and the conductive layer 73 can be collectively formed using the same mask.

For the contents of the semiconductor device 10_13 other than what is described in <Structure example 13>, the description of the semiconductor device 10_3 illustrated in FIGS. 4A and 4B can be referred to.

### Structure Example 14

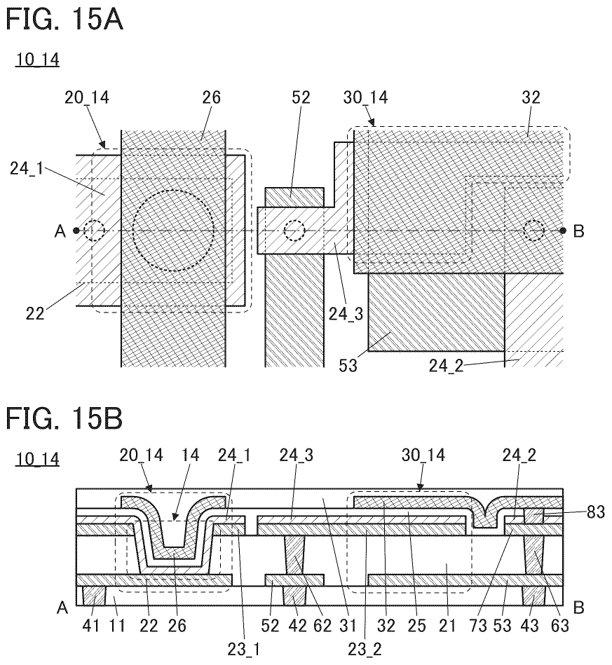

FIGS. 15A and 15B illustrate a semiconductor device 10_14 having a structure different from that of the semiconductor device 10_1 illustrated in FIGS. 2A and 2B. FIG. 15A is a plan view of the semiconductor device 10_14. FIG. 15B is a cross-sectional view taken along the dashed dotted line A-B illustrated in FIG. 15A.

The semiconductor device 10_14 includes a transistor 20_14 and a capacitor 30_14. The semiconductor device 10_14 has a structure in which the semiconductor device 10_2 illustrated in FIGS. 3A and 3B and the semiconductor device 10_13 illustrated in FIGS. 14A and 14B are combined.

Specifically, as in the semiconductor device 10_2, the conductive layer 53 in the semiconductor device 10_14 is provided to extend toward the A side of the dashed-dotted line A-B as compared with the conductive layer 53 in the semiconductor device 10_1. As in the semiconductor device 10_13, the conductive layer functioning as the other of the source electrode and the drain electrode of the transistor and the conductive layer functioning as one electrode of the capacitor are separately formed. A semiconductor layer of the transistor and a semiconductor layer functioning as a dielectric of a capacitor are formed separately.

The semiconductor device 10_14 with the above structure can provide the effect similar to the effects of the semiconductor device 10_2 and the semiconductor device 10_13. For the contents of the semiconductor device 10_14 other than what is described in <Structure example 14>, the description of the semiconductor device 10_1 illustrated in FIGS. 2A and 2B, the semiconductor device 10_2 illustrated in FIGS. 3A and 3B, and the semiconductor device 10_13 illustrated in FIGS. 14A and 14B can be referred to.

### Structure Example 15

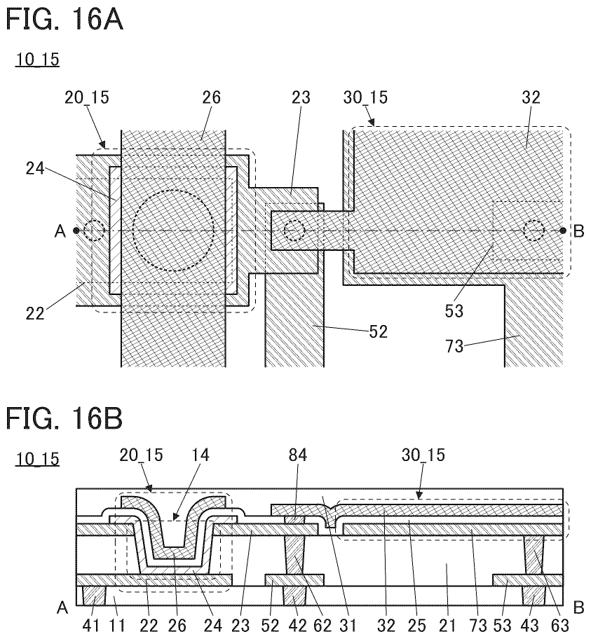

FIGS. 16A and 16B illustrate a semiconductor device 10_15 having a structure different from that of the semiconductor device 10_1 illustrated in FIGS. 2A and 2B. FIG. 16A is a plan view of the semiconductor device 10_15. FIG. 16B is a cross-sectional view taken along the dashed dotted line A-B illustrated in FIG. 16A.

The semiconductor device 10_15 includes a transistor 20_15 and a capacitor 30_15. For the transistor 20_15, the description of the transistor 20_1 included in the semiconductor device 10_1 can be referred to. The structure of the capacitor 30_15 of the semiconductor device 10_15 is different from the structure of the capacitor 30_1 of the semiconductor device 10_1.

Specifically, in the semiconductor device 10_15, a region where the conductive layer 73, the insulating layer 25, and the conductive layer 32 overlap with each other functions as the capacitor 30_15.

The conductive layer 83 which functions as a plug that connects the conductive layer 32 and the conductive layer 73 in the semiconductor device 10_1 is not provided in the semiconductor device 10_15; instead of the conductive layer 83, a conductive layer 84 which functions as a plug that connects the conductive layer 32 and the conductive layer 23 is provided. The conductive layer 84 is provided to be embedded in the insulating layer 25, and the conductive layer 32 is provided to include a region in contact with a top surface of the conductive layer 84 and a region in contact with the top surface of the insulating layer 25. Note that in the case where the semiconductor device 10_15 is used in the pixel circuit illustrated in FIG. 1B, one electrode and the other electrode are interchanged with each other in the capacitor 30_1 included in the semiconductor device 10_1 and the capacitor 30_15 included in the semiconductor device 10_15.

For the contents of the semiconductor device 10_15 other than what is described in <Structure example 15>, the description of the semiconductor device 10_1 illustrated in FIGS. 2A and 2B can be referred to.

### Structure Example 16

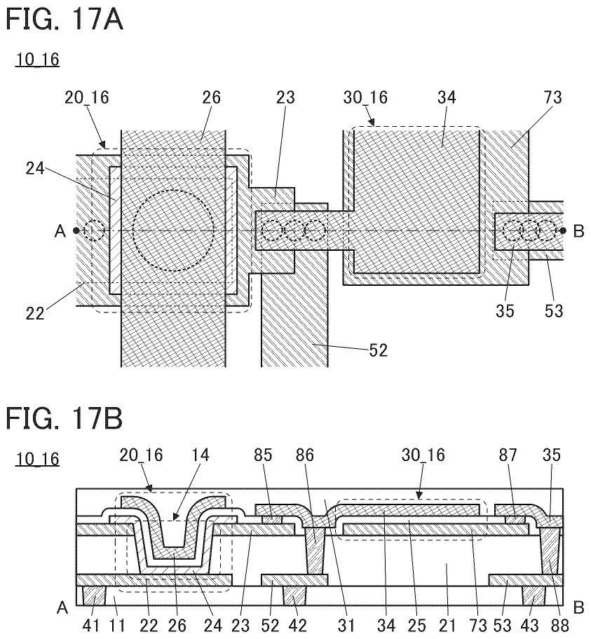

FIGS. 17A and 17B illustrate a semiconductor device 10_16 having a structure different from that of the semiconductor device 10_1 illustrated in FIGS. 2A and 2B. FIG. 17A is a plan view of the semiconductor device 10_16. FIG. 17B is a cross-sectional view taken along the dashed dotted line A-B illustrated in FIG. 17A.

The semiconductor device 10_16 includes a transistor 20_16 and a capacitor 30_16. For the transistor 20_16, the description of the transistor 20_1 included in the semiconductor device 10_1 can be referred to. The capacitor 30_16 includes the conductive layer 34 functioning as one electrode, a conductive layer 73 functioning as the other electrode, and the insulating layer 25 functioning as a dielectric. The semiconductor device 10_16 is different from the semiconductor device 10_1 in the structure of a plug connected to a transistor, a capacitor, or the like.

In the semiconductor device 10_16, the conductive layer 34 and the conductive layer 35 are provided in regions over the insulating layer 25 which are different from the region provided with the conductive layer 26. The conductive layer 34 is provided to include a region overlapping with the conductive layer 23, a region overlapping with the conductive layer 73, and a region overlapping with the conductive layer 52. The conductive layer 35 is provided to include a region overlapping with the conductive layer 73 and a region overlapping with the conductive layer 53.

A conductive layer 85 is provided to be embedded in a region of the insulating layer 25 which overlaps with the conductive layer 23 and the conductive layer 34. The conductive layer 85 includes a region in contact with the top surface of the conductive layer 23 and a bottom surface of the conductive layer 34. In a region between the conductive layer 23 and the conductive layer 73, an opening reaching the conductive layer 52 is provided in the insulating layer 25 and the insulating layer 21, and a conductive layer 86 is provided to fill the opening. The conductive layer 86 includes a region in contact with the top surface of the conductive layer 52 and a region in contact with the bottom surface of the conductive layer 34. A conductive layer 87 is provided to be embedded in a region of the insulating layer 25 which overlaps with the conductive layer 73 and the conductive layer 35. The conductive layer 87 includes a region in contact with a top surface of the conductive layer 73 and a bottom surface of the conductive layer 35. In a region not overlapping with the conductive layer 73, an opening reaching the conductive layer 53 is provided in the insulating layer 25 and the insulating layer 21, and a conductive layer 88 is provided to fill the opening. The conductive layer 88 includes a region overlapping with the top surface of the conductive layer 53 and the bottom surface of the conductive layer 35.

The conductive layer 85 functions as a plug that connects the other (the conductive layer 23) of a source electrode and a drain electrode of the transistor 20_16 and one electrode (the conductive layer 34) of the capacitor 30_16. The conductive layer 86 functions as a plug that connects the one electrode (the conductive layer 34) of the capacitor 30_16 and the conductive layer 52. The conductive layer 87 functions as a plug that connects the other electrode (the conductive layer 73) of the capacitor 30_16 and the conductive layer 35. The conductive layer 88 functions as a plug that connects the conductive layer 35 and the conductive layer 53.

The conductive layer 34 includes a region in contact with a top surface of the conductive layer 85, a region in contact with a top surface of the conductive layer 86, and a region in contact with the top surface of the insulating layer 25. The conductive layer 35 includes a region in contact with a top surface of the conductive layer 87, a region in contact with a top surface of the conductive layer 88, and a region in contact with the top surface of the insulating layer 25. In the semiconductor device 10_16, a region where the conductive layer 73, the insulating layer 25, and the conductive layer 34 overlap with each other functions as the capacitor 30_16. The conductive layer 26, the conductive layer 34, and the conductive layer 35 can be formed at the same time by processing the same material.

For the contents of the semiconductor device 10_16 other than what is described in <Structure example 2>, the description of the semiconductor device 10_1 illustrated in FIGS. 2A and 2B can be referred to.

### Structure Example 17

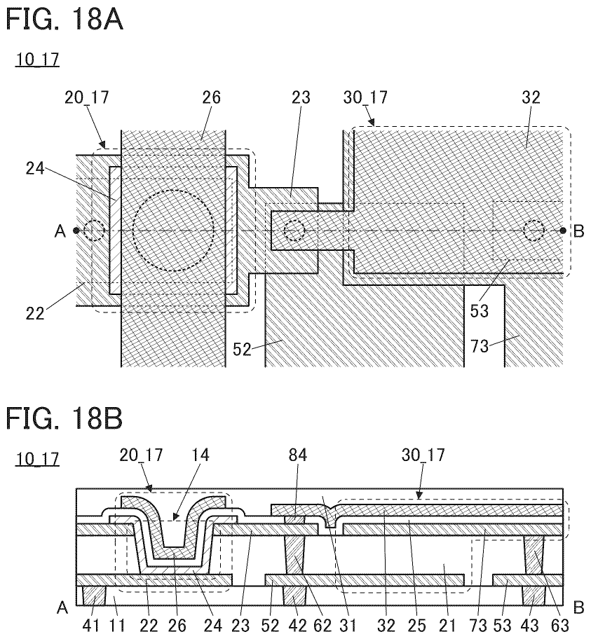

FIGS. 18A and 18B illustrate a semiconductor device 10_17 having a structure different from that of the semiconductor device 10_15 illustrated in FIGS. 16A and 16B. FIG. 18A is a plan view of the semiconductor device 10_17. FIG. 18B is a cross-sectional view taken along the dashed dotted line A-B illustrated in FIG. 18A.

The semiconductor device 10_17 includes a transistor 20_17 and a capacitor 30_17. For the transistor 20_17, the description of the transistor 20_15 included in the semiconductor device 10_15 can be referred to. The structure of the capacitor 30_17 of the semiconductor device 10_17 is different from the structure of the capacitor 30_15 of the semiconductor device 10_15.

Specifically, in the semiconductor device 10_17, the conductive layer 52 is provided to extend toward the B side of the dashed-dotted line A-B as compared in the semiconductor device 10_15, and the capacitor 30_17 includes the insulating layer 21 and the conductive layer 52 in addition to the components included in the capacitor 30_15.

In the capacitor 30_17, a region where the conductive layer 73, the insulating layer 25, and the conductive layer 32 overlap with each other can function as a capacitor (a first capacitor), as in the capacitor 30_15. In the capacitor 30_17, a region where the conductive layer 52, the insulating layer 21, and the conductive layer 73 overlap with each other can also function as a capacitor (a second capacitor).

That is, the capacitance value of the capacitor 30_17 can be larger than that of the capacitor 30_15 by the capacitance of the second capacitor because the capacitor 30_17 includes the second capacitor.

For the contents of the semiconductor device 10_17 other than what is described in <Structure example 17>, the description of the semiconductor device 10_15 illustrated in FIGS. 16A and 16B can be referred to.

### Structure Example 18

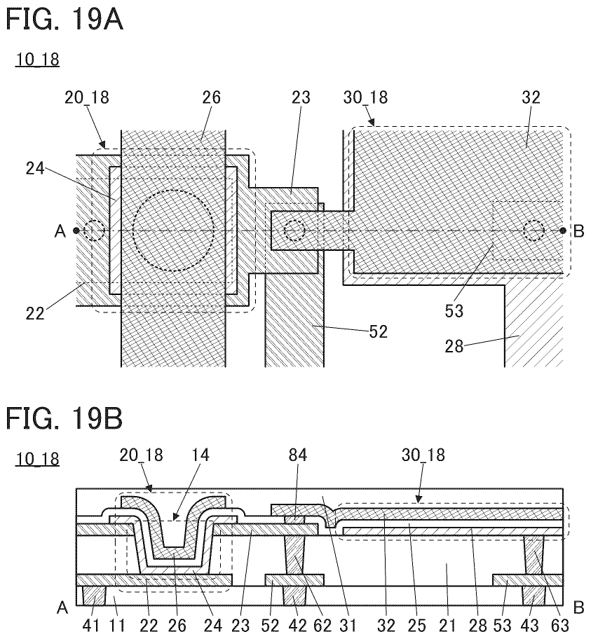

FIGS. 19A and 19B illustrate a semiconductor device 10_18 having a structure different from that of the semiconductor device 10_15 illustrated in FIGS. 16A and 16B. FIG. 19A is a plan view of the semiconductor device 10_18. FIG. 19B is a cross-sectional view taken along the dashed dotted line A-B illustrated in FIG. 19A.

The semiconductor device 10_18 includes a transistor 20_18 and a capacitor 30_18. The semiconductor device 10_18 is different from the semiconductor device 10_15 in that the semiconductor layer 28 is used as a component functioning as the other electrode of the capacitor 30_18.

The semiconductor layer 28 is provided over the insulating layer 21 to include a region overlapping with the conductive layer 32. The semiconductor layer 28 is in contact with the top surface of the conductive layer 63 and the top surface of the insulating layer 21. The semiconductor layer 28 has the same shape as the conductive layer 73 included in the semiconductor device 10_15 in the plan view (FIG. 19A), and is placed in a position corresponding to the conductive layer 73. That is, the semiconductor device 10_18 has a structure in which the conductive layer 73 in the semiconductor device 10_15 is replaced with the semiconductor layer 28. In the semiconductor device 10_18, the semiconductor layer 24 and the semiconductor layer 28 can be formed at the same time by processing the same material.

In the capacitor 30_18 included in the semiconductor device 10_18, the semiconductor layer 28 functions as the other electrode and thus preferably has high conductivity. For example, it is preferable that the semiconductor layer 24 and the semiconductor layer 28 be formed into island shapes by processing the same semiconductor material and then an impurity such as hydrogen be added only to the semiconductor layer 28 to reduce the resistance. Thus, the semiconductor layer 28 can function as the other electrode of the capacitor 30_18.

For the contents of the semiconductor device 10_18 other than what is described in <Structure example 18>, the description of the semiconductor device 10_15 illustrated in FIGS. 16A and 16B can be referred to.

### Structure Example 19

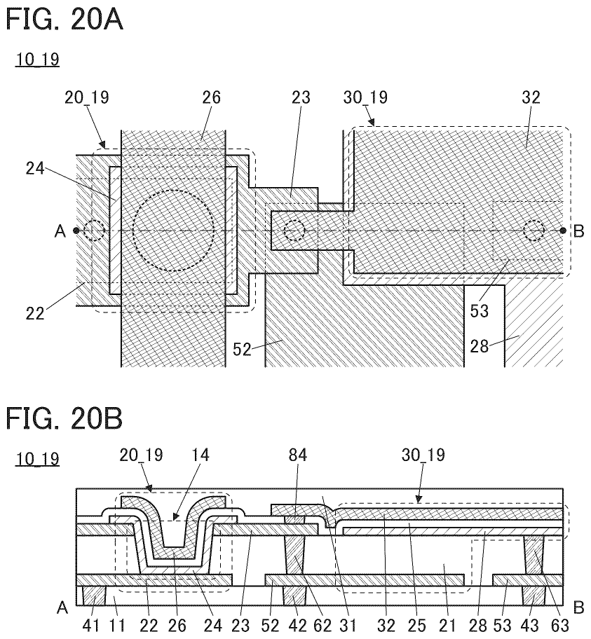

FIGS. 20A and 20B illustrate a semiconductor device 10_19 having a structure different from that of the semiconductor device 10_1 illustrated in FIGS. 2A and 2B. FIG. 20A is a plan view of the semiconductor device 10_19. FIG. 20B is a cross-sectional view taken along the dashed dotted line A-B illustrated in FIG. 20A.

The semiconductor device 10_19 includes a transistor 20_19 and a capacitor 30_19. The semiconductor device 10_19 has a structure in which the semiconductor device 10_17 illustrated in FIGS. 18A and 18B and the semiconductor device 10_18 illustrated in FIGS. 19A and 19B are combined.

Specifically, as in the semiconductor device 10_17, the conductive layer 52 in the semiconductor device 10_19 is provided to extend toward the B side of the dashed-dotted line A-B as compared with the conductive layer 52 in the semiconductor device 10_1. As in the semiconductor device 10_18, the semiconductor layer 28 is provided as the other electrode of the capacitor.

The semiconductor device 10_19 with the above structure can provide the effect similar to the effects of the semiconductor device 10_17 and the semiconductor device 10_18.

For the contents of the semiconductor device 10_19 other than what is described in <Structure example 19>, the description of the semiconductor device 10_1 illustrated in FIGS. 2A and 2B, the semiconductor device 10_17 illustrated in FIGS. 18A and 18B, and the semiconductor device 10_18 illustrated in FIGS. 19A and 19B can be referred to.

### Structure Example 20

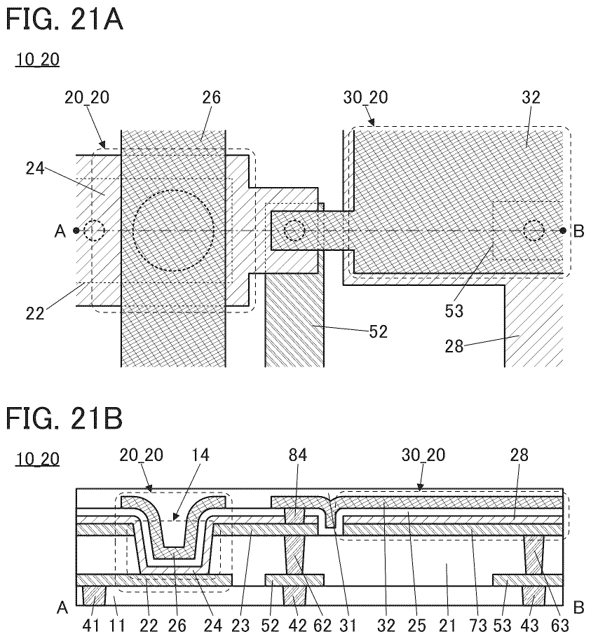

FIGS. 21A and 21B illustrate a semiconductor device 10_20 having a structure different from that of the semiconductor device 10_15 illustrated in FIGS. 16A and 16B. FIG. 21A is a plan view of the semiconductor device 10_20. FIG. 21B is a cross-sectional view taken along the dashed dotted line A-B illustrated in FIG. 21A.

The semiconductor device 10_20 includes a transistor 20_20 and a capacitor 30_20. The semiconductor device 10_20 is different from the semiconductor device 10_15 in the structure of the semiconductor layer.

Specifically, the semiconductor device 10_20 includes the semiconductor layer 24 provided over the conductive layer 23 and the semiconductor layer 28 provided over the conductive layer 73. In a plan view (FIG. 21A), an end portion of the semiconductor layer 24 is aligned with an end portion of the conductive layer 23. An end portion of the semiconductor layer 28 is aligned with an end portion of the conductive layer 73. Thus, the semiconductor layer 24 and the conductive layer 23 can be collectively formed using the same mask, and the semiconductor layer 28 and the conductive layer 73 can be collectively formed using the same mask.

The capacitor 30_20 includes the semiconductor layer 28 and the insulating layer 25 between the conductive layer 73 and the conductive layer 32. Thus, in the capacitor 30_20, the semiconductor layer 28 and the insulating layer 25 in a region between the conductive layer 73 and the conductive layer 32 function as dielectrics.

The conductive layer 84 is provided to be embedded in the semiconductor layer 24 and the insulating layer 25 in a region where the conductive layer 23 and the conductive layer 32 overlap with each other. The conductive layer 84 includes a region in contact with the top surface of the conductive layer 23 and a region in contact with a bottom surface of the conductive layer 32.

For the contents of the semiconductor device 10_20 other than what is described in <Structure example 20>, the description of the semiconductor device 10_15 illustrated in FIGS. 16A and 16B can be referred to.

### Structure Example 21

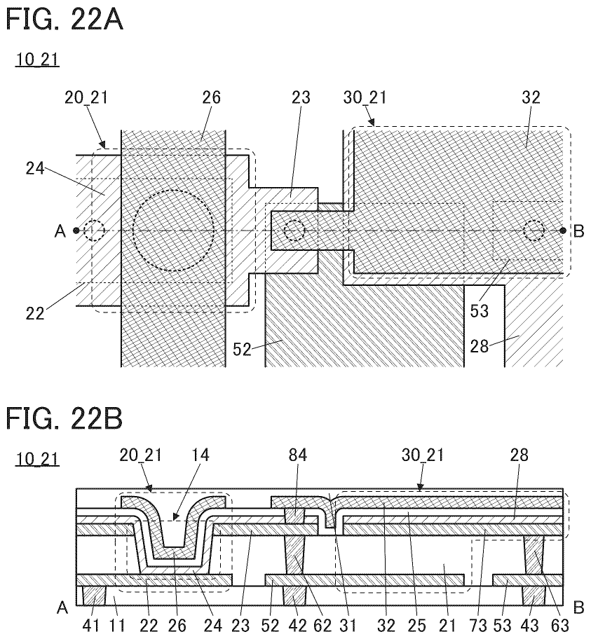

FIGS. 22A and 22B illustrate a semiconductor device 10_21 having a structure different from that of the semiconductor device 10_1 illustrated in FIGS. 2A and 2B. FIG. 22A is a plan view of the semiconductor device 10_21. FIG. 22B is a cross-sectional view taken along the dashed dotted line A-B illustrated in FIG. 22A.

The semiconductor device 10_21 includes a transistor 20_21 and a capacitor 30_21. The semiconductor device 10_21 has a structure in which the semiconductor device 10_17 illustrated in FIGS. 18A and 18B and the semiconductor device 10_20 illustrated in FIGS. 21A and 21B are combined.

Specifically, as in the semiconductor device 10_17, the conductive layer 52 in the semiconductor device 10_21 is provided to extend toward the B side of the dashed-dotted line A-B as compared with the conductive layer 52 in the semiconductor device 10_1. As in the semiconductor device 10_20, the semiconductor layer 28 is provided as a dielectric of the capacitor in addition to the insulating layer 25.

The semiconductor device 10_21 with the above structure can provide the effect similar to the effects of the semiconductor device 10_17 and the semiconductor device 10_20.

For the contents of the semiconductor device 10_21 other than what is described in <Structure example 21>, the description of the semiconductor device 10_1 illustrated in FIGS. 2A and 2B, the semiconductor device 10_17 illustrated in FIGS. 18A and 18B, and the semiconductor device 10_20 illustrated in FIGS. 21A and 21B can be referred to.

### Structure Example 22

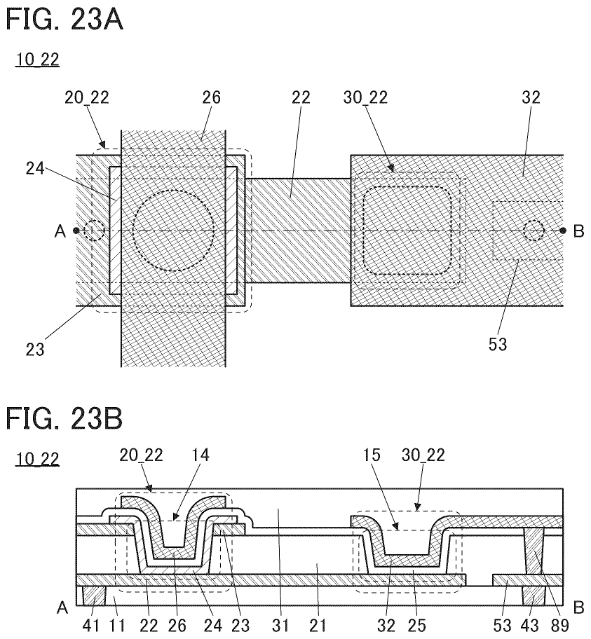

FIGS. 23A and 23B illustrate a semiconductor device 10_22 having a structure different from that of the semiconductor device 10_1 illustrated in FIGS. 2A and 2B. FIG. 23A is a plan view of the semiconductor device 10_22. FIG. 23B is a cross-sectional view taken along the dashed dotted line A-B illustrated in FIG. 23A.

The semiconductor device 10_22 includes a transistor 20_22 and a capacitor 30_22. For the transistor 20_22, the description of the transistor 20_1 included in the semiconductor device 10_1 can be referred to. The structure of the capacitor 30_22 in the semiconductor device 10_22 is different from that of the capacitor 30_1 in the semiconductor device 10_1.

Specifically, in the semiconductor device 10_22, an end portion of the conductive layer 23 on the capacitor side is closer to the A side of the dashed-dotted line A-B than that in the semiconductor device 10_1, and the conductive layer 22 is provided to extend toward the B side of the dashed-dotted line A-B as compared with the semiconductor device 10_1. In the insulating layer 21, an opening 15 reaching the conductive layer 22 is provided in a region different from a region of the transistor 20_22, and the insulating layer 25 is provided in contact with a sidewall of the opening 15 (i.e., the side surface of the insulating layer 21 in the opening 15) and a bottom surface of the opening 15 (i.e., the top surface of the conductive layer 22 in the opening 15). The conductive layer 32 is provided over the insulating layer 25 to include a region overlapping with the opening 15. In the semiconductor device 10_22, a region in the opening 15 where the conductive layer 22, the insulating layer 25, and the conductive layer 32 overlap with each other functions as the capacitor 30_22.

In the semiconductor device 10_22, the conductive layer 23 functions as one of a source electrode and a drain electrode of the transistor 20_22. The conductive layer 22 functions as the other of the source electrode and the drain electrode of the transistor 20_22 and also functions as one electrode of the capacitor 30_22. The conductive layer 32 functions as the other electrode of the capacitor 30_22.

In the semiconductor device 10_22, the opening 15 needs to be formed in the insulating layer 21 in order to provide the capacitor 30_22. With this structure, only the insulating layer 25 can serve as a dielectric of the capacitor 30_22. Meanwhile, in the case where the opening 15 is not provided in the insulating layer 21 and an insulating layer in a region sandwiched between the conductive layer 22 and the conductive layer 32 (i.e., the insulating layer 21 and the insulating layer 25 in the region) is used as a dielectric of the capacitor 30_22, the thickness of the dielectric is larger than that in the case where the opening 15 is provided by the thickness of the insulating layer 21; accordingly, the capacitance value is lower than that in the case where the opening 15 is provided. Thus, it is preferable that the opening 15 be provided in the insulating layer 21 and the capacitor 30_22 be formed in a region overlapping with the opening 15 as in the semiconductor device 10_22, in which case the capacitance value can be increased.

When the semiconductor device 10_22 has the above structure, the number of conductive layers functioning as plugs can be smaller than that in the semiconductor device 10_1. For example, conductive layers, such as the conductive layer 42, the conductive layer 52, and the conductive layer 62, included in the semiconductor device 10_1 are not necessary in the semiconductor device 10_22; thus, the number of steps for manufacturing the semiconductor device 10_22 can be smaller than that for the semiconductor device 10_1.

For the contents of the semiconductor device 10_22 other than what is described in <Structure example 22>, the description of the semiconductor device 10_1 illustrated in FIGS. 2A and 2B can be referred to.

### Structure Example 23

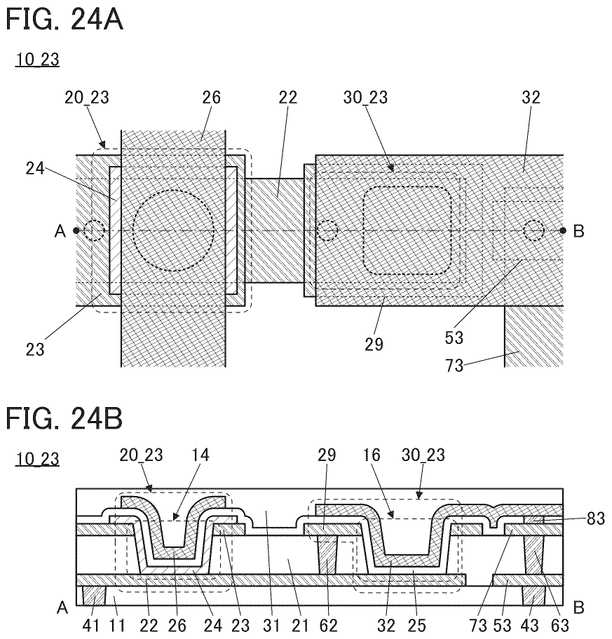

FIGS. 24A and 24B illustrate a semiconductor device 10_23 having a structure different from the structures of the semiconductor device 10_1 illustrated in FIGS. 2A and 2B and the semiconductor device 10_22 illustrated in FIGS. 23A and 23B. FIG. 24A is a plan view of the semiconductor device 10_23. FIG. 24B is a cross-sectional view taken along the dashed dotted line A-B illustrated in FIG. 24A.

The semiconductor device 10_23 includes a transistor 20_23 and a capacitor 30_23. For the transistor 20_23, the description of the transistor 20_22 included in the semiconductor device 10_22 can be referred to. The structure of the capacitor 30_23 in the semiconductor device 10_23 is different from that of the capacitor 30_22 in the semiconductor device 10_22.

Specifically, in the semiconductor device 10_23, a conductive layer 29 is provided over the insulating layer 21 to include a region overlapping with an opening 16 where the capacitor 30_23 is formed. In other words, in the semiconductor device 10_23, the opening 16 reaching the conductive layer 22 is provided in the conductive layer 29 and the insulating layer 21. The insulating layer 25 is provided in contact with a sidewall of the opening 16 (i.e., a side surface of the conductive layer 29 in the opening 16 and the side surface of the insulating layer 21 in the opening 16) and a bottom surface of the opening 16 (i.e., the top surface of the conductive layer 22 in the opening 16). The conductive layer 32 is provided over the insulating layer 25 to include a region overlapping with the opening 16 and a region overlapping with the conductive layer 29. In the semiconductor device 10_23, a region where the conductive layer 22, the insulating layer 25, and the conductive layer 32 overlap with each other in the opening 16 and a region where the conductive layer 29, the insulating layer 25, and the conductive layer 32 overlap with each other outside the opening 16 function as the capacitor 30_23.

That is, in the capacitor 30_23, the region where the conductive layer 22, the insulating layer 25, and the conductive layer 32 overlap with each other in the opening 16 can function as a capacitor (a first capacitor), as in the capacitor 30_22. Furthermore, in the capacitor 30_23, the region where the conductive layer 29, the insulating layer 25, and the conductive layer 32 overlap with each other outside the opening 16 can also function as a capacitor (a second capacitor).

That is, the capacitance value of the capacitor 30_23 can be larger than that of the capacitor 30_22 by the capacitance of the second capacitor because the capacitor 30_23 includes the second capacitor.

In the semiconductor device 10_23, the conductive layer 23, the conductive layer 29, and the conductive layer 73 can be formed at the same time by processing the same material.

An opening reaching the conductive layer 22 is provided in a region of the insulating layer 21 which overlaps with the conductive layer 29 and the conductive layer 22, and the conductive layer 62 is provided to fill the opening. The conductive layer 62 includes a region in contact with the top surface of the conductive layer 22 and a region in contact with a bottom surface of the conductive layer 29. The conductive layer 62 functions as a plug that connects the conductive layer 22 and the conductive layer 29. Thus, in the semiconductor device 10_23, a region of the conductive layer 22 which overlaps with the transistor 20_23 can function as one of a source electrode and a drain electrode of the transistor 20_23. The conductive layer 29 and the region of the conductive layer 22 which overlaps with the capacitor 30_23 can function as one electrode of the capacitor 30_23.

For the contents of the semiconductor device 10_23 other than what is described in <Structure example 23>, the description of the semiconductor device 10_1 illustrated in FIGS. 2A and 2B and the semiconductor device 10_22 illustrated in FIGS. 23A and 23B can be referred to.

### Structure Example 24

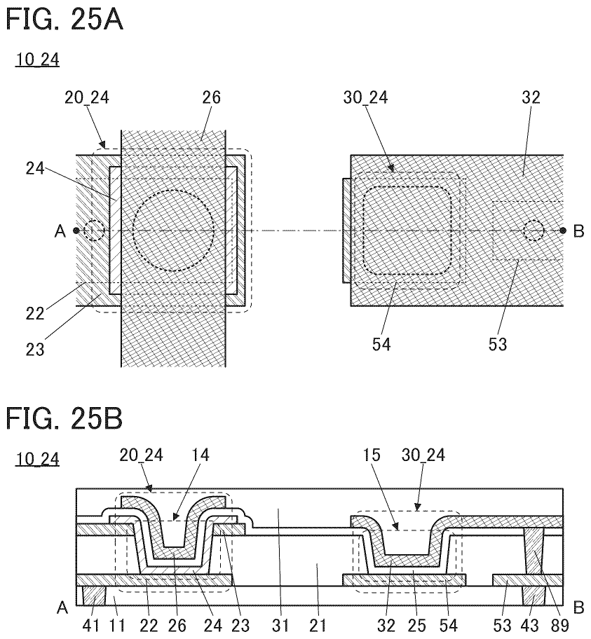

FIGS. 25A and 25B illustrate a semiconductor device 10_24 having a structure different from that of the semiconductor device 10_22 illustrated in FIGS. 23A and 23B. FIG. 25A is a plan view of the semiconductor device 10_24. FIG. 25B is a cross-sectional view taken along the dashed dotted line A-B illustrated in FIG. 25A.

The semiconductor device 10_24 includes a transistor 20_24 and a capacitor 30_24. The semiconductor device 10_24 is different from the semiconductor device 10_22 in that a conductive layer functioning as one of a source electrode and a drain electrode of a transistor and a conductive layer functioning as one electrode of a capacitor are separately provided.

Specifically, in the semiconductor device 10_24, the end portion of the conductive layer 22 functioning as one of a source electrode and a drain electrode of the transistor 20_24 is not extended to a region overlapping with the capacitor 30_24. A conductive layer 54 is provided separately from the conductive layer 22, as a conductive layer functioning as one electrode of the capacitor 30_24. In the semiconductor device 10_24, the conductive layer 22, the conductive layer 54, and the conductive layer 53 can be formed at the same time by processing the same material.

In the case of this structure, for example, when a conductive layer functioning as a plug connected to the conductive layer 22 and a conductive layer functioning as a plug connected to the conductive layer 54 are connected below the insulating layer 11 (not illustrated), the semiconductor device 10_24 having a function similar to that of the semiconductor device 10_22 can be achieved.

For the contents of the semiconductor device 10_24 other than what is described in <Structure example 24>, the description of the semiconductor device 10_22 illustrated in FIGS. 23A and 23B can be referred to.

### Structure Example 25

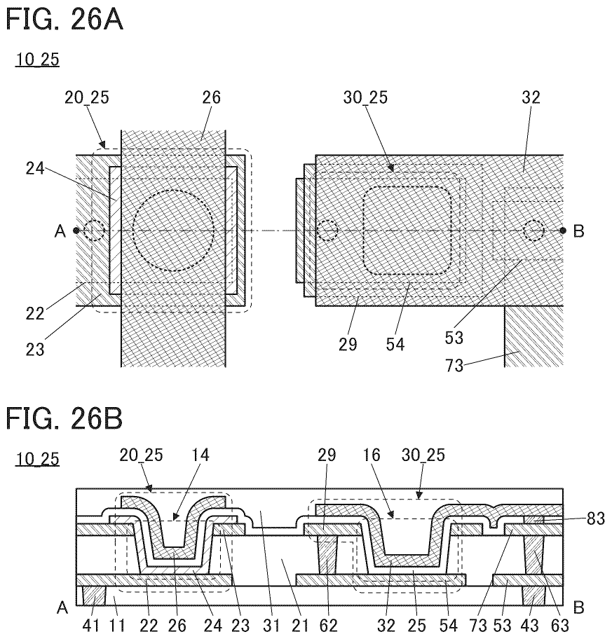

FIGS. 26A and 26B illustrate a semiconductor device 10_25 having a structure different from that of the semiconductor device 10_1 illustrated in FIGS. 2A and 2B. FIG. 26A is a plan view of the semiconductor device 10_25. FIG. 26B is a cross-sectional view taken along the dashed dotted line A-B illustrated in FIG. 26A.

The semiconductor device 10_25 includes a transistor 20_25 and a capacitor 30_25. The semiconductor device 10_25 has a structure in which the semiconductor device 10_23 illustrated in FIGS. 24A and 24B and the semiconductor device 10_24 illustrated in FIGS. 25A and 25B are combined.

Specifically, the semiconductor device 10_25 includes the conductive layer 54 functioning as one electrode of the capacitor, like the semiconductor device 10_24. As in the semiconductor device 10_23, two portions, a region in the opening 16 formed in the conductive layer 29 and the insulating layer 21 (to be exact, a region where the conductive layer 54, the insulating layer 25, and the conductive layer 32 overlap with each other) and a region outside the opening 16 (to be exact, a region where the conductive layer 29, the insulating layer 25, and the conductive layer 32 overlap with each other) can function as capacitors.

The semiconductor device 10_25 with the above structure can provide the effect similar to the effects of the semiconductor device 10_23 and the semiconductor device 10_24. For the contents of the semiconductor device 10_25 other than what is described in <Structure example 25>, the description of the semiconductor device 10_1 illustrated in FIGS. 2A and 2B, the semiconductor device 10_23 illustrated in FIGS. 24A and 24B, and the semiconductor device 10_24 illustrated in FIGS. 25A and 25B can be referred to.

### Structure Example 26

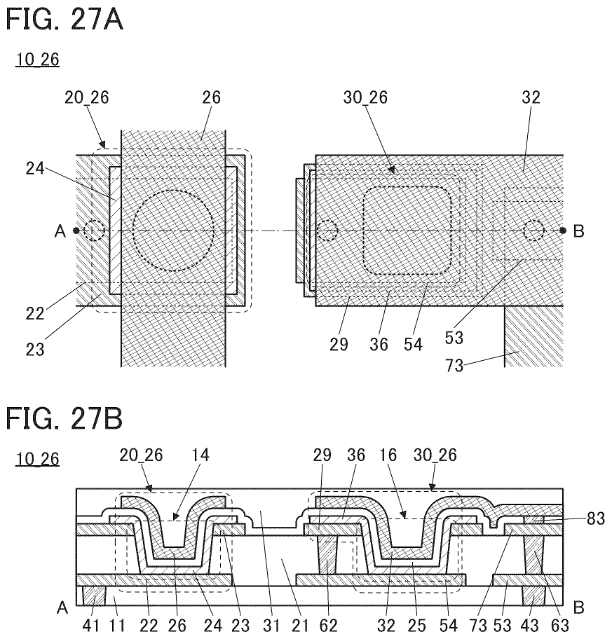

FIGS. 27A and 27B illustrate a semiconductor device 10_26 having a structure different from that of the semiconductor device 10_25 illustrated in FIGS. 26A and 26B. FIG. 27A is a plan view of the semiconductor device 10_26. FIG. 27B is a cross-sectional view taken along the dashed dotted line A-B illustrated in FIG. 27A.

The semiconductor device 10_26 includes a transistor 20_26 and a capacitor 30_26. The semiconductor device 10_26 is different from the semiconductor device 10_25 in that the semiconductor layer 36 is included in addition to the insulating layer 25 as a dielectric of the capacitor 30_26.

Specifically, in the semiconductor device 10_26, the semiconductor layer 36 is provided in contact with the sidewall of the opening 16 provided in the conductive layer 29 and the insulating layer 21 (i.e., the side surface of the conductive layer 29 in the opening 16 and the side surface of the insulating layer 21 in the opening 16), the bottom surface of the opening 16 (i.e., a top surface of the conductive layer 54 in the opening 16), and a top surface of the conductive layer 29, and the insulating layer 25 is provided to cover the conductive layer 29 and the semiconductor layer 36. In the semiconductor device 10_26, the semiconductor layer 36 and the insulating layer 25 can function as dielectrics of the capacitor 30_26 in a region between the conductive layer 54 and the conductive layer 32 and a region between the conductive layer 29 and the conductive layer 32.

In the semiconductor device 10_26, the semiconductor layer 24 and the semiconductor layer 36 can be formed at the same time by processing the same material.

For the contents of the semiconductor device 10_26 other than what is described in <Structure example 26>, the description of the semiconductor device 10_25 illustrated in FIGS. 26A and 26B can be referred to.

### Structure Example 27

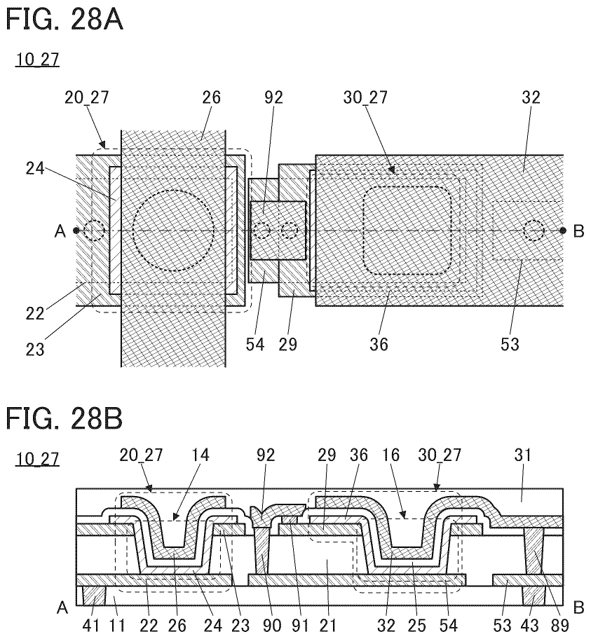

FIGS. 28A and 28B illustrate a semiconductor device 10_27 having a structure different from that of the semiconductor device 10_26 illustrated in FIGS. 27A and 27B. FIG. 28A is a plan view of the semiconductor device 10_27. FIG. 28B is a cross-sectional view taken along the dashed dotted line A-B illustrated in FIG. 28A.

The semiconductor device 10_27 includes a transistor 20_27 and a capacitor 30_27. The semiconductor device 10_27 is different from the semiconductor device 10_26 in the structure of a plug that connects the conductive layer 54 and the conductive layer 29.

Specifically, in the semiconductor device 10_27, an opening reaching the conductive layer 54 is provided in the insulating layer 25 and the insulating layer 21 in a region between the conductive layer 23 and the conductive layer 29, and a conductive layer 90 is provided to fill the opening. An opening reaching the conductive layer 29 is provided in the insulating layer 25, and a conductive layer 91 is provided to fill the opening. A conductive layer 92 is provided over the insulating layer 25 to include a region overlapping with the conductive layer 90 and a region overlapping with the conductive layer 91. The conductive layer 90 includes a region in contact with a top surface of the conductive layer 54 and a region in contact with a bottom surface of the conductive layer 92. The conductive layer 91 includes a region in contact with the top surface of the conductive layer 29 and the bottom surface of the conductive layer 92. The conductive layer 92 includes a region in contact with a top surface of the conductive layer 90, a region in contact with a top surface of the conductive layer 91, and a region in contact with the top surface of the insulating layer 25. The conductive layer 90 and the conductive layer 91 function as plugs that connect the conductive layer 54 and the conductive layer 29 with the conductive layer 92 therebetween.

In a region overlapping with the conductive layer 53 and the conductive layer 32, an opening reaching the conductive layer 53 is provided in the insulating layer 25 and the insulating layer 21, and a conductive layer 89 is provided to fill the opening. The conductive layer 89 includes a region in contact with the top surface of the conductive layer 53 and the bottom surface of the conductive layer 32. The conductive layer 89 functions as a plug that connects the conductive layer 53 and the conductive layer 32.

In the semiconductor device 10_27, the conductive layer 26, the conductive layer 92, and the conductive layer 32 can be formed at the same time by processing the same material.

For the contents of the semiconductor device 10_27 other than what is described in <Structure example 2>, the description of the semiconductor device 10_26 illustrated in FIGS. 27A and 27B can be referred to.

### Structure Example 28

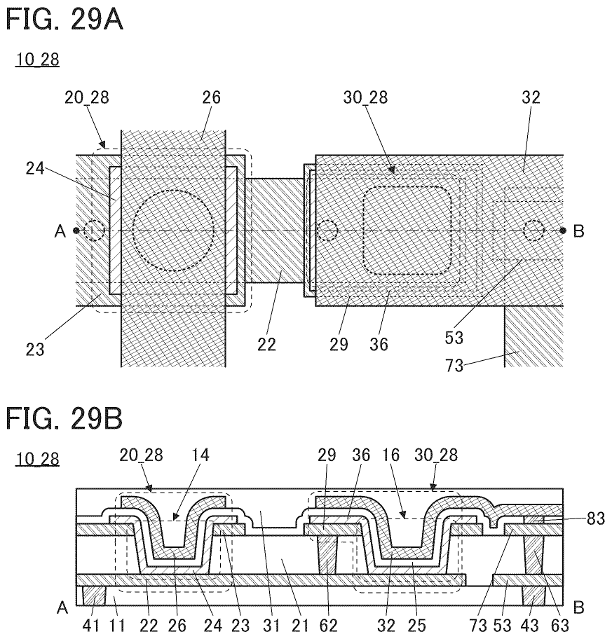

FIGS. 29A and 29B illustrate a semiconductor device 10_28 having a structure different from that of the semiconductor device 10_1 illustrated in FIGS. 2A and 2B. FIG. 29A is a plan view of the semiconductor device 10_28. FIG. 29B is a cross-sectional view taken along the dashed dotted line A-B illustrated in FIG. 29A.

The semiconductor device 10_28 includes a transistor 20_28 and a capacitor 30_28. The semiconductor device 10_28 has a structure in which the semiconductor device 10_23 illustrated in FIGS. 24A and 24B and the semiconductor device 10_26 illustrated in FIGS. 27A and 27B are combined.

Specifically, as in the semiconductor device 10_23, the conductive layer functioning as one of the source electrode and the drain electrode of the transistor and the conductive layer functioning as one electrode of the capacitor share the same conductive layer (the conductive layer 22) in the semiconductor device 10_28. As in the semiconductor device 10_26, the semiconductor layer 36 is included as a dielectric of the capacitor in addition to the insulating layer 25.

The semiconductor device 10_28 with the above structure can provide the effect similar to the effects of the semiconductor device 10_23 and the semiconductor device 10_26.

For the contents of the semiconductor device 10_28 other than what is described in <Structure example 28>, the description of the semiconductor device 10_1 illustrated in FIGS. 2A and 2B, the semiconductor device 10_23 illustrated in FIGS. 24A and 24B, and the semiconductor device 10_26 illustrated in FIGS. 27A and 27B can be referred to.

### Structure Example 29

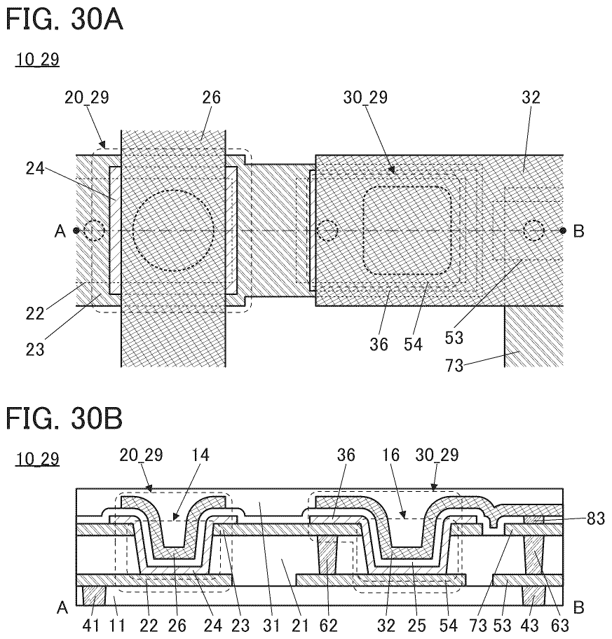

FIGS. 30A and 30B illustrate a semiconductor device 10_29 having a structure different from that of the semiconductor device 10_26 illustrated in FIGS. 27A and 27B. FIG. 30A is a plan view of the semiconductor device 10_29. FIG. 30B is a cross-sectional view taken along the dashed dotted line A-B illustrated in FIG. 30A.

The semiconductor device 10_29 includes a transistor 20_29 and a capacitor 30_29. The semiconductor device 10_29 is different from the semiconductor device 10_26 in that the conductive layer 23 included in the transistor is shared as part of the capacitor.

Specifically, in the semiconductor device 10_29, the conductive layer 23 included in the transistor 20_29 extends to the capacitor 30_29 side and is shared as part of the capacitor 30_29. The conductive layer 23 is connected to the conductive layer 54 through the conductive layer 62. Thus, in the semiconductor device 10_29, a region of the conductive layer 23 which overlaps with the transistor 20_29 can function as the other of a source electrode and a drain electrode of the transistor 20_29. The conductive layer 54 and the region of the conductive layer 23 which overlaps with the capacitor 30_29 can function as one electrode of the capacitor 30_29.

For the contents of the semiconductor device 10_29 other than what is described in <Structure example 29>, the description of the semiconductor device 10_26 illustrated in FIGS. 27A and 27B can be referred to.

### Structure Example 30

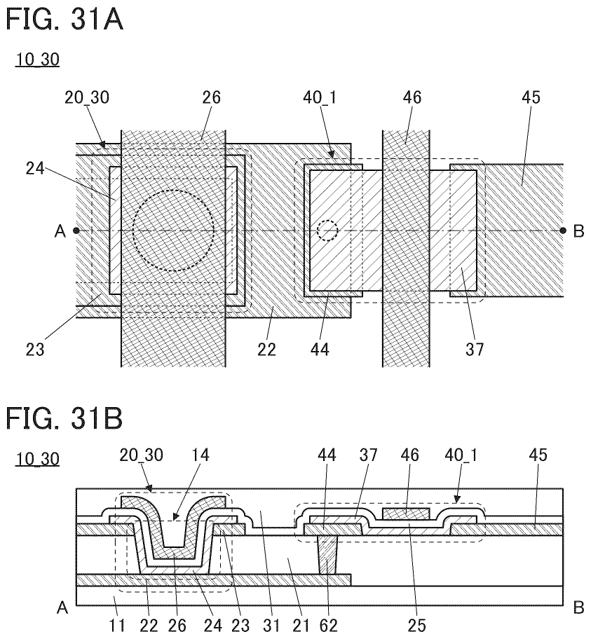

FIGS. 31A and 31B illustrate a semiconductor device 10_30 having a structure different from that of the semiconductor devices 10_1 to 10_29 illustrated in FIGS. 2A and 2B to FIGS. 30A and 30B. FIG. 31A is a plan view of the semiconductor device 10_30. FIG. 31B is a cross-sectional view taken along the dashed dotted line A-B illustrated in FIG. 31A.

The semiconductor device 10_30 includes a transistor 20_30 and a transistor 40_1. The semiconductor device 10_30 is different from the semiconductor devices 10_1 to 10_29 in including two transistors while each of the semiconductor devices 10_1 to 10_29 includes one transistor and one capacitor.

The semiconductor device 10_30 includes one vertical transistor (the transistor 20_30) and one TG transistor (the transistor 40_1). For the transistor 20_30, the description of the transistor 20_1 and the like can be referred to.

The transistor 40_1 includes a conductive layer 44 functioning as one of a source electrode and a drain electrode, a conductive layer 45 functioning as the other of the source electrode and the drain electrode, a semiconductor layer 37, an insulating layer 25 functioning as a gate insulating layer, and a conductive layer 46 functioning as a gate electrode.

The conductive layer 44 and the conductive layer 45 are provided in regions over the insulating layer 21, which are different from the region of the conductive layer 23. The semiconductor layer 37 is provided in contact with a top surface of the conductive layer 44, a side surface of the conductive layer 44 on the side opposite to the conductive layer 45, the top surface of the insulating layer 21 in a region sandwiched between the conductive layer 44 and the conductive layer 45, a side surface of the conductive layer 45 on the side opposite to the conductive layer 44, and a top surface of the conductive layer 45. The insulating layer 25 includes, in a region overlapping with the transistor 40_1, a region in contact with a top surface and a side surface of the semiconductor layer 37, a region in contact with the top surface and the side surface of the conductive layer 44, and a region in contact with the top surface of the conductive layer 45. In a region between the conductive layer 44 and the conductive layer 45, the conductive layer 46 is provided over the insulating layer 25.

In the semiconductor device 10_30, a region of the insulating layer 25 which overlaps with the transistor 20_30 functions as a gate insulating layer of the transistor 20_30, and a region of the insulating layer 25 which overlaps with the transistor 40_1 functions as a gate insulating layer of the transistor 40_1.

In the semiconductor device 10_30, the conductive layer 23, the conductive layer 44, and the conductive layer 45 can be formed at the same time by processing the same material. The semiconductor layer 24 and the semiconductor layer 37 can be formed at the same time by processing the same material. The conductive layer 26 and the conductive layer 46 can be formed at the same time by processing the same material.

An opening reaching the conductive layer 22 is provided in a region of the insulating layer 21 which overlaps with the conductive layer 44 and the conductive layer 22, and the conductive layer 62 is provided to fill the opening. The conductive layer 62 includes a region in contact with the top surface of the conductive layer 22 and a region in contact with a bottom surface of the conductive layer 44. The conductive layer 62 functions as a plug that connects the conductive layer 22 and the conductive layer 44.

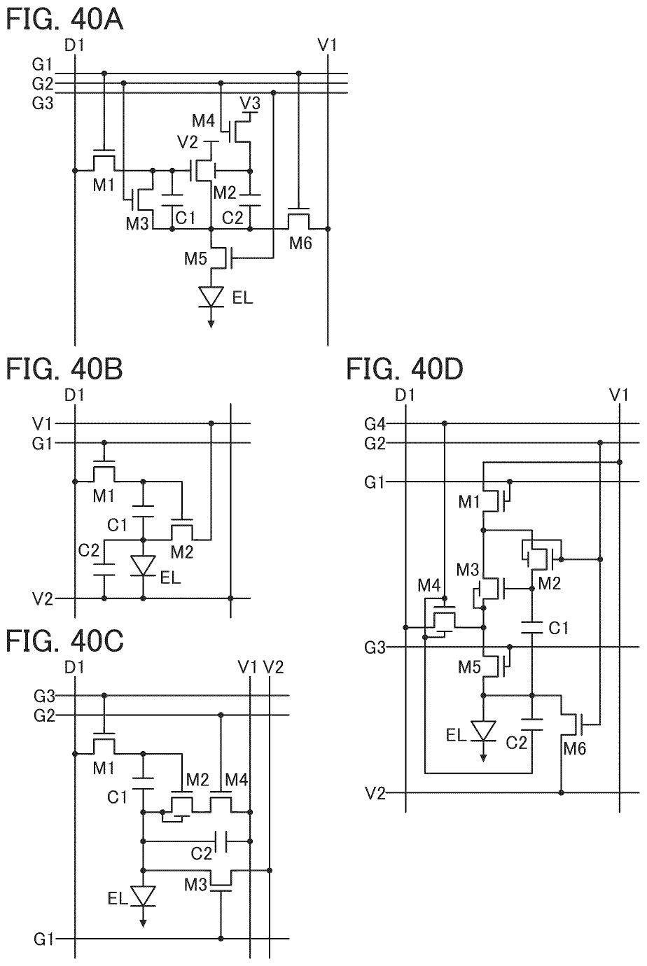

In the semiconductor device 10_30, a source electrode or a drain electrode of the transistor 20_30 is connected to a source electrode or a drain electrode of the transistor 40_1. The two transistors (the transistor 20_30 and the transistor 40_1) included in the semiconductor device 10_30 can be used in a pixel circuit of a display device including the light-emitting element described with reference to FIGS. 40A to 40D, FIGS. 41A to 41D, and FIG. 42, for example. As described above, vertical transistors and TG transistors have different features. Therefore, the semiconductor device 10_30 is preferably used in a suitable place in accordance with the required performance of the transistors included in the pixel circuit.

### Structure Example 31

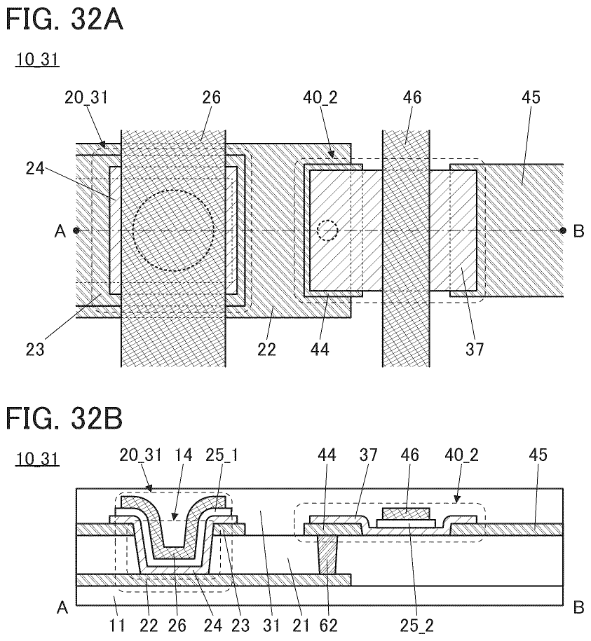

FIGS. 32A and 32B illustrate a semiconductor device 10_31 having a structure different from that of the semiconductor device 10_30 illustrated in FIGS. 31A and 31B. FIG. 32A is a plan view of the semiconductor device 10_31. FIG. 32B is a cross-sectional view taken along the dashed dotted line A-B illustrated in FIG. 32A.

The semiconductor device 10_31 includes a transistor 20_31 and a transistor 40_2. The semiconductor device 10_31 is different from the semiconductor device 10_30 in that gate insulating layers are provided separately in the transistor 20_31 that is a vertical transistor and the transistor 40_2 that is a TG transistor.

Specifically, the insulating layer 25_1 is provided in the transistor 20_31 only in a region overlapping with the semiconductor layer 24, and the insulating layer functions as a gate insulating layer of the transistor 20_31. Meanwhile, an insulating layer 25_2 is provided in the transistor 40_2 only in a region overlapping with a top surface of the semiconductor layer 37 in a region sandwiched between the conductive layer 44 and the conductive layer 45, and the insulating layer functions as a gate insulating layer of the transistor 40_2.

In the semiconductor device 10_31, the insulating layer 25_1 and the insulating layer 25_2 can be formed at the same time by processing the same material.

For the contents of the semiconductor device 10_31 other than what is described in <Structure example 31>, the description of the semiconductor device 10_30 illustrated in FIGS. 31A and 31B can be referred to.

### Structure Example 32

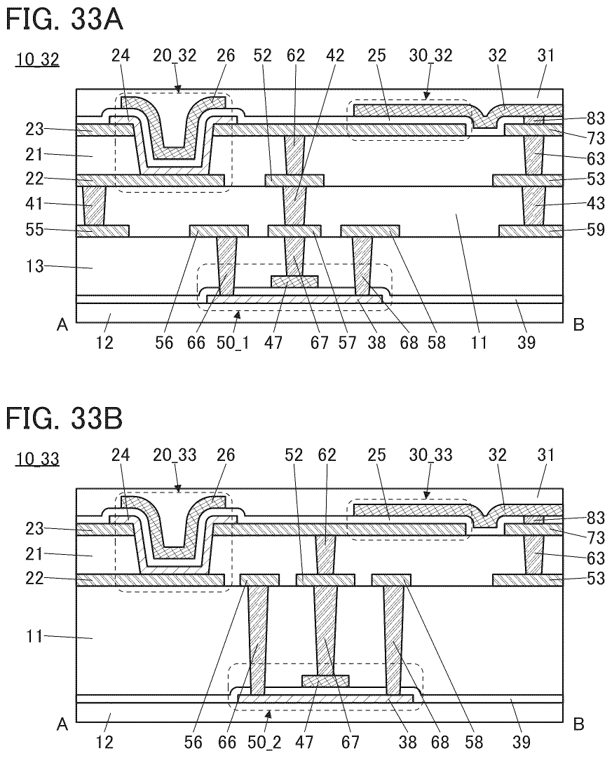

FIG. 33A illustrates a semiconductor device 10_32 having a structure different from that of the semiconductor devices 10_1 to 10_29 illustrated in FIGS. 2A and 2B to FIGS. 30A and 30B. FIG. 33A is a cross-sectional view of the semiconductor device 10_32 taken along the dashed-dotted line A-B in the plan view of the semiconductor device 10_1 illustrated in FIG. 2A.

Th/e semiconductor device 10_32 includes a transistor 20_32, a capacitor 30_32, and a transistor 50_1. For the transistor 20_32 and the capacitor 30_32, the description of the transistor 20_1 and the capacitor 30_1 included in the semiconductor device 10_1 can be referred to. The semiconductor device 10_32 can be regarded as having a structure in which the transistor 50_1 is provided below the semiconductor device 10_1.

The transistor 50_1 is provided over an insulating layer 12 provided over a substrate (not illustrated). The transistor 50_1 includes the conductive layer 66, a conductive layer 68, a semiconductor layer 38, an insulating layer 39, and a conductive layer 47. The conductive layer 66 functions as one of a source electrode and a drain electrode. The conductive layer 68 functions as the other of the source electrode and the drain electrode. The insulating layer 39 functions as a gate insulating layer. The conductive layer 47 functions as a gate electrode. Silicon can also be used for the semiconductor layer 38 as well as an oxide semiconductor. That is, a transistor using silicon (hereinafter referred to as a Si transistor) as well as a transistor using an oxide semiconductor (hereinafter referred to as an OS transistor) can be used as the transistor 50_1.

The semiconductor layer 38 is provided over the insulating layer 12. The insulating layer 39 is provided over the insulating layer 12 to cover the semiconductor layer 38. Over the insulating layer 39, the conductive layer 47 is provided to include a region overlapping with the semiconductor layer 38. An insulating layer 13 having a planarized top surface is provided over the conductive layer 47 and the insulating layer 39.

An opening reaching the conductive layer 47 is provided in the insulating layer 13, and a conductive layer 67 is provided to fill the opening. In the insulating layer 13 and the insulating layer 39, two openings reaching the semiconductor layer 38 are provided to sandwich the conductive layer 67; the conductive layer 66 is provided to fill one opening and the conductive layer 68 is provided to fill the other opening. The top surface of the conductive layer 66, a top surface of the conductive layer 67, a top surface of the conductive layer 68, and a top surface of the insulating layer 13 are substantially level with each other.

A conductive layer 55, a conductive layer 56, a conductive layer 57, a conductive layer 58, and a conductive layer 59 are provided in different regions over the insulating layer 13. The conductive layer 55, the conductive layer 56, the conductive layer 57, the conductive layer 58, and the conductive layer 59 can be formed at the same time by processing the same material. The conductive layer 56 includes a region overlapping with the conductive layer 66. The conductive layer 57 includes a region overlapping with the conductive layer 67. The conductive layer 58 includes a region overlapping with the conductive layer 68.

The conductive layer 66 includes a region in contact with a top surface of the semiconductor layer 38 and a region in contact with a bottom surface of the conductive layer 56. The conductive layer 67 includes a region in contact with a top surface of the conductive layer 47 and a region in contact with a bottom surface of the conductive layer 57. The conductive layer 68 includes a region in contact with the top surface of the semiconductor layer 38 and a region in contact with a bottom surface of the conductive layer 58.

The insulating layer 11 having a planarized top surface is provided over the conductive layer 55, the conductive layer 56, the conductive layer 57, the conductive layer 58, the conductive layer 59, and the insulating layer 13. An opening reaching the conductive layer 55, an opening reaching the conductive layer 57, and an opening reaching the conductive layer 59 are provided in the insulating layer 11, and are filled with the conductive layer 41, the conductive layer 42, and the conductive layer 43, respectively. The conductive layer 41 includes a region in contact with a top surface of the conductive layer 55 and a region in contact with a bottom surface of the conductive layer 22. The conductive layer 42 includes a region in contact with a top surface of the conductive layer 57 and a region in contact with a bottom surface of the conductive layer 52. The conductive layer 43 includes a region in contact with a top surface of the conductive layer 59 and a region in contact with a bottom surface of the conductive layer 53.

For the components above the conductive layer 41, the conductive layer 42, the conductive layer 43, and the insulating layer 11, the description of the semiconductor device 10_1 illustrated in FIG. 2B can be referred to.

The semiconductor device 10_32 includes two transistors (the transistor 20_32 and the transistor 50_1) and one capacitor (the capacitor 30_32). In the semiconductor device 10_32, the other of a source electrode and a drain electrode of the transistor 20_32, one electrode of the capacitor 30_32, and a gate electrode of the transistor 50_1 are connected to each other. The semiconductor device 10_32 can be used for a pixel circuit of a display device including a light-emitting element described with reference to FIGS. 40A to 42, for example.

### Structure Example 33

FIG. 33B illustrates a semiconductor device 10_33 having a structure different from that of the semiconductor device 10_32 illustrated in FIG. 33A. FIG. 33B is a cross-sectional view of the semiconductor device 10_33 taken along the dashed-dotted line A-B in the plan view of the semiconductor device 10_1 illustrated in FIG. 2A.

The semiconductor device 10_33 includes a transistor 20_33, a capacitor 30_33, and a transistor 50_2. For the transistor 20_33 and the capacitor 30_33, the description of the transistor 20_32 and the capacitor 30_32 included in the semiconductor device 10_32 can be referred to. The semiconductor device 10_33 is different from the semiconductor device 10_32 in the structure below the insulating layer 21.

The transistor 50_2 has a structure similar to that of the transistor 50_1 included in the semiconductor device 10_32. Note that in the semiconductor device 10_33, the insulating layer 13 included in the semiconductor device 10_32 is not provided, and the transistor 50_2 is covered with the insulating layer 11. That is, the conductive layer 66 and the conductive layer 68 which function as a source electrode and a drain electrode of the transistor 50_2 and the conductive layer 67 connected to the conductive layer 47 functioning as a gate electrode are provided to be embedded in openings formed in the insulating layer 11.

The number of steps of the semiconductor device 10_33 can be smaller than that of the semiconductor device 10_32 because the insulating layer 13 and a plug or the like embedded in the insulating layer 13 do not need to be formed.

For the contents of the semiconductor device 10_33 other than what is described in <Structure example 33>, the description of the semiconductor device 10_32 illustrated in FIG. 33A can be referred to.

### Structure Example 34

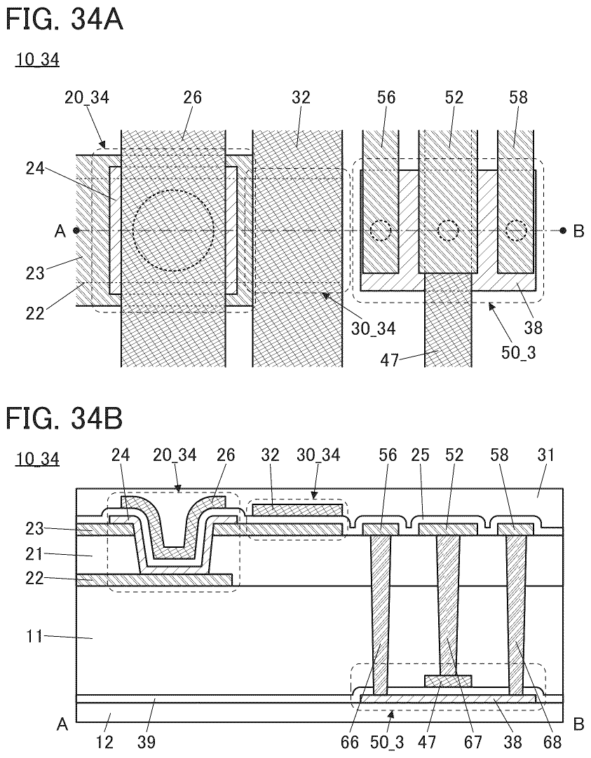

FIGS. 34A and 34B illustrate a semiconductor device 10_34 having a structure different from structures of the semiconductor device 10_32 illustrated in FIG. 33A and the semiconductor device 10_33 illustrated in FIG. 33B. FIG. 34A is a plan view of the semiconductor device 10_34. FIG. 34B is a cross-sectional view taken along the dashed dotted line A-B illustrated in FIG. 34A.

The semiconductor device 10_34 includes a transistor 20_34, a capacitor 30_34, and a transistor 50_3. For the transistor 20_34, the description of the transistor 20_1 included in the semiconductor device 10_1 can be referred to.

The capacitor 30_34 includes the conductive layer 23, the conductive layer 32, and the insulating layer 25. In the semiconductor device 10_34, a region where the conductive layer 23, the insulating layer 25, and the conductive layer 32 overlap with each other functions as the capacitor 30_34. In the capacitor 30_34, the conductive layer 23 functions as one electrode, the conductive layer 32 functions as the other electrode, and the insulating layer 25 functions as a dielectric.

Here, the conductive layer 23 can function as the other of a source electrode and a drain electrode of the transistor 20_34. The insulating layer 25 can also function as a gate insulating layer of the transistor 20_34.

The transistor 50_3 has a structure similar to that of the transistor 50_1 included in the semiconductor device 10_32 and that of the transistor 50_2 included in the semiconductor device 10_33. Note that the transistor 50_3 is different from the semiconductor device 10_32 and the semiconductor device 10_33 in that the conductive layer 66 functioning as one of a source electrode and a drain electrode, the conductive layer 68 functioning as the other of the source electrode and the drain electrode, and the conductive layer 67 connected to the conductive layer 47 functioning as a gate electrode are provided to be embedded in openings formed in the insulating layer 21 and the insulating layer 11.

The conductive layer 56 connected to the conductive layer 66, the conductive layer 52 connected to the conductive layer 67, and the conductive layer 58 connected to the conductive layer 68 are provided over the insulating layer 21. In the semiconductor device 10_34, the conductive layer 23, the conductive layer 56, the conductive layer 52, and the conductive layer 58 can be formed at the same time by processing the same material.

For the contents of the semiconductor device 10_34 other than what is described in <Structure example 35>, the description of the semiconductor device 10_32 in FIG. 33A and the semiconductor device 10_33 in FIG. 33B can be referred to.

### Structure Example 35

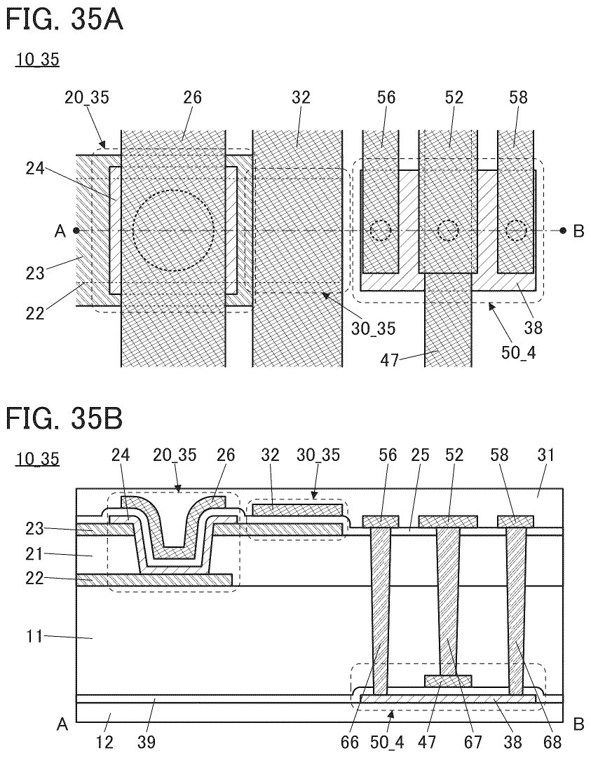

FIGS. 35A and 35B illustrate a semiconductor device 10_35 having a structure different from that of the semiconductor device 10_34 illustrated in FIGS. 34A and 34B. FIG. 35A is a plan view of the semiconductor device 10_35. FIG. 35B is a cross-sectional view taken along the dashed dotted line A-B illustrated in FIG. 35A.

The semiconductor device 10_35 includes a transistor 20_35, a capacitor 30_35, and a transistor 50_4. The semiconductor device 10_35 is different from the semiconductor device 10_34 in that the conductive layer 66, the conductive layer 67, and the conductive layer 68 are provided to be embedded in openings formed in the insulating layer 25, the insulating layer 21, and the insulating layer 11, respectively.

The conductive layer 56 connected to the conductive layer 66, the conductive layer 52 connected to the conductive layer 67, and the conductive layer 58 connected to the conductive layer 68 are provided over the insulating layer 25. In the semiconductor device 10_35, the conductive layer 26, the conductive layer 32, the conductive layer 56, the conductive layer 52, and the conductive layer 58 can be formed at the same time by processing the same material.

For the contents of the semiconductor device 10_35 other than what is described in <Structure example 35>, the description of the semiconductor device 10_34 illustrated in FIGS. 34A and 34B can be referred to.

### Structure Example 36

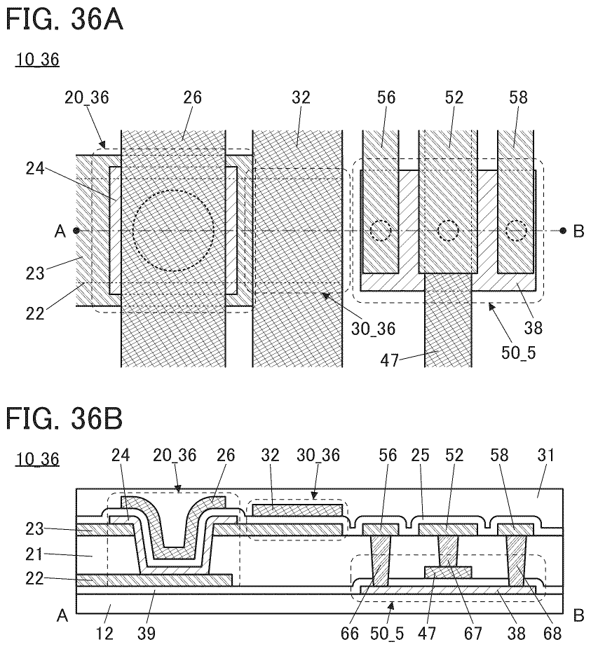

FIGS. 36A and 36B illustrate a semiconductor device 10_36 having a structure different from that of the semiconductor device 10_34 illustrated in FIGS. 34A and 34B. FIG. 36A is a plan view of the semiconductor device 10_36. FIG. 36B is a cross-sectional view taken along the dashed dotted line A-B illustrated in FIG. 36A.

The semiconductor device 10_36 includes a transistor 20_36, a capacitor 30_36, and a transistor 50_5. The semiconductor device 10_36 can be regarded as having a structure in which the insulating layer 11 is excluded from the semiconductor device 10_34.

For the transistor 20_36 and the capacitor 30_36 in the semiconductor device 10_36, the description of the transistor 20_34 and the capacitor 30_34 in the semiconductor device 10_34 can be referred to.

The semiconductor device 10_36 is different from the semiconductor device 10_34 in that the conductive layer 66 functioning as one of a source electrode and a drain electrode of the transistor 50_5 and the conductive layer 68 functioning as the other of the source electrode and the drain electrode of the transistor 50_5 are provided to be embedded in openings provided in the insulating layer 21 and the insulating layer 39. The semiconductor device 10_36 is different from the semiconductor device 10_34 also in that the conductive layer 67 connected to the conductive layer 47 functioning as a gate electrode is provided to be embedded in an opening formed in the insulating layer 21. The semiconductor device 10_36 is different from the semiconductor device 10_34 also in that the conductive layer 22 functioning as one of a source electrode and a drain electrode of the transistor 20_36 is provided in contact with a top surface of the insulating layer 39.

The number of steps of the semiconductor device 10_36 can be smaller than that of the semiconductor device 10_34 because the insulating layer 11 does not need to be formed.

For the contents of the semiconductor device 10_36 other than what is described in <Structure example 36>, the description of the semiconductor device 10_34 illustrated in FIGS. 34A and 34B can be referred to.

### Structure Example 37

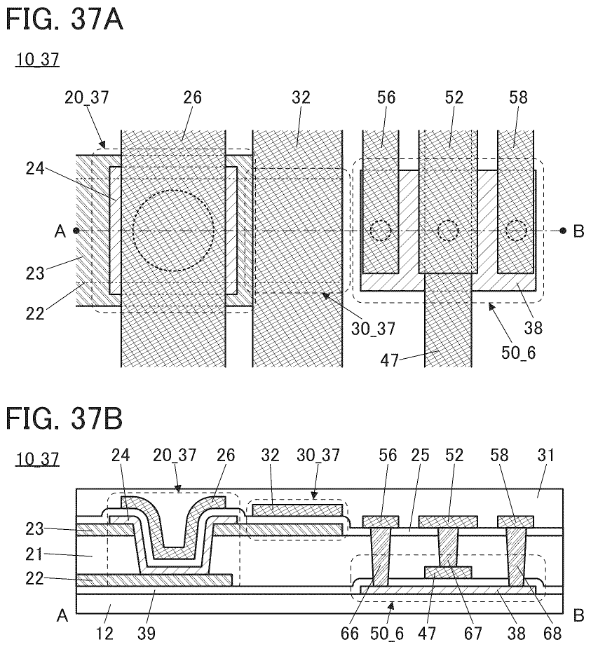

FIGS. 37A and 37B illustrate a semiconductor device 10_37 having a structure different from that of the semiconductor device 10_35 illustrated in FIGS. 35A and 35B. FIG. 37A is a plan view of the semiconductor device 10_37. FIG. 37B is a cross-sectional view taken along the dashed dotted line A-B illustrated in FIG. 37A.

The semiconductor device 10_37 includes a transistor 20_37, a capacitor 30_37, and a transistor 50_6. The semiconductor device 10_37 can be regarded as having a structure in which the insulating layer 11 is excluded from the semiconductor device 10_35.

For the transistor 20_37 and the capacitor 30_37 in the semiconductor device 10_37, the description of the transistor 20_35 and the capacitor 30_35 in the semiconductor device 10_35 can be referred to.

The semiconductor device 10_37 is different from the semiconductor device 10_35 in that the conductive layer 66 functioning as one of a source electrode and a drain electrode of the transistor 50_6 and the conductive layer 68 functioning as the other of the source electrode and the drain electrode of the transistor 50_6 are provided to be embedded in openings provided in the insulating layer 25, the insulating layer 21, and the insulating layer 39. The semiconductor device 10_37 is different from the semiconductor device 10_35 also in that the conductive layer 67 connected to the conductive layer 47 functioning as a gate electrode is provided to be embedded in an opening formed in the insulating layer 25 and the insulating layer 21. The semiconductor device 10_37 is different from the semiconductor device 10_35 also in that the conductive layer 22 functioning as one of a source electrode and a drain electrode of the transistor 20_37 is provided in contact with a top surface of the insulating layer 39.

The number of steps of the semiconductor device 10_37 can be smaller than that of the semiconductor device 10_35 because the insulating layer 11 does not need to be formed.

For the contents of the semiconductor device 10_37 other than what is described in <Structure example 37>, the description of the semiconductor device 10_35 illustrated in FIGS. 35A and 35B can be referred to.

### Structure Example 38

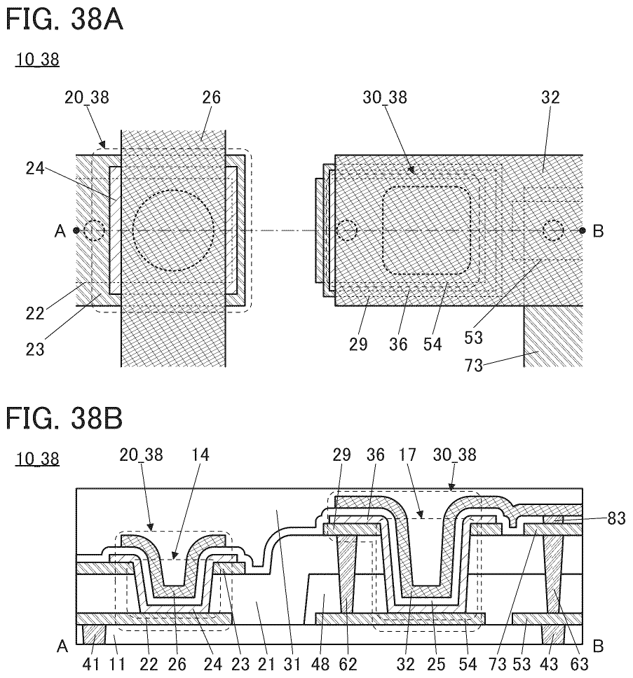

FIGS. 38A and 38B illustrate a semiconductor device 10_38 having a structure different from that of the semiconductor device 10_26 illustrated in FIGS. 27A and 27B. FIG. 38A is a plan view of the semiconductor device 10_38. FIG. 38B is a cross-sectional view taken along the dashed dotted line A-B illustrated in FIG. 38A.

The semiconductor device 10_38 includes a transistor 20_38 and a capacitor 30_38. For the transistor 20_38, the description of the transistor 20_26 included in the semiconductor device 10_26 can be referred to. The structure of the capacitor 30_38 in the semiconductor device 10_38 is different from that of the capacitor 30_26 in the semiconductor device 10_26.

Specifically, in the semiconductor device 10_38, an insulating layer 48 having an island shape is provided over the insulating layer 11 to include a region overlapping with the conductive layer 54 and a region overlapping with the conductive layer 53. The insulating layer 21 is provided over the conductive layer 22, the insulating layer 48, and the insulating layer 11. Over the insulating layer 21 overlapping with the insulating layer 48, the conductive layer 29 is provided in a region overlapping with the conductive layer 54, and the conductive layer 73 is provided in a region overlapping with the conductive layer 53.

An opening 17 reaching the conductive layer 54 is provided in the conductive layer 29, the insulating layer 21, and the insulating layer 48, and the semiconductor layer 36 is provided in contact with a sidewall of the opening 17 (i.e., the side surface of the conductive layer 29 in the opening 17, the side surface of the insulating layer 21 in the opening 17, and a side surface of the insulating layer 48 in the opening 17) and a bottom surface of the opening 17 (i.e., the top surface of the conductive layer 54 in the opening 17). The conductive layer 62 functioning as a plug that connects the conductive layer 54 and the conductive layer 29 and the conductive layer 63 functioning as a plug that connects the conductive layer 53 and the conductive layer 73 are provided to be embedded in openings formed in the insulating layer 48 and the insulating layer 21. The opening 17 is located between the conductive layer 62 and the conductive layer 63.

Although the distance between the conductive layer 54 and the conductive layer 29 (which may be referred to as the total thickness of the insulating layer 48 and the insulating layer 21) is longer in the capacitor 30_38 than in the capacitor 30_26, the capacitance value itself hardly changes. By contrast, when the distance between the source electrode and the drain electrode (which may be referred to as the thickness of the insulating layer 21) of the transistor 20_38 is changed, the channel length is changed; thus, electrical characteristics such as on-state current of the transistor 20_38 are changed as compared with those of the transistor 20_26. Accordingly, appropriate adjustment of the thickness of the insulating layer 48 and the thickness of the insulating layer 21 enables the semiconductor device 10_38 to achieve both the amount of on-state current required for the transistor 20_38 and the capacitance value required for the capacitor 30_38, for example.

The semiconductor device 10_38 shows a non-limiting example in which the structure of the capacitor and its vicinity is changed by adding the insulating layer 48 to the structure of the semiconductor device 10_26 (the structure of the transistor and its vicinity is unchanged). For example, by adding an island-shaped insulating layer such as the insulating layer 48 between the source electrode and the drain electrode of the transistor, the structure of the transistor and its vicinity can be changed (the structure of the capacitor and its vicinity is unchanged).

For the contents of the semiconductor device 10_38 other than what is described in <Structure example 38>, the description of the semiconductor device 10_26 illustrated in FIGS. 27A and 27B can be referred to.

### Structure Example 39

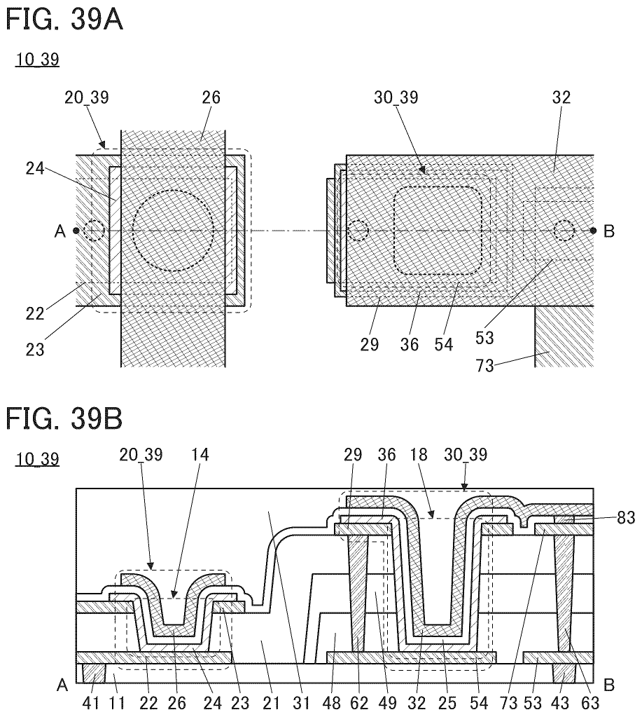

FIGS. 39A and 39B illustrate a semiconductor device 10_39 having a structure different from that of the semiconductor device 10_38 illustrated in FIGS. 38A and 38B. FIG. 39A is a plan view of the semiconductor device 10_39. FIG. 39B is a cross-sectional view taken along the dashed dotted line A-B illustrated in FIG. 39A.

The semiconductor device 10_39 includes a transistor 20_39 and a capacitor 30_39. The structure of the capacitor 30_39 in the semiconductor device 10_39 is different from that of the capacitor 30_38 in the semiconductor device 10_38.

Specifically, in the semiconductor device 10_39, an insulating layer 49 having an island shape is provided over the insulating layer 11 to include a region overlapping with the insulating layer 48. The insulating layer 21 is provided over the conductive layer 22, the insulating layer 49, and the insulating layer 11. Over the insulating layer 21 overlapping with the insulating layer 48 and the insulating layer 49, the conductive layer 29 is provided in a region overlapping with the conductive layer 54, and the conductive layer 73 is provided in a region overlapping with the conductive layer 53.

An opening 18 reaching the conductive layer 54 is provided in the conductive layer 29, the insulating layer 21, the insulating layer 49, and the insulating layer 48, and the semiconductor layer 36 is provided in contact with a sidewall of the opening 18 (i.e., the side surface of the conductive layer 29 in the opening 18, the side surface of the insulating layer 21 in the opening 18, the side surface of the insulating layer 49 in the opening 18, and the side surface of the insulating layer 48 in the opening 18) and a bottom surface of the opening 18 (i.e., the top surface of the conductive layer 54 in the opening 18). The conductive layer 62 functioning as a plug that connects the conductive layer 54 and the conductive layer 29 and the conductive layer 63 functioning as a plug that connects the conductive layer 53 and the conductive layer 73 are provided to be embedded in openings formed in the insulating layer 48, the insulating layer 49, and the insulating layer 21. The opening 18 is located between the conductive layer 62 and the conductive layer 63.

In this manner, in the semiconductor device of one embodiment of the present invention, the total number of island-shaped insulating layers provided between the conductive layer 54 and the conductive layer 29 can be two or more (two layers of the insulating layer 48 and the insulating layer 49 in the case of the semiconductor device 10_39). The semiconductor device 10_39 having the above structure can obtain an effect similar to the effect that can be obtained by the semiconductor device 10_38.

For the contents of the semiconductor device 10_39 other than what is described in <Structure example 39>, the description of the semiconductor device 10_38 illustrated in FIGS. 38A and 38B can be referred to.

The above is the description of the structure example.

### [Components]

### <Substrate>

As the substrate over which the transistor is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, gallium oxide, or gallium nitride. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the elements provided over the substrates include a capacitor, a resistor, a switching element (such as a transistor), a light-emitting element, and a memory element.

### <Semiconductor Layer>

The semiconductor layer 24, the semiconductor layer 24_1, the semiconductor layer 24_2, the semiconductor layer 24_3, the semiconductor layer 27, the semiconductor layer 28, the semiconductor layer 36, the semiconductor layer 37, and the semiconductor layer 38 (hereinafter referred to as a “semiconductor layer”) preferably contain a metal oxide (an oxide semiconductor).

Examples of the metal oxide that can be used for the semiconductor layer include an In oxide, a Ga oxide, and a Zn oxide. The metal oxide preferably includes at least In, Zn, Sn, or Al or further preferably includes In or Zn.

The metal oxide preferably includes two or three elements selected from In, an element M, and Zn. For example, In-M-Zn oxide, In—Zn oxide, In-M oxide, or M-Zn oxide can be used. The element M is a metal element or metalloid element that has a high bonding energy with oxygen, such as a metal element or metalloid element whose bonding energy with oxygen is higher than that of In. Examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The metal oxide preferably includes one or more kinds selected from the above elements, and particularly preferably includes one or more kinds selected from Al, Ga, Y, and Sn. In this specification and the like, a “metal element” may refer to a metalloid element.

The proportion of the number of In atoms is preferably higher than or equal to the number of element M atoms in the In-M-Zn oxide. By increasing the proportion of the number of In atoms in the metal oxide, the on-state current, field-effect mobility, or the like of the transistor can be improved. Examples of the atomic ratio of the metal elements of such In-M-Zn oxide, In:M:Zn, include 1:1:1, 1:1:1.2, 2:1:3, 3:1:2, 4:2:3, 4:2:4.1, 5:1:3, and 5:1:6 and a composition in the vicinity of any of the above atomic ratios. Note that the neighborhood of the atomic ratio includes ±30% of an intended atomic ratio.

The proportion of the number of In atoms may also be lower than that of the number of element M atoms in the In-M-Zn oxide. By increasing the proportion of the number of element M atoms in the metal oxide, generation of oxygen vacancies can be inhibited. Examples of the atomic ratio of the metal elements of the In-M-Zn oxide, In:M:Zn, include 1:3:2, 1:3:3, and 1:3:4 and a composition in the vicinity of any of the above atomic ratios.

For the semiconductor layer, for example, In oxide, In—Zn oxide, In—Ga oxide, In—Sn oxide, In—Ti oxide, In—W oxide, In—Ga—Al oxide, In—Ga—Sn oxide, In—Ga—Zn oxide, In—Sn—Zn oxide, In—Al—Zn oxide, In—Ti—Zn oxide, In—W—Zn oxide, In—Ga—Sn—Zn oxide, or In—Ga—Al—Zn oxide can be used. As the oxide that does not contain In, Ga oxide, Zn oxide, Ga—Zn oxide, Ga—Sn oxide, Al—Zn oxide, Al—Sn oxide, or the like may also be used. A material that does not contain Zn like indium oxide is preferred in that it improves the compatibility with an LSI manufacturing process. By contrast, a material that contains Zn is preferred in that crystallinity can be easily increased.

Note that the metal oxide may contain a metal element having a relatively large atomic number instead of or in addition to indium. As the overlap between orbits of metal elements is larger, the metal oxide tends to have higher carrier conductivity. Thus, a transistor including a metal element having a relatively large atomic number can have high field-effect mobility in some cases. For example, one or more of metal elements belonging to Period 5 and metal elements belonging to Period 6 can be used. Specific examples of the metal element include Y, Zr, Ag, Cd, Sn, Sb, Ba, Pb, Bi, La, Ce, Pr, Nd, Pm, Sm, and Eu.

The metal oxide may contain one or more selected of nonmetallic elements. A transistor including the metal oxide including a nonmetallic element can have high field-effect mobility in some cases. Examples of the nonmetallic element include C, N, P, S, Se, F, Cl, Br, and H.

A sputtering method or an ALD method can be suitably used for the formation of the metal oxide. A sputtering method is preferably used to form a film with a reduced impurity concentration. An ALD method is preferably used to form a film with good coverage. Note that in the case where the metal oxide is formed by a sputtering method, the composition of the formed metal oxide may be different from the composition of a target. In particular, the zinc content percentage of the formed metal oxide may be reduced to approximately 50% of that of the target.

In this specification and the like, the content of a certain metal element in a metal oxide refers to the proportion of the number of atoms of the metal element to the total number of metal element atoms contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X to the metal element Y and the metal element Z contained in the metal oxide is represented by B_{X}:B_{Y}:B_{Z}, the content of the metal element X can be represented by B_{X}/(B_{X}+B_{Y}+B_{Z}).

In the case of using a metal oxide containing In, for example, an increase in the In content enables a transistor to have a high on-state current.

When the semiconductor layer includes a metal oxide not containing Ga or having a low Ga content, a transistor can have high reliability against positive bias application. That is, the transistor can show a small amount of change in the threshold voltage in the positive bias temperature stress (PBTS) test. In the case of using a metal oxide containing Ga, the Ga content is preferably lower than the In content. Accordingly, the transistor can have high mobility and high reliability.

Meanwhile, a transistor having a high Ga content can have high reliability against light. That is, the transistor can show a small amount of change in the threshold voltage of the transistor in the negative bias temperature illumination stress (NBTIS) test. Specifically, a metal oxide in which the proportion of the number of Ga atoms is greater than or equal to that of the number of In atoms has a wider band gap and can reduce the amount of change in the threshold voltage of the transistor in the NBTIS test.

Furthermore, a metal oxide having a high zinc content has high crystallinity whereby diffusion of impurities can be inhibited. Consequently, a change in electrical characteristics of the transistor is suppressed and the transistor can have high reliability.

The semiconductor layer may have a stacked-layer structure including two or more metal oxides. The two or more metal oxides included in the semiconductor layer may have the same composition or substantially the same compositions. Employing a stacked-layer structure of metal oxides having the same composition can reduce the manufacturing cost because the metal oxide layers can be formed using the same sputtering target. Note that a stacked-layer structure including two or more oxides having different compositions may be employed. The use of an ALD method can form a metal oxide with a composition that continuously changes in the thickness direction. This not only increases the range of choices for design without need for use of a film with a predetermined composition but also prevents generation of an interface state or the like between two layers with different compositions; thus, the electrical characteristics and reliability of the transistor can be improved.

In the case where the semiconductor layer has a two-layer structure, the second layer, i.e., the layer closer to the gate electrode, preferably includes a material with higher mobility (higher conductivity) than the first layer. This structure enables the transistor to have normally-off characteristics and a high on-state current. Consequently, both low power consumption and high performance can be achieved. Alternatively, the first layer, i.e., the layer in contact with the source electrode and the drain electrode, may include a material having higher mobility than the second layer. In that case, the contact resistance between the semiconductor layer and the source electrode or the drain electrode can be reduced and the parasitic resistance can be reduced accordingly, so that the transistor can have a high on-state current.

In the case where the semiconductor layer has a three-layer structure, the second layer preferably includes a material having higher mobility than the first layer and the third layer. This structure enables the transistor to have normally-off characteristics and high reliability.

In the case where the semiconductor layer has a stacked-layer structure, all the layers may be formed by the same deposition method or different deposition methods may be used in combination. For example, a semiconductor layer having a stacked-layer structure may be formed by a combination of a sputtering method and an ALD method. Here, by a deposition method such as a sputtering method, a mixed layer is sometimes formed (also referred to as mixing) at the interface between the semiconductor layer and the formation surface. Accordingly, when the first layer is formed by an ALD method to inhibit mixing and the second layer is formed by a sputtering method to form a film with high crystallinity, a transistor having both high reliability and high electrical characteristics can be achieved. Furthermore, a three-layer structure in which the third layer is formed by an ALD method may be employed. Heat treatment is preferably performed after a stacked-layer film is formed by a combination of an ALD method and a sputtering method. With such a structure, crystal growth occurs from the layer formed by a sputtering method toward the layer formed by an ALD method, so that a semiconductor layer with high crystallinity can be formed as the whole stacked film in some cases.

In the case where the semiconductor layer has a stacked-layer structure, a material with high mobility may be used for a layer in contact with the source electrode and the drain electrode. Thus, the contact resistance between the semiconductor layer and the source electrode and the drain electrode is reduced, so that the transistor can have a high on-state current. In particular, in the case of a bottom-contact structure (a structure in which a semiconductor layer is provided over a source electrode and a drain electrode), the above-described contact resistance is sometimes relatively higher than that in the case of a top-contact structure (a structure in which a source electrode and a drain electrode are provided over a semiconductor layer); thus, a material with high mobility is suitably used for the layer in contact with the source electrode and the drain electrode.

The mobility and the conductivity are improved with the higher content of an element that contributes to an increase in conductivity, such as indium. Examples of a high mobility material include materials having an atomic ratio of In:Ga:Zn=4:3:2, In:Zn=1:1, In:Zn=2:1, In:Zn=4:1, In:Sn:Zn=40:1:10, In:Sn:Zn=20:1:10, In:Sn=95:5, and In:Sn=90:10 and materials having an atomic ratio in the vicinity of any of the above atomic ratios. Examples of a material having lower mobility than the above-described materials include materials with In:Ga:Zn atomic ratios of 1:3:2, 1:3:4, 2:2:1, 1:1:1, and 1:1:2 and materials having an atomic ratio in the vicinity of any of the above atomic ratios.

It is preferable to use a metal oxide layer having crystallinity as the semiconductor layer. For example, a metal oxide layer having a c-axis aligned crystal (CAAC) structure, a polycrystalline structure, a nano-crystal (nc) structure, or the like can be used. By using a metal oxide layer having crystallinity as the semiconductor layer, the density of defect states in the semiconductor layer can be reduced, which enables the semiconductor device to have high reliability.

As the crystallinity of the metal oxide layer used as the semiconductor layer becomes higher, the density of defect states in the semiconductor layer can be reduced. By contrast, the use of a metal oxide layer having low crystallinity enables a transistor to flow large current.

An OS transistor has much higher field-effect mobility than a transistor including amorphous silicon. In addition, the OS transistor has an extremely low leakage current between a source and a drain in an off state, and charge accumulated in a capacitor that is connected in series to the transistor can be held for a long period. Furthermore, the power consumption of the semiconductor device can be reduced with the OS transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that a semiconductor material that can be used for the semiconductor layer is not limited to an oxide semiconductor. For example, a single-element semiconductor or a compound semiconductor can be used. Examples of the single-element semiconductor include Si (such as single crystal Si, polycrystalline Si, microcrystalline Si, and amorphous Si) and Ge. Examples of the compound semiconductor include GaAs and SiGe. Examples of the compound semiconductor include an organic semiconductor, a nitride semiconductor, and an oxide semiconductor. These semiconductor materials may contain impurities as dopants.

Alternatively, a material having a layered crystal structure may be used for the semiconductor layer. A material having a layered crystal structure has high electrical conductivity in a plane of the layer. Thus, when such a material having a layered crystal structure is used for a channel formation region, the transistor can have a high on-state current. Examples of the material include graphene, silicane, and chalcogenide. Examples of chalcogenide include chalcogenide of transition elements such as Mo, W, Hf, and Zr. Examples of chalcogen elements include Group 16 elements such as S, Se, and Te.

There is no particular limitation on the crystallinity of a semiconductor material used for the semiconductor layer, and any of an amorphous semiconductor, a single crystal semiconductor, and a semiconductor having other crystallinity than single crystal (a polycrystalline semiconductor, a microcrystalline semiconductor, or a semiconductor partly including crystal regions) may be used. It is preferable to use a semiconductor having crystallinity, in which case deterioration of the transistor characteristics can be suppressed.

### <Gate Insulating Layer>

The insulating layer 25, the insulating layer 25_1, the insulating layer 25_2, and the insulating layer 39 function as gate insulating layers of the transistors and can also be used as dielectrics of the capacitors. In the case where an oxide semiconductor is used for the semiconductor layer, an oxide insulating film is preferably used as at least a film that is in contact with the semiconductor layer among the insulating layer 25, the insulating layer 25_1, the insulating layer 25_2, and the insulating layer 39. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 25, the insulating layer 25_1, the insulating layer 25_2, and the insulating layer 39, a nitride insulating film of silicon nitride, silicon nitride oxide, aluminum nitride, or aluminum nitride oxide can also be used. Each of the insulating layer 25, the insulating layer 25_1, the insulating layer 25_2, and the insulating layer 39 may have a stacked-layer structure, e.g., a stacked-layer structure including at least one oxide insulating film and at least one nitride insulating film.

Note that in this specification and the like, oxynitride refers to a material that contains more oxygen than nitrogen. Nitride oxide refers to a material that contains more nitrogen than oxygen.

Each of the insulating layer 25, the insulating layer 25_1, the insulating layer 25_2, and the insulating layer 39 preferably has a stacked-layer structure using an insulating material that includes a high-k material. A stacked-layer structure including a high dielectric constant (high-k) material and a material having higher dielectric strength than the high-k material is preferably used. For example, as the insulating layer 25, the insulating layer 25_1, the insulating layer 25_2, and the insulating layer 39, an insulating film (also referred to as ZAZ) in which zirconium oxide, aluminum oxide, and zirconium oxide are stacked in this order can be used. An insulating film (also referred to as ZAZA) in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor.

Alternatively, a material exhibiting ferroelectricity may be used for the insulating layer 25, the insulating layer 25_1, the insulating layer 25_2, and the insulating layer 39. Examples of the material exhibiting ferroelectricity include metal oxides such as hafnium oxide, zirconium oxide, and HfZrO_{X} (X is a real number greater than 0).

### <Conductive Layer>

The conductive layer 22, the conductive layer 23, the conductive layer 23_1, the conductive layer 23_2, the conductive layer 29, the conductive layer 44, the conductive layer 45, the conductive layer 54, the conductive layer 66, the conductive layer 68, the conductive layer 73, and the conductive layer 83 are in contact with the semiconductor layer. Here, when the semiconductor layer is formed using an oxide semiconductor and a part of the conductive layer in contact with the semiconductor layer is formed using, for example, a metal that is likely to be oxidized such as aluminum, an insulating oxide (e.g., aluminum oxide) is formed between the conductive layer and the semiconductor layer, which might inhibit electrical continuity between the conductive layer and the semiconductor layer. Therefore, at least a part of the conductive layer in contact with the semiconductor layer is preferably formed using a conductive material that is less likely to be oxidized, a conductive material that maintains low electric resistance even when oxidized, or an oxide conductive material.

For the conductive layers, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide. A conductive oxide containing indium is particularly preferable because of its high conductivity. Alternatively, the above-described oxide material such as In—Ga—Zn oxide that can be used for the semiconductor layer can be used for the conductive layer when the carrier concentration is increased.

For the conductive layers, any of the following structures can be used: a single-layer structure of the above conductive oxide film, a three-layer structure in which a titanium nitride film, a tungsten film, and a titanium nitride are stacked in this order, a two-layer structure in which a ruthenium film or a ruthenium oxide film is stacked over a tungsten film, a two-layer structure in which a ruthenium film or a ruthenium oxide film is stacked over the above conductive oxide film, a two-layer structure in which the above conductive oxide film is stacked over a ruthenium film or a ruthenium oxide film, or the like, for example. Note that ruthenium is a material that is not easily etched and thus is preferably as thin as possible when used; ruthenium used preferably has a thickness greater than or equal to 0.1 nm and less than or equal to 2 nm, for example.

Each of the conductive layer 26, the conductive layer 46, and the conductive layer 47 serves as a gate electrode and can be formed using a variety of conductive materials. For the conductive layer 26, the conductive layer 46, and the conductive layer 47, for example, a metal element selected from Al, Cr, Cu, Ag, Pt, Ta, Ni, Ti, Mo, W, Hf, V, Nb, Mn, Mg, Zr, Be, In, Ru, Ir, Sr, La, and the like or an alloy containing any of these metal elements as its component is preferably used. A nitride or an oxide of any of the above metals or the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

A nitride and an oxide, which can be used for the conductive layer in contact with the semiconductor layer, may be used for the conductive layer 26, the conductive layer 46, and the conductive layer 47.

The conductive layer in contact with the above semiconductor layer and the conductive layer functioning as the gate electrode also function as wirings and thus are preferably formed by stacking low-resistance conductive materials. For example, for a layer under the conductive layer in contact with the semiconductor layer, a low-resistance conductive material that can be used for the conductive layer functioning as the gate electrode described above can also be used.

For the conductive layer 32, the conductive layer 33, the conductive layer 34, the conductive layer 35, the conductive layer 41, the conductive layer 42, the conductive layer 43, the conductive layer 52, the conductive layer 53, the conductive layer 54, the conductive layer 55, the conductive layer 56, the conductive layer 57, the conductive layer 58, the conductive layer 59, the conductive layer 62, the conductive layer 63, the conductive layer 65, the conductive layer 67, the conductive layer 73, the conductive layer 83, the conductive layer 84, the conductive layer 85, the conductive layer 86, the conductive layer 87, the conductive layer 88, the conductive layer 89, the conductive layer 90, the conductive layer 91, and the conductive layer 92, low-resistance conductive materials that can be used for the conductive layer 26, the conductive layer 46, and the conductive layer 47 can be used.

### <Insulating Layer>

Each of the insulating layer 11, the insulating layer 13, the insulating layer 21, the insulating layer 31, the insulating layer 48, and the insulating layer 49 can be used as an interlayer insulating film. The insulating layer 11, the insulating layer 13, the insulating layer 21, the insulating layer 31, the insulating layer 48, and the insulating layer 49 are preferably formed by a film formation method such as a sputtering method or a plasma CVD method, for example. It is particularly preferable to employ a sputtering method, in which a hydrogen gas does not need to be used as a deposition gas, to form a film having an extremely low hydrogen content. Consequently, supply of hydrogen to the semiconductor layer is inhibited and the electrical characteristics of the transistor can be stabilized.

The insulating layer 21 is in contact with the channel formation region of the semiconductor layer and therefore is preferably formed using an oxide insulating film. In particular, an oxide insulating film that releases oxygen by heating is preferably used. An oxide insulating film that can be used as the gate insulating layer can be used as the insulating layer 21.

For formation of a film functioning as the interlayer insulating layer, it is preferable to use a film formation method that enables a higher deposition rate than those of the other insulating layers. For example, a silicon oxide film formed by a plasma CVD method using tetraethyl orthosilicate (TEOS) whose chemical formula is Si(OC₂H₅)₄) as a source material may be used as the insulating layer 21. The productivity can be thus increased.

The insulating layer 12 functions as a base insulating layer or an interlayer insulating layer. For the insulating layer 12, an insulating material that can be used for the insulating layer 21 or an insulating material having a barrier property against oxygen or hydrogen is preferably used. For example, silicon nitride, silicon nitride oxide, or aluminum oxide is preferably used.

The above is the description of the components.

### [Structure Example of Pixel Circuit]

The semiconductor device of one embodiment of the present invention can be used for not only a display device in which a liquid crystal element is used as a display element but also a display device in which a light-emitting element is used. To increase the luminance of the light-emitting element included in the pixel circuit of the display device, it is necessary to increase the amount of current flowing through the light-emitting element. To increase the current amount, the source-drain voltage of a driving transistor included in the pixel circuit needs to be increased. An OS transistor has higher withstand voltage between a source and a drain than a Si transistor; hence, high voltage can be applied between the source and the drain of the OS transistor. Thus, with the use of an OS transistor as the driving transistor included in the pixel circuit, the amount of current flowing through the light-emitting element can be increased, resulting in an increase in luminance of the light-emitting element.

When transistors operate in a saturation region, a change in source-drain current relative to a change in gate-source voltage can be smaller in an OS transistor than in a Si transistor. Therefore, when an OS transistor is used as the driving transistor included in the pixel circuit, the amount of current flowing through the light-emitting element can be controlled minutely. Consequently, the number of gray levels expressed by the pixel circuit can be increased. Moreover, a stable current can flow through the light-emitting element even when the electrical characteristics (e.g., resistance) of the light-emitting element change or the electrical characteristics of the light-emitting elements vary.

As described above, with use of an OS transistor as a driving transistor included in the pixel circuit, it is possible to achieve “inhibition of black floating”, “increase in emission luminance”, “increase in gray level”, “reduction in influence of manufacturing variation in light-emitting elements”, and the like.

A structure example of a pixel circuit in which a light-emitting element is used as a display element is described below.

A pixel circuit illustrated in FIG. 40A includes a transistor M1, a transistor M2, a transistor M3, a transistor M4, a transistor M5, a transistor M6, a capacitor C1, a capacitor C2, and a light-emitting element EL. A wiring G1, a wiring G2, and a wiring G3 which function as gate lines, a wiring D1 which functions as a source line, and a wiring V1, a wiring V2, and a wiring V3 each supplied with a fixed potential are connected to the pixel circuit.

A gate of the transistor M1 is connected to the wiring G1; one of a source and a drain of the transistor M1 is connected to the wiring D1; and the other of the source and the drain of the transistor M1 is connected to one of a source and a drain of the transistor M3, one electrode of the capacitor C1, and a gate of the transistor M2. A back gate of the transistor M2 is connected to the other of a source and a drain of the transistor M4 and one electrode of the capacitor C2; one of a source and a drain of the transistor M2 is connected to the wiring V2; and the other of the source and the drain of the transistor M2 is connected to the other of the source and the drain of the transistor M3, the other electrode of the capacitor C1, the other electrode of the capacitor C2, one of a source and a drain of the transistor M6, and one of a source and a drain of the transistor M5. A gate of the transistor M3 is connected to the wiring G2. A gate of the transistor M4 is connected to the wiring G2, and one of the source and the drain of the transistor M4 is connected to the wiring V3. A gate of the transistor M5 is connected to the wiring G3, and the other of the source and the drain of the transistor M5 is connected to one electrode of the light-emitting element EL. A gate of the transistor M6 is connected to the wiring G1, and the other of the source and the drain of the transistor M6 is connected to the wiring V1.

The transistor M2 functions as a driving transistor, and the other transistors function as switches. A TG transistor is preferably used as the transistor M2. TG transistors or LTPS transistors, which have low parasitic capacitance, are preferably used as the transistor M1, the transistor M4, and the transistor M6 which have a large influence of noise on the capacitor C1 and the capacitor C2. Furthermore, vertical transistors with a high on-state current are preferably used as the transistor M3 and the transistor M5.

Since a high on-state current can flow through both a vertical transistor and an LTPS transistor, a structure in which a vertical transistor is used as the transistor M1 and an LTPS transistor is used as the transistor M5 can be employed, for example.

A pixel circuit illustrated in FIG. 40B includes the transistor M1, the transistor M2, the capacitor C1, the capacitor C2, and the light-emitting element EL. The wiring G1, which functions as a gate line, the wiring D1 which functions as a source line, and the wiring V1 and the wiring V2 each supplied with a fixed potential are connected to the pixel circuit.

The gate of the transistor M1 is connected to the wiring G1; the one of the source and the drain of the transistor M1 is connected to the wiring D1; and the other of the source and the drain of the transistor M1 is connected to one electrode of the capacitor C1 and the gate of the transistor M2. The one of the source and the drain of the transistor M2 is connected to the other electrode of the capacitor C1, the one electrode of the capacitor C2, and the one electrode of the light-emitting element EL; and the other of the source and the drain of the transistor M2 is connected to the wiring V1. The other electrode of the capacitor C2 is connected to the wiring V2.

The transistor M2 functions as a driving transistor, and the other transistors function as switches. A TG transistor is preferably used as the transistor M2. A TG or LTPS transistor, which has low parasitic capacitance, is preferably used as the transistor M1 which has a large influence of noise on the capacitor C1 and the capacitor C2.

A pixel circuit illustrated in FIG. 40C includes the transistor M1, the transistor M2, the transistor M3, the transistor M4, the capacitor C1, the capacitor C2, and the light-emitting element EL. The wiring G1, the wiring G2, and the wiring G3 which function as gate lines, the wiring D1 which functions as a source line, and the wiring V1 and the wiring V2 supplied with a fixed potential are connected to the pixel circuit.

The gate of the transistor M1 is connected to the wiring G3; the one of the source and the drain of the transistor M1 is connected to the wiring D1; and the other of the source and the drain of the transistor M1 is connected to the one electrode of the capacitor C1 and the gate of the transistor M2. The back gate and the one of the source and the drain of the transistor M2 are connected to the other electrode of the capacitor C1, the one electrode of the capacitor C2, one of the source and the drain of the transistor M3, and the one electrode of the light-emitting element EL; and the other of the source and the drain of the transistor M2 is connected to the one of the source and the drain of the transistor M4. The gate of the transistor M3 is connected to the wiring G1, and the other of the source and the drain of the transistor M3 is connected to the wiring V2. The gate of the transistor M4 is connected to the wiring G2, and the other of the source and the drain of the transistor M4 is connected to the wiring V1. The other electrode of the capacitor C2 is connected to the wiring V1.

The transistor M2 functions as a driving transistor, and the other transistors function as switches. A TG transistor is preferably used as the transistor M2. A TG or LTPS transistor, which has low parasitic capacitance, is preferably used as the transistor M1 which has a large influence of noise on the capacitor C1 and the capacitor C2. Furthermore, vertical transistors with a high on-state current are preferably used as the transistor M3 and the transistor M4.

A pixel circuit illustrated in FIG. 40D includes the transistor M1, the transistor M2, the transistor M3, the transistor M4, the transistor M5, the transistor M6, the capacitor C1, the capacitor C2, and the light-emitting element EL. The wiring G1, the wiring G2, the wiring G3, a wiring G4 which function as gate lines, the wiring D1 which functions as a source line, and the wiring V1 and the wiring V2 each supplied with a fixed potential are connected to the pixel circuit.

The gate of the transistor M1 is connected to the wiring G1; the one of the source and the drain of the transistor M1 is connected to the wiring V1; and the other of the source and the drain of the transistor M1 is connected to the one of the source and the drain of the transistor M3 and the one of the source and the drain of the transistor M2. The gate and the back gate of the transistor M2 are connected to the wiring G2 and the gate of the transistor M6, and the other of the source and the drain of the transistor M2 is connected to the one electrode of the capacitor C1 and the gate of the transistor M3. A back gate and the other of the source and the drain of the transistor M3 are connected to the other of the source and the drain of the transistor M4 and the one of the source and the drain of the transistor M5. The gate and a back gate of the transistor M4 are connected to the wiring G4 and the other electrode of the capacitor C2, and the other of the source and the drain of the transistor M4 is connected to the wiring D1. The gate of the transistor M5 is connected to the wiring G3, and the other of the source and the drain of the transistor M5 is connected to the one electrode of the light-emitting element EL, the other electrode of the capacitor C1, the one electrode of the capacitor C2, and the one of the source and the drain of the transistor M6. The other of the source and the drain of the transistor M6 is connected to the wiring V2.

The transistor M3 functions as a driving transistor, and the other transistors function as switches. A TG transistor is preferably used as the transistor M3. A TG transistor or an LTPS transistor, which has low parasitic capacitance, is preferably used as the transistor M2 which has a large influence of noise on the capacitor C1 and the capacitor C2. Furthermore, vertical transistors with a high on-state current are preferably used as the transistors M1, M4, M5, and M6.

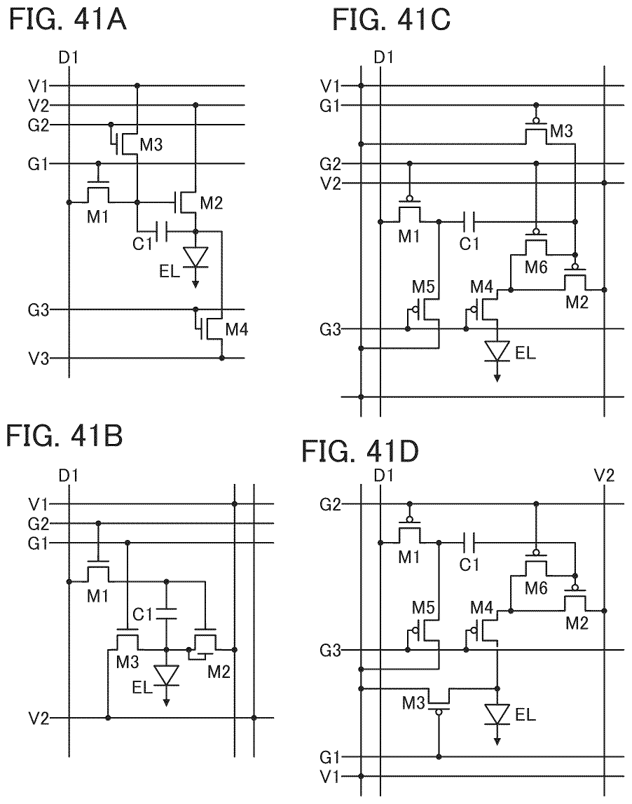

A pixel circuit illustrated in FIG. 41A includes the transistor M1, the transistor M2, the transistor M3, the transistor M4, the capacitor C1, and the light-emitting element EL. The wiring G1, the wiring G2, and the wiring G3 which function as gate lines, the wiring D1 which functions as a source line, and the wiring V1, the wiring V2, and the wiring V3 each supplied with a fixed potential are connected to the pixel circuit.

The gate of the transistor M1 is connected to the wiring G1; the one of the source and the drain of the transistor M1 is connected to the wiring D1; and the other of the source and the drain of the transistor M1 is connected to the gate of the transistor M2, the one electrode of the capacitor C1, and the other of the source and the drain of the transistor M3. The one of the source and the drain of the transistor M2 is connected to the wiring V2; the other of the source and the drain of the transistor M2 is connected to the other electrode of the capacitor C1, the one electrode of the light-emitting element EL, and the one electrode of the transistor M4. The gate of the transistor M3 is connected to the wiring G2, and the one of the source and the drain of the transistor M3 is connected to the wiring V1. The gate of the transistor M4 is connected to the wiring G3, and the other of the source and the drain of the transistor M4 is connected to the wiring V3.

The transistor M2 functions as a driving transistor, and the other transistors function as switches. A TG transistor is preferably used as the transistor M2. A TG or LTPS transistor, which has low parasitic capacitance, is preferably used as the transistor M1 which has a large influence of noise on the capacitor C1. Furthermore, vertical transistors with a high on-state current are preferably used as the transistor M3 and the transistor M4.

A pixel circuit illustrated in FIG. 41B includes the transistor M1, the transistor M2, the transistor M3, the capacitor C1, and the light-emitting element EL. The wiring G1 and the wiring G2 which function as gate lines, the wiring D1 which functions as a source line, and the wiring V1 and the wiring V2 each supplied with a fixed potential are connected to the pixel circuit.

The gate of the transistor M1 is connected to the wiring G2; the one of the source and the drain of the transistor M1 is connected to the wiring D1; and the other of the source and the drain of the transistor M1 is connected to one electrode of the capacitor C1 and the gate of the transistor M2. The back gate and the one of the source and the drain of the transistor M2 are connected to the other electrode of the capacitor C1, the one electrode of the light-emitting element EL, the other of the source and the drain of the transistor M3; and the other of the source and the drain of the transistor M2 is connected to the wiring V1. The gate of the transistor M3 is connected to the wiring G1, and the one of the source and the drain of the transistor M3 is connected to the wiring V2.

The transistor M2 functions as a driving transistor, and the other transistors function as switches. A TG transistor is preferably used as the transistor M2. A TG or LTPS transistor, which has low parasitic capacitance, is preferably used as the transistor M1 which has a large influence of noise on the capacitor C1. Furthermore, a vertical transistor with a high on-state current is preferably used as the transistor M3.

A pixel circuit illustrated in FIG. 41C includes the transistor M1, the transistor M2, the transistor M3, the transistor M4, the transistor M5, the transistor M6, the capacitor C1, and the light-emitting element EL. The wiring G1, the wiring G2, and the wiring G3 which function as gate lines, the wiring D1 which functions as a source line, and the wiring V1 and the wiring V2 each supplied with a fixed potential are connected to the pixel circuit.

The gate of the transistor M1 is connected to the wiring G2; the one of the source and the drain of the transistor M1 is connected to the wiring D1; and the other of the source and the drain of the transistor M1 is connected to the one electrode of the capacitor C1 and the one of the source and the drain of the transistor M5. The gate of the transistor M2 is connected to the other of the source and the drain of the transistor M3, the other electrode of the capacitor C1, and the other of the source and the drain of the transistor M6; the one of the source and the drain of the transistor M2 is connected to the one of the source and the drain of the transistor M4 and the other of the source and the drain of the transistor M6; and the other of the source and the drain of the transistor M2 is connected to the wiring V2. The gate of the transistor M3 is connected to the wiring G1, and the one of the source and the drain of the transistor M3 is connected to the wiring V1. The gate of the transistor M4 is connected to the wiring G3 and the gate of the transistor M5, and the other of the source and the drain of the transistor M4 is connected to the one electrode of the light-emitting element EL. The other of the source and the drain of the transistor M5 is connected to the wiring V1. The gate of the transistor M6 is connected to the wiring G2.

Although the transistors M1 to M6 are all p-channel transistors here, one or more of the transistors M1 to M6 may be n-channel transistors.

The transistor M2 functions as a driving transistor, and the other transistors function as switches. A p-channel LTPS transistor is preferably used as the transistor M2. TG transistors, which have low parasitic capacitance, are preferably used as the transistors M1, M3, and M6 which have a large influence of noise on the capacitor C1. Furthermore, vertical transistors with a high on-state current or LTPS transistors with a high on-state current are preferably used as the transistors M4 and M5. In the case where TG transistors or vertical transistors are employed, n-channel transistors are preferably used.

A pixel circuit illustrated in FIG. 41D includes the transistor M1, the transistor M2, the transistor M3, the transistor M4, the transistor M5, the transistor M6, the capacitor C1, and the light-emitting element EL. The wiring G1, the wiring G2, and the wiring G3 which function as gate lines, the wiring D1 which functions as a source line, and the wiring V1 and the wiring V2 each supplied with a fixed potential are connected to the pixel circuit.

The gate of the transistor M1 is connected to the wiring G2; the one of the source and the drain of the transistor M1 is connected to the wiring D1; and the other of the source and the drain of the transistor M1 is connected to the one electrode of the capacitor C1 and the one of the source and the drain of the transistor M5. The gate of the transistor M2 is connected to the other electrode of the capacitor C1 and the other of the source and the drain of the transistor M6; the one of the source and the drain of the transistor M2 is connected to the one of the source and the drain of the transistor M4 and the other of the source and the drain of the transistor M6; and the other of the source and the drain of the transistor M2 is connected to the wiring V2. The gate of the transistor M3 is connected to the wiring G1; the one of the source and the drain of the transistor M3 is connected to the wiring V1; and the other of the source and the drain of the transistor M3 is connected to the other of the source and the drain of the transistor M4 and the one electrode of the light-emitting element EL. The gate of the transistor M4 is connected to the wiring G3 and the gate of the transistor M5. The other of the source and the drain of the transistor M5 is connected to the wiring V1. The gate of the transistor M6 is connected to the wiring G2.

Although the transistors M1 to M6 are all p-channel transistors here, one or more of the transistors M1 to M6 may be n-channel transistors.

The transistor M2 functions as a driving transistor, and the other transistors function as switches. A p-channel LTPS transistor is preferably used as the transistor M2. TG transistors, which have low parasitic capacitance, are preferably used as the transistors M1 and M6 which have a large influence of noise on the capacitor C1. Furthermore, vertical transistors with a high on-state current or LTPS transistors with a high on-state current are preferably used as the transistors M3, M4, and M5. In the case where TG transistors or vertical transistors are employed, n-channel transistors are preferably used.

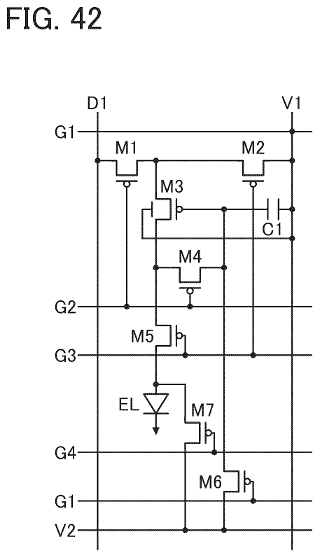

A pixel circuit illustrated in FIG. 42 includes the transistor M1, the transistor M2, the transistor M3, the transistor M4, the transistor M5, the transistor M6, a transistor M7, the capacitor C1, and the light-emitting element EL. The wiring G1, the wiring G2, the wiring G3, and the wiring G4 which function as gate lines, the wiring D1 which functions as a source line, and the wiring V1 and the wiring V2 each supplied with a fixed potential are connected to the pixel circuit.

The gate of the transistor M1 is connected to the wiring G2; the one of the source and the drain of the transistor M1 is connected to the wiring D1; and the other of the source and the drain of the transistor M1 is connected to the one of the source and the drain of the transistor M2 and the one of the source and the drain of the transistor M3. The gate of the transistor M2 is connected to the wiring G3, and the other of the source and the drain of the transistor M2 is connected to the wiring V1. The gate of the transistor M3 is connected to the one electrode of the capacitor C1, the other of the source and the drain of the transistor M4, and the one of the source and the drain of the transistor M6; the back gate of the transistor M3 is connected to the wiring V1; and the other of the source and the drain of the transistor M3 is connected to the one of the source and the drain of the transistor M4 and the one of the source and the drain of the transistor M5. The gate of the transistor M4 is connected to the wiring G2. The gate of the transistor M5 is connected to the wiring G3, and the other of the source and the drain of the transistor M5 is connected to the one electrode of the light-emitting element EL and one of a source and a drain of the transistor M7. The gate of the transistor M6 is connected to the wiring G1, and the other of the source and the drain of the transistor M6 is connected to the wiring V2. A gate of the transistor M7 is connected to the wiring G4, and the other of the source and the drain of the transistor M7 is connected to the wiring V2. The other electrode of the capacitor C1 is connected to the wiring V1.

Although the transistors M1 to M7 are all p-channel transistors here, one or more of the transistors M1 to M7 may be n-channel transistors.

The transistor M3 functions as a driving transistor, and the other transistors function as switches. A p-channel LTPS transistor is preferably used as the transistor M3. TG transistors, which have low parasitic capacitance, are preferably used as the transistors M4 and M6 which have a large influence of noise on the capacitor C1. Furthermore, vertical transistors with a high on-state current or LTPS transistors with a high on-state current are preferably used as the transistors M1, M2, M5, and M7. In the case where TG transistors or vertical transistors are employed, n-channel transistors are preferably used.

The above is examples of the pixel circuits.

At least part of this embodiment can be implemented in combination with any of the other embodiments described in this specification, as appropriate.

### Embodiment 2

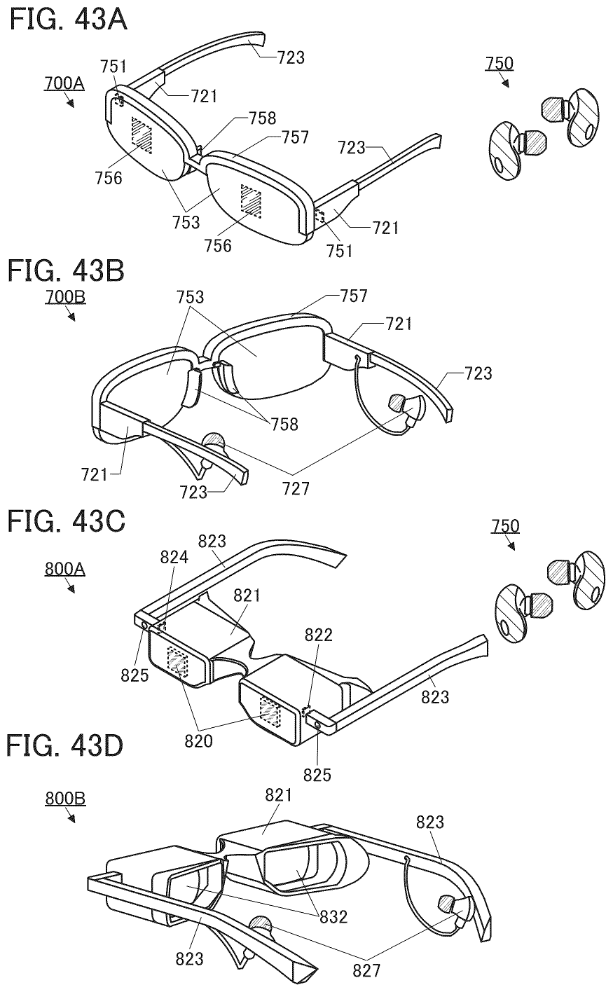

In this embodiment, electronic devices of embodiments of the present invention will be described with reference to FIGS. 43A to 43D, FIGS. 44A to 44F, and FIGS. 45A to 45G.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices worn on the head, such as a virtual reality (VR) device like a head-mounted display, a glasses-type augmented reality (AR) device, and a mixed reality (MR) device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation and sense of depth. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 43A to 43D. The wearable devices have at least one of a function of displaying AR contents, a function of displaying VR contents, a function of displaying substitutional reality (SR) contents, and a function of displaying MR contents. The electronic device having a function of displaying contents of at least one of AR, VR, SR, and MR enables the user to feel a higher level of immersion.

An electronic device 700A illustrated in FIG. 43A and an electronic device 700B illustrated in FIG. 43B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In each of the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 43C and an electronic device 800B illustrated in FIG. 43D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 43C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 43A has a function of transmitting information to the earphones 750 with the wireless communication function. As another example, the electronic device 800A in FIG. 43C has a function of transmitting information to the earphones 750 with the wireless communication function.

The electronic device may include an earphone portion. The electronic device 700B in FIG. 43B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 43D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

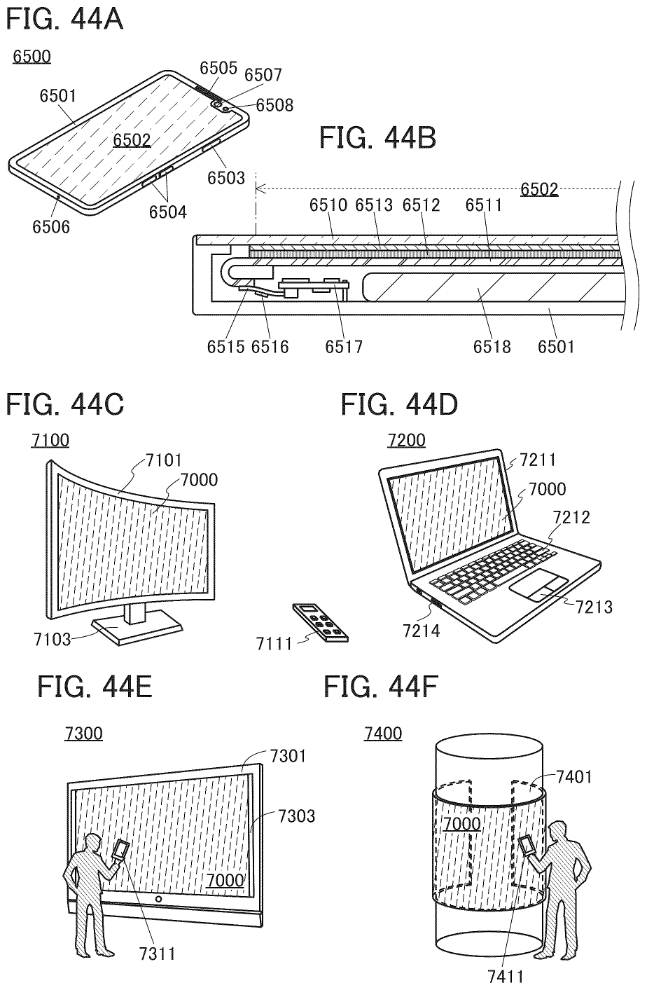

An electronic device 6500 illustrated in FIG. 44A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 44B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 44C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 44C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 44D illustrates an example of a laptop personal computer. The laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 44E and 44F illustrate examples of digital signage.

Digital signage 7300 illustrated in FIG. 44E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 44F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 44E and 44F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIGS. 44E and 44F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

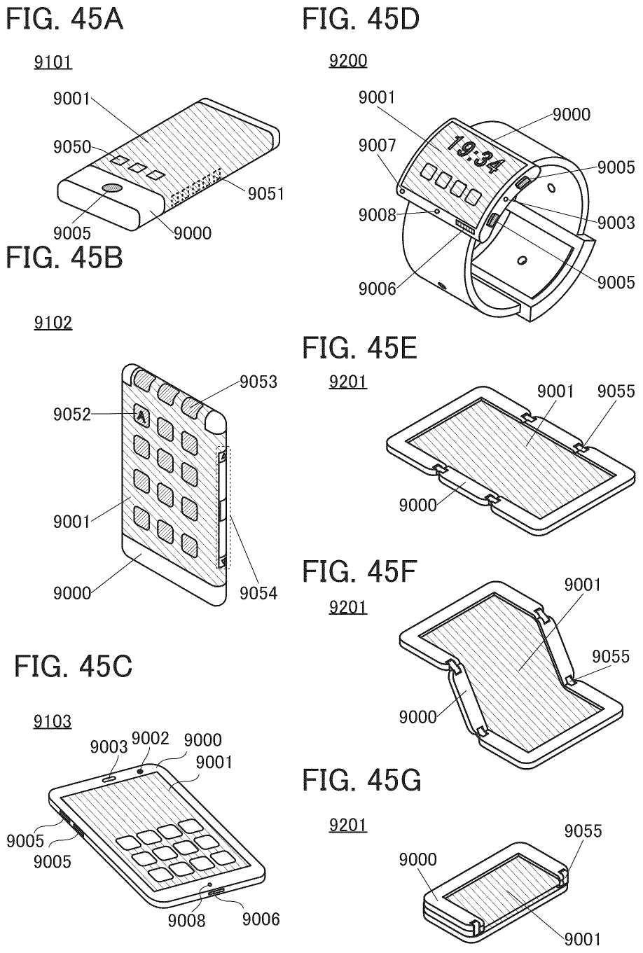

Electronic devices illustrated in FIGS. 45A to 45G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 45A to 45G, the display device of one embodiment of the present invention can be used in the display portion 9001.

The electronic devices illustrated in FIGS. 45A to 45G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 45A to 45G will be described in detail below.

FIG. 45A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 45A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 45B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 45C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 45D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 45E to 45G are perspective views of a foldable portable information terminal 9201. FIG. 45E is a perspective view illustrating the portable information terminal 9201 that is opened. FIG. 45G is a perspective view illustrating the portable information terminal 9201 that is folded. FIG. 45F is a perspective view illustrating the portable information terminal 9201 that is shifted from one of the states in FIGS. 45E and 45G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with any of the other embodiments described in this specification, as appropriate.

This application is based on Japanese Patent Application Serial No. 2023-207567 filed with Japan Patent Office on Dec. 8, 2023, the entire contents of which are hereby incorporated by reference.

What is claimed is:

1. A semiconductor device comprising:
a transistor;
a capacitor; and
a first insulating layer,
wherein the transistor comprises a first conductive layer, a second conductive layer, a third conductive layer, a semiconductor layer, and a second insulating layer,
wherein the first insulating layer is positioned over the first conductive layer,
wherein the second conductive layer is positioned over the first insulating layer,
wherein the second conductive layer and the first insulating layer comprise an opening reaching the first conductive layer,
wherein in the opening, the semiconductor layer is in contact with a side surface of the second conductive layer, a side surface of the first insulating layer, and a top surface of the first conductive layer,
wherein the second insulating layer is in contact with a top surface of the semiconductor layer and a top surface of the second conductive layer,
wherein the third conductive layer is positioned over the second insulating layer so as to comprise a region overlapping with the semiconductor layer,
wherein the capacitor comprises the second conductive layer, the second insulating layer, and a fourth conductive layer, and
wherein the fourth conductive layer is positioned over the second insulating layer so as to comprise a region overlapping with the second conductive layer.

2. The semiconductor device according to claim 1,
wherein the third conductive layer and the fourth conductive layer comprise the same material.

3. The semiconductor device according to claim 1, further comprising a fifth conductive layer,
wherein the fifth conductive layer is positioned over the same layer as the first conductive layer,
wherein the fifth conductive layer comprises a region overlapping with the second conductive layer with the first insulating layer therebetween, and
wherein the capacitor comprises the second conductive layer, the second insulating layer, the fourth conductive layer, the fifth conductive layer, and the first insulating layer.

4. The semiconductor device according to claim 1,
wherein the semiconductor layer comprises a region positioned between the second conductive layer and the fourth conductive layer, and
wherein the region serves as a dielectric of the capacitor.

5. A semiconductor device comprising:
a transistor;
a capacitor; and
a first insulating layer,
wherein the transistor comprises a first conductive layer, a second conductive layer, a third conductive layer, a semiconductor layer, and a second insulating layer,
wherein the first insulating layer is positioned over the first conductive layer,
wherein the second conductive layer is positioned over the first insulating layer,
wherein the second conductive layer and the first insulating layer comprise a first opening reaching the first conductive layer,
wherein in the first opening, the semiconductor layer is in contact with a side surface of the second conductive layer, a side surface of the first insulating layer, and a top surface of the first conductive layer,
wherein the second insulating layer is in contact with a top surface of the semiconductor layer and a top surface of the second conductive layer,
wherein the third conductive layer is positioned over the second insulating layer so as to comprise a region overlapping with the semiconductor layer,
wherein the capacitor comprises the first conductive layer, the second insulating layer, and a fourth conductive layer,
wherein the first insulating layer comprises a second opening reaching the first conductive layer,
wherein in the second opening, the second insulating layer is in contact with a side surface of the first insulating layer and a top surface of the first conductive layer, and
wherein the fourth conductive layer is positioned over the second insulating layer so as to comprise a region overlapping with the second opening.

6. The semiconductor device according to claim 5,
wherein the third conductive layer and the fourth conductive layer comprise the same material.

7. A semiconductor device comprising:
a first transistor;
a second transistor;
a capacitor;
a first insulating layer; and
a second insulating layer,
wherein the first transistor comprises a first conductive layer over the second insulating layer, a second conductive layer, a third conductive layer, a first semiconductor layer, and a third insulating layer,
wherein the first insulating layer is positioned over the first conductive layer,
wherein the second conductive layer is positioned over the first insulating layer,
wherein the second conductive layer and the first insulating layer comprise an opening reaching the first conductive layer,
wherein in the opening, the first semiconductor layer is in contact with a side surface of the second conductive layer, a side surface of the first insulating layer, and a top surface of the first conductive layer,
wherein the third insulating layer is in contact with a top surface of the first semiconductor layer and a top surface of the second conductive layer,
wherein the third conductive layer is positioned over the third insulating layer so as to comprise a region overlapping with the first semiconductor layer,
wherein the second transistor comprises a fifth conductive layer, a sixth conductive layer, a seventh conductive layer, a second semiconductor layer, the second insulating layer, and a fourth insulating layer,
wherein the fifth conductive layer, the sixth conductive layer and the fourth insulating layer are positioned over the second semiconductor layer,
wherein the seventh conductive layer is positioned over the fourth insulating layer,
wherein the second insulating layer is positioned over the fourth insulating layer and the fifth conductive layer,
wherein the capacitor comprises the second conductive layer, the third insulating layer, and a fourth conductive layer, and
wherein the fourth conductive layer is positioned over the third insulating layer so as to comprise a region overlapping with the second conductive layer.

8. The semiconductor device according to claim 7,
wherein the third conductive layer and the fourth conductive layer comprise the same material.

9. A display device comprising:
the semiconductor device according to claim 1; and
a display element.

10. The display device according to claim 9,
wherein the display element is a liquid crystal element.

11. The display device according to claim 9,
wherein the display element is a light-emitting element.

12. A display device comprising:
the semiconductor device according to claim 5; and
a display element.

13. The display device according to claim 12,
wherein the display element is a liquid crystal element.

14. The display device according to claim 12,
wherein the display element is a light-emitting element.

15. A display device comprising:
the semiconductor device according to claim 7; and
a display element.

16. The display device according to claim 15,
wherein the display element is a liquid crystal element.

17. The display device according to claim 15,
wherein the display element is a light-emitting element.
